(19) United States
(12) Patent Application Publication
(10) Pub. No.: US 2022/0365434 A1
(43) Pub. Date: Nov. 17, 2022

(54) SUBSTRATE SURFACE MODIFICATION WITH HIGH EUV ABSORBERS FOR HIGH PERFORMANCE EUV PHOTORESISTS

(71) Applicant: Lam Research Corporation, Fremont, CA (US)

(72) Inventors: Katie Lynn Nardi, San Jose, CA (US); Timothy William Weidman, Sunnyvale, CA (US); Chenghao Wu, Berkeley, CA (US); Kevin Li Gu, Mountain View, CA (US); Boris Volosskiy, San Jose, CA (US)

(73) Assignee: Lam Research Corporation, Fremont, CA (US)

(21) Appl. No.: 17/754,019

(22) PCT Filed: Oct. 1, 2020
(86) PCT No.: PCT/US2020/053856

§ 371 Date: Mar. 21, 2022

Related U.S. Application Data
(60) Provisional application No. 62/909,430, filed on Oct. 2, 2019.

(51) Int. Cl. G03F 7/09; G03F 7/20; G03F 7/004; G03F 7/16

(52) U.S. Cl. CPC G03F 7/091; G03F 7/70033; G03F 7/0042; G03F 7/167

(57) ABSTRACT

The present disclosure relates to a patterning structure having a radiation-absorbing layer and an imaging layer, as well as methods and apparatuses thereof. In particular embodiments, the radiation-absorbing layer provides an increase in radiation absorptivity and/or patterning performance of the imaging layer.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in their entireties and for all purposes.

### FIELD

This disclosure relates generally to the field of semiconductor processing. In particular aspects, the disclosure relates to a patterning structure having a radiation-absorbing layer and an imaging layer, as well as methods and apparatuses thereof. In some embodiments, the radiation-absorbing layer provides an increase in radiation absorptivity and/or patterning performance of the imaging layer.

### BACKGROUND

As semiconductor fabrication continues to advance, feature sizes continue to shrink, and new processing methods are needed. One area where advances are being made is in the context of patterning, for example using photoresist materials that are sensitive to lithographic radiation.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Various embodiments herein relate to methods, materials, apparatus, and systems for depositing a photoresist material on a substrate.

In a first aspect, the present disclosure encompasses a method of making a patterning structure, the method including: providing a substrate to receive a pattern; incorporating a radiation-absorbing layer on a surface of the substrate; and providing an imaging layer, wherein the radiation-absorbing layer underlies the imaging layer to increase radiation absorptivity and/or patterning performance of the imaging layer.

In some embodiments, the imaging layer includes a radiation-sensitive imaging layer, an Extreme Ultraviolet (EUV)-sensitive film, a photoresist layer, a hardmask, or an atomic layer deposition (ALD) hardmask. In other embodiments, the radiation-absorbing layer includes iodine (I), indium (In), tin (Sn), bismuth (Bi), antimony (Sb), tellurium (Te), an oxide thereof, an alloy thereof, or a combination thereof. In particular embodiments, the radiation-absorbing layer includes a first element having a high patterning radiation-absorption cross-section. In further embodiments, the imaging layer includes a second element having a high patterning radiation-absorption cross-section and a moiety that is cleavable under exposure to a patterning radiation. The first and second elements may be the same or different.

In some embodiments, the method further includes (e.g., prior to said providing the imaging layer): incorporating halo, alkyl, or haloalkyl moieties to a surface of the radiation-absorbing layer.

In other embodiments, said incorporating includes: depositing the radiation-absorbing layer by sputtering, physical vapor deposition (PVD), chemical vapor deposition (CVD), atomic layer deposition (ALD), plasma-based deposition, thermal-induced decomposition, or plasma-induced decomposition of one or more precursors.

In some embodiments, said incorporating includes: providing a first precursor including tellurium (Te) and a second precursor including a metal oxide to the surface of the substrate, wherein the first and second precursors are each provided to the substrate in vapor phase, thereby depositing the radiation-absorbing layer on the substrate. In some embodiments, the first precursor includes TeR₂ or TeR₄, wherein each R is, independently, halo, optionally substituted C₁₋₁₂ alkyl, optionally substituted C₁₋₁₂ alkoxy, optionally substituted aryl, hydroxyl, oxo, or optionally substituted trialkylsilyl; and the second precursor includes tin oxide, antimony oxide, or bismuth oxide.

In other embodiments, said incorporating includes: exposing the surface of the substrate to a vapor including an element having a high EUV-absorption cross-section and in the presence of plasma or heat, thereby depositing the radiation-absorbing layer on the substrate. In particular embodiments, the vapor includes iodine (I), iodine gas (I₂), diiodomethane (CH₂I₂), tin (Sn), tellurium (Te), or bis(alkyl)tellurium (TeR₂).

In some embodiments, a surface of the radiation-absorbing layer further includes a photoresponsive surface having a labile moiety that is cleavable under exposure to the patterning radiation. In particular embodiments, said incorporating includes: depositing the radiation-absorbing layer on the surface of the substrate; and capping the radiation-absorbing layer with a capping agent including the labile moiety. In further embodiments, the radiation-absorbing layer includes tin oxide, tin, tin alloy, bismuth oxide, or tellurium; and wherein the capping agent includes an alkyl substituted metal-containing precursor (e.g., any described herein).

In yet other embodiments, the method further includes (e.g., after said providing the imaging layer): exposing the radiation-absorbing layer and the imaging layer to a patterned radiation exposure, thereby providing an exposed film having a radiation exposed area and a radiation unexposed area; and developing the exposed film, thereby removing the radiation unexposed area to provide the pattern. In some embodiments, the radiation exposed area is characterized by enhanced adhesion between the radiation-absorbing layer and the imaging layer, as compared to the radiation unexposed area.

In other embodiments, the method further includes (e.g., before said providing the imaging layer: exposing the photoresponsive surface of the radiation-absorbing layer to a patterned radiation exposure, thereby providing a patterned radiation-absorbing layer having a radiation exposed area and a radiation unexposed area, as compared to the radiation unexposed area. In some embodiments, the radiation exposed area is characterized by enhanced nucleation for deposition of the imaging layer.

In some embodiments, the method further includes (e.g., after said providing the imaging layer): exposing the radiation-absorbing layer and the imaging layer to a patterned radiation exposure, thereby providing an exposed film having a radiation exposed area and a radiation unexposed area; and developing the exposed film, thereby removing the radiation unexposed area or the radiation exposed area to provide the pattern.

In a second aspect, the present disclosure encompasses a patterning structure including: a substrate to receive a pattern; an imaging layer on a surface of the substrate; and a radiation-absorbing layer under the imaging layer. In some embodiments, the radiation-absorbing layer is configured to increase the radiation absorptivity and patterning performance of the imaging layer.

In a third aspect, the present disclosure encompasses an apparatus for processing a substrate, the apparatus including: (a) one or more process chambers configured to hold a substrate; and (b) a controller having at least one processor and a memory, where the controller is configured to cause any method described herein.

In one embodiment, each process chamber includes a chuck or a pedestal. In other embodiments, the apparatus includes one or more gas inlets into the process chambers and associated flow-control hardware; and one or more gas outlets for removing materials from the process chamber and associated flow-control hardware.

In particular embodiments, at least one processor and the memory are communicatively connected with one another, and at least one processor is at least operatively connected with the flow-control hardware. In further embodiments, the memory stores computer-executable instructions for controlling the at least one processor to at least control the flow-control hardware and for causing any of method described herein.

In a fourth aspect, the apparatus includes a deposition module; a patterning module; a development module; and a controller including one or more memory devices, one or more processors, and system control software coded with instructions including machine-readable instructions.

In some embodiments, the deposition module includes a chamber for depositing a radiation-sensitive film (e.g., an EUV-sensitive film), a radiation-absorbing layer, or an imaging layer. In other embodiments, the patterning module includes a photolithography tool with a source of sub-300 nm wavelength radiation (e.g., in which the source can be a source of sub-30 nm wavelength radiation). In yet other embodiments, the development module includes a chamber for developing the resist film.

In particular embodiments, the controller instructions include machine-readable instructions for (e.g., in the deposition module) causing deposition of a radiation-absorbing layer and an imaging layer on a top surface of a substrate to form a film (e.g., a radiation-sensitive film). In other embodiments, the controller instructions include machine-readable instructions for (e.g., in the patterning module) causing patterning of the film with sub-300 nm resolution (e.g., or with sub-30 nm resolution) directly by patterned radiation exposure, thereby forming an exposed film having radiation exposed areas and radiation unexposed areas. In yet other embodiments, the exposed film has EUV exposed areas and EUV unexposed areas. In particular embodiments, the controller instructions include machine-readable instructions for (e.g., in the development module) causing development of the exposed film to remove the radiation exposed areas or the radiation unexposed areas to provide a pattern within the resist film. In other particular embodiments, the machine-readable instructions include instructions for causing removal of the EUV exposed areas or the EUV unexposed areas.

In some embodiments, the machine-readable instructions for causing deposition of the absorbing layer and/or the imaging layer further include: instructions for causing deposition of an element having a high patterning radiation-absorption cross-section. In particular embodiments, the element has a high EUV absorption cross-section.

In some embodiments, the apparatus can further include: a cleaning module (e.g., including a chamber for cleaning the substrate or the film). In particular embodiments, the controller instructions include machine-readable instructions for (e.g., in the cleaning module) causing cleaning of a backside surface or a bevel of the semiconductor substrate after said deposition and/or causing removal of an edge bead of the film after said deposition.

In some embodiments, the apparatus can further include: a bake module. In particular embodiments, the controller instructions include machine-readable instructions for (e.g., in the bake module) causing baking of the film after said deposition and/or causing baking of the exposed film after said patterning.

In some embodiments, the apparatus can further include: an etch module. In particular embodiments, the controller instructions include machine-readable instructions for (e.g., in the etch module) causing etching or removing of the exposed film (e.g., removing of an exposed area or an unexposed area of the absorbing layer and/or the imaging layer) and/or the substrate (e.g., removing a portion of the substrate underlying an exposed area or an unexposed area of the absorbing layer) after said patterning.

In any embodiment herein, the absorbing layer and/or the imaging layer includes an EUV-sensitive film, a DUV-sensitive film, a UV-sensitive film, a photoresist film, a photopatternable film, or a photoresponsive adhesive film.

In any embodiment herein, the absorbing layer and/or the imaging layer includes a metal or an atom having a high patterning radiation-absorption cross-section. In particular embodiments, the metal or the atom includes a high EUV absorption cross-section. In other embodiments, the metal-containing layer includes tin (Sn), bismuth (Bi), tellurium (Te), cesium (Cs), antimony (Sb), indium (In), molybdenum (Mo), hafnium (Hf), iodine (I), zirconium (Zr), iron (Fe), cobalt (Co), nickel (Ni), copper (Cu), zinc (Zn), silver (Ag), platinum (Pt), or lead (Pb), as well as combinations thereof. In some embodiments, the absorbing layer and/or the imaging layer is a photosensitive layer.

In any embodiment herein, the precursor includes a metal or an atom having a high patterning radiation-absorption cross-section. In particular embodiments, the metal or the atom includes a high EUV absorption cross-section (e.g., equal to or greater than 1×10⁷ cm²/mol). In other embodiments, the precursor includes Sn, Bi, Te, Cs, Sb, In, Mo, Hf, I, Zr, Fe, Co, Ni, Cu, Zn, Ag, Pt, or Pb, as well as combinations thereof. In yet other embodiments, the precursor is a high photoabsorbing precursor (e.g., having a high Beer's absorption coefficient α, including an α of more than about 6 μm⁻¹ or other values described herein).

In any embodiment herein, said incorporating the absorbing layer and/or said providing the imaging layer includes providing one or more precursors. Non-limiting precursors include a structure having formula (I), (II), (IIa), (III), (IV), (V), (VI), (VII), or (VIII). In particular non-limiting embodiments, a precursor for the absorbing layer includes a structure having formula (I), (II), (III), (IV), (V), (VI), (VII), or (VIII). In other embodiments, a precursor for the imaging layer includes a structure having formula (II), (IIa), (VII), or (VIII).

In any embodiment herein, said incorporating the absorbing layer includes providing one or more precursors including an indium precursor (e.g., InR₃, as described herein), a tin precursor (e.g., SnR₂ or SnR₄, as described herein), a bismuth precursor (e.g., BiR₃, as described herein), an antimony precursor (e.g., SbR₃, as described herein), a tellurium precursor (e.g., TeR₂ or TeR₄, as described herein), or an iodine precursor (e.g., periodate or RI, as described herein).

In any embodiment herein, said providing the imaging layer includes providing one or more precursors (e.g., any described herein, such as those including a structure having formula (I) or (II)) in the presence of the counter-reactant. Non-limiting counter-reactants include an oxygen-containing counter-reactant, including oxygen (O₂), ozone (O₃), water, a peroxide, hydrogen peroxide, oxygen plasma, water plasma, an alcohol, a dihydroxy alcohol, a polyhydroxy alcohol, a fluorinated dihydroxy alcohol, a fluorinated polyhydroxy alcohol, a fluorinated glycol, formic acid, and other sources of hydroxyl moieties, as well as combinations thereof. Yet other non-limiting counter-reactants include a chalcogenide precursor having the formula ZR₂, wherein Z is sulfur, selenium, or tellurium; and wherein each R is, independently, H, optionally substituted alkyl (e.g., methyl, ethyl, n-propyl, isopropyl, n-butyl, t-butyl, etc.), optionally substituted alkenyl, optionally substituted aryl, optionally substituted amino, optionally substituted alkoxy, or optionally substituted trialkylsilyl.

In any embodiment herein, a single precursor is employed to deposit a layer (e.g., an absorbing layer or an imaging layer). In other embodiments, two or more different precursors are employed to deposit the layer.

In any embodiment herein, depositing includes providing or depositing the metal precursor(s) in vapor form. In other embodiments, depositing includes providing one or more counter-reactant(s) in vapor form. In particular embodiments, depositing includes CVD, ALD, or plasma-enhanced forms thereof.

In any embodiment herein, depositing of a layer further includes providing a counter-reactant. Non-limiting counter-reactants include an oxygen-containing counter-reactant or a chalcogenide precursor, including O₂, O₃, water, a peroxide, hydrogen peroxide, oxygen plasma, water plasma, an alcohol, a dihydroxy alcohol, a polyhydroxy alcohol, a fluorinated dihydroxy alcohol, a fluorinated polyhydroxy alcohol, a fluorinated glycol, formic acid, other sources of hydroxyl moieties, and ZR₂ (e.g., wherein Z is S, Se, or Te; and each R is, independently, H, optionally substituted alkyl, optionally substituted alkenyl, optionally substituted aryl, optionally substituted amino, optionally substituted alkoxy, or optionally substituted trialkylsilyl), as well as combinations thereof.

Other features and advantages of the invention will be apparent from the following description and the claims.

### BRIEF DESCRIPTION OF THE DRAWINGS

FIG. 1A-1B presents schematic diagrams of non-limiting patterning structures. Provided are (A) a structure having a substrate 101 and an imaging layer 102; and (B) a structure having a substrate 111, an imaging layer 112, and a radiation-absorbing layer 113 under the imaging layer 112.

FIG. 2 presents a schematic diagram of a non-limiting method that employs a radiation-absorbing layer 213 and an imaging layer 212.

FIG. 3 presents a schematic diagram of a non-limiting method that employs a radiation-absorbing layer 313 and a hardmask 315.

FIG. 4 presents a reaction scheme between a non-limiting first precursor (1) and a non-limiting second precursor (2).

FIG. 5 presents a schematic diagram of a non-limiting method for making and using a patterning structure.

FIG. 6 presents a schematic diagram of another non-limiting method for making and using a patterning structure.

FIG. 7A-7C presents non-limiting patterning structures. Provided are (A) a structure having a substrate 711, an imaging layer 712, and a radiation-absorbing layer 713 under the imaging layer 712, (B) an image of a non-limiting patterning structure; and (C) a schematic of a non-limiting method.

FIG. 8 presents a non-limiting graph showing extreme ultraviolet (EUV) photoabsorption cross-sections of various elements. Asterisks (*) denote non-limiting elements having high EUV photoabsorption cross-sections; and number signs (#) denote non-limiting elements that are radioactive. Absorption of EUV light (92 eV, 13.5 nm) associated with excitation of inner shell electrons can have little dependence on chemical bonding.

FIG. 9 presents a schematic illustration of an embodiment of a process station 900 for dry development.

FIG. 10 presents a schematic illustration of an embodiment of a multi-station processing tool 1000.

FIG. 11 presents a schematic illustration of an embodiment of an inductively coupled plasma apparatus 1100.

FIG. 12 presents a schematic illustration of an embodiment of a semiconductor process cluster tool architecture 1200.

FIG. 13 depicts a cross-sectional schematic view of an example of a dry deposition apparatus 1300.

FIG. 14 depicts detail side section and plan views of a portion of a top plate, substrate, and edge ring.

### DETAILED DESCRIPTION

Reference is made herein in detail to specific embodiments of the disclosure. Examples of the specific embodiments are illustrated in the accompanying drawings. While the disclosure will be described in conjunction with these specific embodiments, it will be understood that it is not intended to limit the disclosure to such specific embodiments. On the contrary, it is intended to cover alternatives, modifications, and equivalents as may be included within the spirit and scope of the disclosure. In the following description, numerous specific details are set forth in order to provide a thorough understanding of the present disclosure. The present disclosure may be practiced without some or all of these specific details. In other instances, well known process operations have not been described in detail so as to not unnecessarily obscure the present disclosure.

Patterning of thin films in semiconductor processing is often an important step in the fabrication of semiconductors. Patterning involves lithography. In conventional photolithography, such as 193 nm photolithography, patterns are printed by emitting photons from a photon source onto a mask and printing the pattern onto a photosensitive photoresist, thereby causing a chemical reaction in the photoresist that, after development, removes certain portions of the photoresist to form the pattern.

Advanced technology nodes (as defined by the International Technology Roadmap for Semiconductors) include nodes 22 nm, 16 nm, and beyond. In the 16 nm node, for example, the width of a typical via or line in a Damascene structure is typically no greater than about 30 nm. Scaling of features on advanced semiconductor integrated circuits (ICs) and other devices is driving lithography to improve resolution.

Extreme ultraviolet (EUV) lithography can extend lithography technology by moving to smaller imaging source wavelengths than would be achievable with conventional photolithography methods. EUV light sources at approximately 10-20 nm, or 11-14 nm wavelength, for example 13.5 nm wavelength, can be used for leading-edge lithography tools, also referred to as scanners. The EUV radiation is strongly absorbed in a wide range of solid and fluid materials including quartz and water vapor, and so operates in a vacuum.

Traditional organic chemically amplified resists (CAR) have a few drawbacks when used in EUV lithography, particularly low absorption coefficient in EUV region and acid diffusion of photo-activated chemical species. To overcome the low absorption coefficient, a relatively thick CAR film is necessary, but at the risk of pattern collapse. Moreover, the broad clearing radius during the acid diffusion process leads to relatively high line roughness in patterned CAR films. Quenchers may be used to reduce the acid diffusion radius, but at the cost of decreased sensitivity. As such, the lithographic performance of current CARs is unable to reach the desired EUV lithographic performance.

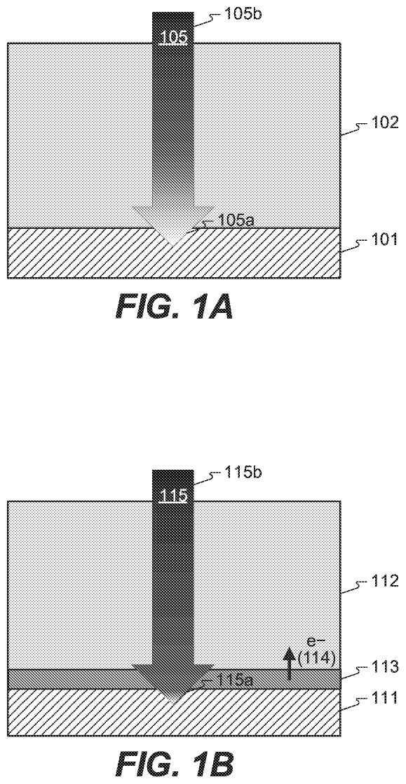

Directly photopatternable EUV resists containing metals and/or metal oxides mixed within organic components show promise in that they can enhance the EUV photon absorption and generate secondary electrons and/or show increased etch selectivity to an underlying film stack and device layers. Organometallic resists, such as are available from Inpria Corp., Corvallis, Oreg., have a substantially higher absorption coefficient and can be significantly thinner while still providing good etch resistance. Currently, all commercially available EUV photoresists for high-resolution patterning applications are solution-based (wet) spin-on formulations. However, spin-on formulations generally result in spatially homogenous films which can suffer from depth-dependent EUV dose concerns; once a material starts absorbing around 30% or more of the incident EUV photons there are unavoidably fewer photons making it to the bottom of the film to induce the chemical effects required to permit selective development. This concept is illustrated in FIG. 1A-1B, as further described herein. Another potential drawback of spin-on formulations can be the instability of solutions and/or variations in film properties due to environmental variables during spin coating.

Dry deposition of metal-organic based resists has also been described, for example in prior International Application PCT/US19/31618, published as International Pub. No. WO2019/217749, filed May 9, 2019, and titled METHODS FOR MAKING EUV PATTERNABLE HARD MASKS, the disclosure of which relating to the composition, deposition, and patterning of directly photopatternable metal-organic based metal oxide films to form EUV resist masks is incorporated by reference herein. In most or all of these metal-organic based resists, other than the metal center (mostly Sn), all other elements have low EUV absorption cross-section. The introduction of other, highly-EUV-absorbing, elements into the resist either as an alternative metal center or as part of the counter-reactant or by substitution of fluorine or iodine for hydrogen on the organic groups that can further increase the EUV absorption in the PR and thus further reduce the EUV dosage required for patterning, and our prior work has explored these possibilities.

Further improvement in EUV lithographic organometallic resist performance is contemplated by increasing the sensitivity, reducing the line edge roughness, and/or improving the resolution, captured in a term referenced herein as “z-factor”. The present disclosure addresses the underlayer of the organometallic resist film, outlining methods to improve the sensitivity of these resists through the incorporation of elements with high EUV absorption under the photoactive layer of the film to increase the EUV absorptivity and patterning performance of EUV photoresists. Described compositions, structures, and methods may be applicable to both dry deposited organometallic photoresist strategies as well as other competitive strategies such as CARs and spin-on metalorganic films.

### Patterning Structures

The patterning structures (or films) herein can include an imaging layer on a surface of the substrate and a radiation-absorbing layer under the imaging layer. In particular embodiments, the presence of the radiation-absorbing layer provides increased radiation absorptivity and/or patterning performance of the imaging layer.

Generally, photon absorption through a layer is depth dependent. When a homogenous layer or film is exposed to radiation, the lower portion of the layer is exposed to a lower dose of radiation, as compared to the upper portion of that same layer, because fewer photons reach that lower portion. Thus, to ensure sufficient and uniform exposure through the entire depth of a layer, the layer must provide sufficient transmission of the radiation. As seen in FIG. 1A, a homogenous imaging layer 102 is disposed on a top surface of a substrate 101. Upon exposure to radiation, photoabsorption 105 through the homogenous layer is depth dependent and has a lower value 105a towards the substrate (and in the lower portion of the layer 102) and a higher value 105b away from the substrate (in the upper portion of the layer 102).

By using a radiation-absorbing layer below the imaging layer, radiation absorption can be increased through the imaging layer. For instance, by providing an absorbing layer having an increased density of atoms with high EUV absorptivity at the bottom of the film, relative to the imaging layer, it becomes possible to more efficiently utilize available EUV photons while more uniformly distributing absorption (and the effects of secondary electrons) towards the bottom of the patterning structure. Furthermore, in some instances, the absorbing layer can effectively generate more secondary electrons that can better expose lower portions of the patterning structure.

As seen in FIG. 1B, a patterning structure can include an imaging layer 112, as well as a radiation-absorbing layer 113 under the imaging layer 112 and above a substrate 111. As compared to a structure lacking the absorbing layer, photoabsorption between the lower portion 115a and upper portion 115b of the layer 112 can be more uniform. Upon exposure to radiation, photoabsorption 115 through the layers is influenced by the absorbing layer 113, which can result in the generation of additional secondary electrons 114 that can assist in radiation exposure of the bottom of the imaging layer. In this way, photoabsorption 115 can be improved, as compared to photoabsorption in an imaging layer lacking the absorbing layer.

The absorbing layer can include an element (e.g., a metal atom or a non-metal atom) having a high photoabsorption cross-section (or a high-absorbing element), such as I, In, Sn, Sb, Bi, and/or Te. Such elements can be provided as a layer in any useful manner, such as by sputter deposition, physical vapor deposition (PVD) including PVD co-sputtering, chemical vapor deposition (CVD), plasma enhanced CVD (PE-CVD), low pressure CVD (LP-CVD), atomic layer deposition (ALD, (e.g., thermal ALD and plasma-enhanced ALD (PE-ALD)), spin-coat deposition, plasma-based deposition, thermal-induced decomposition, plasma-induced decomposition, electron-beam (e-beam) deposition including e-beam co-evaporation, etc., or a combination thereof, with one or more precursors (e.g., any described herein). The absorbing layer can be a photoresist layer or a surface modification layer disposed on a surface of the substrate.

One or both of the absorbing layer and the imaging layer can include a high-absorbing element. In one instance, the absorbing layer and the imaging layer both include a high-absorbing element. The element in each of the absorbing and imaging layers can be the same or different.

In particular non-limiting instances, the absorbing layer is characterized by having an increased radiation absorptivity, as compared to the imaging layer. For instance, the absorbing layer can include a higher fraction of EUV-absorbing species that are not bonded to bulky, terminal substituents. In another instance, the absorbing layer can include an element having a higher absorption coefficient than the element that is present in the imaging layer. For example, the imaging layer can include Sn, and the absorbing layer can include Te (e.g., Te alone or a mixture of Te and Sn). In yet another instance, the concentration of a high-absorbing element is higher in the absorbing layer than in the imaging layer.

The absorbing layer can provide other functionalities, in addition to modulating photon or radiation absorption. In one instance, the absorbing layer can be a photoresponsive adhesion layer, in which exposure to radiation can enhance adhesion to the overlying imaging layer. Prior to radiation exposure, a top surface of the absorbing layer can include a labile moiety that is cleavable under exposure to the patterning radiation. Upon exposure, the labile moiety can provide a reactive center, which then participates in the formation of a covalent bond between the absorbing layer and the imaging layer. In this way, the top surface of the absorbing layer can be characterized as a photoresponsive surface, and the absorbing layer itself can be characterized as a photoresponsive adhesion layer.

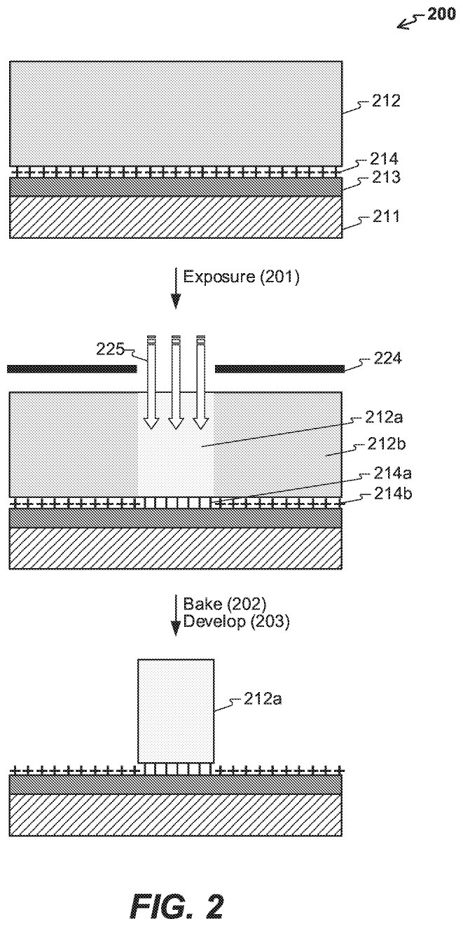

FIG. 2 provides a non-limiting method 200 of using a patterning structure having a photoresponsive adhesion layer. The non-limiting patterning structure can include a substrate 211, an imaging layer 212, and an absorbing layer 213 under the imaging layer 212. As can be seen, also present is a photoresponsive surface 214 atop the absorbing layer 213. The patterning structure including such layers can be formed in any useful manner, as described herein. In one embodiment, the imaging layer is a radiation-sensitive imaging layer, an EUV-sensitive film, or a photoresist layer.

In operation 201, the patterning structure is exposed to a patterned radiation exposure to provide an exposed film having radiation exposed area(s) 212a and radiation unexposed area(s) 212b, in which patterning can include use of a mask 224 having radiation transparent region(s) and radiation opaque region(s) and in which radiation beams 225 are transmitted through the radiation transparent region, into the imaging layer 212, and further into the absorbing layer 213.

Radiation can also pattern the photoresponsive surface 214 of the absorbing layer 213. As can be seen, the photoresponsive surface includes radiation exposed area(s) 214a and radiation unexposed area(s) 214b. In radiation exposed area(s) 214a, enhanced adhesion is provided between the imaging layer 212 and the absorbing layer 213. In particular embodiments, enhanced adhesion can lower the required radiation dose to provide desired patterned features within the imaging layer and/or the absorbing layer.

Optionally, in operation 202, the exposed layers can be baked, which can further promote bonding between the absorbing and imaging layers and/or increase contrast in etch selectivity of the exposed layer(s). Developing 203 the patterning structure can result in selectively removing the radiation unexposed area(s) 212b and maintaining the radiation exposed area(s) 212a of the imaging layer 212. The resulting patterning structure can include an exposed portion 212a of an imaging layer, an underlying patterned absorbing layer 213, and a substrate 211. Optionally, such developing can result in selectively removing portions of the absorbing layer 213, such as selectively removing the radiation unexposed area(s) 214b and maintaining the radiation exposed area(s) 214a of the imaging layer 214.

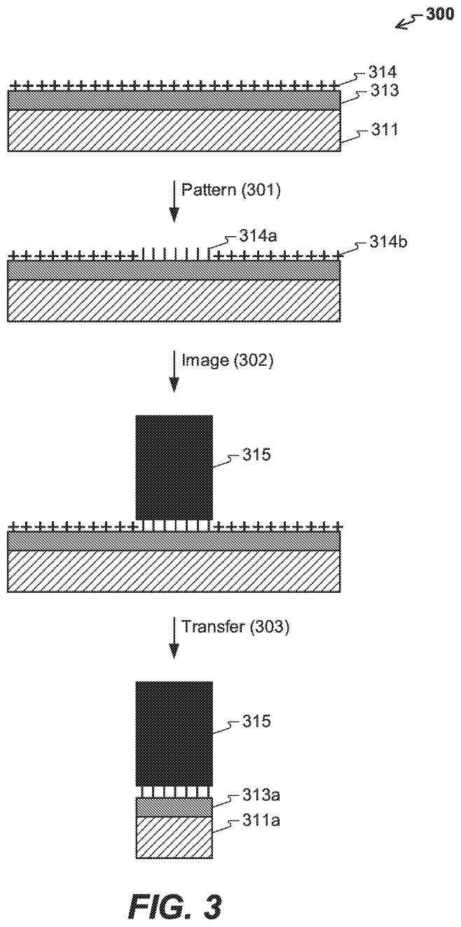

FIG. 3 provides a non-limiting method 300 of making a patterning structure having a photoresponsive adhesion layer. Such a method 300 can include providing a substrate 311 having an absorbing layer 313 disposed on a surface of the substrate 311.

In operation 301, the photoresponsive surface 314 of the absorbing layer 313 is patterned to provide a patterned absorbing layer. As can be seen, the photoresponsive surface 314 can include radiation exposed area(s) 314a and radiation unexposed area(s) 314b. Such patterning can include exposing the photoresponsive surface to a patterned radiation exposure, thereby releasing the labile moiety from the surface and providing a reactive center. In particular embodiments, the reactive center can provide a surface having enhanced nucleation for deposition of the imaging layer, as compared to the radiation unexposed area. Optionally, the reactive center can be treated (e.g., by oxidation or by reaction with air, water, or a counter-reactant described herein) to provide a further reactive center that provides enhanced nucleation. Non-limiting reactive centers and further reactive centers can include M-H bonds or M-OH bonds, in which M is a metal. Optionally, the patterned absorbing layer can be baked, which can further promote bonding between the absorbing and imaging layers and/or increase contrast in etch selectivity of the exposed layer(s).

In operation 302, further surface imaging on the absorbing layer can provide a hardmask 315. Surface imaging can include selective deposition on the radiation exposed area(s) 314a of the absorbing layer. Such selective deposition can include selective ALD, selective CVD, selective electroless deposition (ELD), selective deposition of a polymer, directed self-assembly (DSA) of a block co-polymer (BCP), or directed self-assembly of a sol-gel, as described herein.

In operation 303, further processing can provide a patterning structure including the hardmask 315, an etched substrate 31 la, and an etched absorbing layer 313a. After deposition of the hardmask 315, further steps can include etching of the underlying absorbing layer and substrate, such as by using an oxygen plasma.

The present disclosure encompasses any method that employs a patterning structure having an absorbing layer, in which such methods those of making and/or using such structures. In one embodiment, a method of making a patterning structure includes: providing a substrate to receive a pattern; incorporating an absorbing layer on a top surface of the substrate; and providing an imaging layer, wherein the absorbing layer underlies the imaging layer to increase radiation absorptivity and/or patterning performance of the imaging layer.

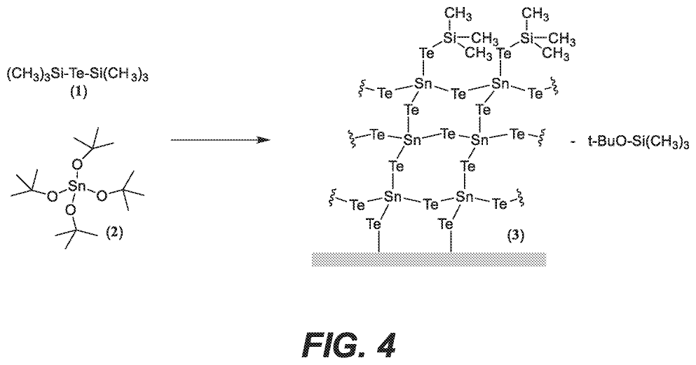

The absorbing layer can include a high-absorbing element, which can be deposited by using one or more precursors (e.g., any described herein). The absorbing layer can include predominantly high-absorbing elements. In one embodiment, the absorbing layer includes I, In, Sn, Bi, Sb, Te, or a combination thereof. In another embodiment, a single precursor is employed. In yet another embodiment, two or more precursors are employed. Optionally, the precursor(s) is employed with one or more counter-reactants, as described herein. Deposition can include, e.g., ALD or CVD. As seen in FIG. 4, the absorbing layer can include use of a non-limiting Te-based precursor (e.g., bis(trimethylsilyl)tellurium, 1) and a non-limiting organotin precursor (e.g., tetra(t-butoxy)tin, 2) to provide a SnTe material (3) having a trimethylsilyl surface, which can be further reacted (e.g., with a counter-reactant or an alcohol) to remove silyl groups.

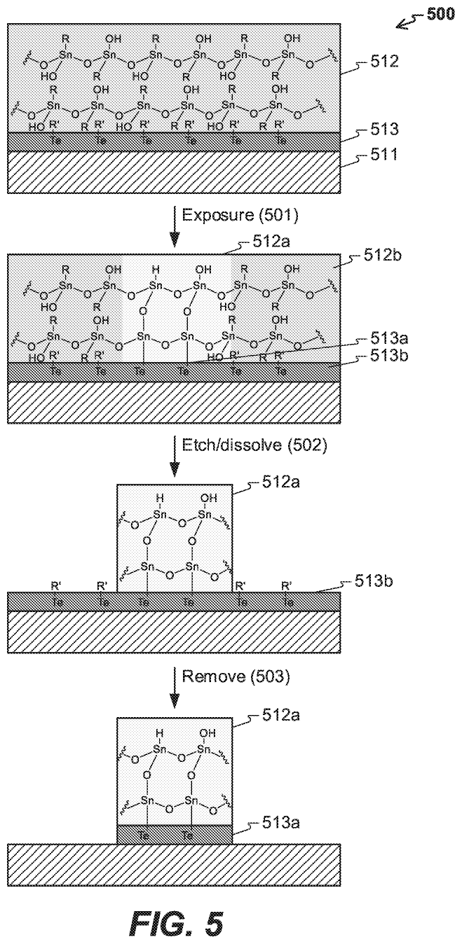

The surface of the absorbing layer can include a labile moiety, such as halo, alkyl (e.g., a branched alkyl), haloalkyl, or any described herein as R for formula (I) or (II). FIG. 5 shows a method 500 employing a non-limiting patterning structure including a substrate 511, an absorbing layer 513 disposed on a top surface of the substrate 511, and an imaging layer 512. The non-limiting absorbing layer includes Te having a labile moiety R′, and the non-limiting imaging layer includes a tin oxide film having a labile moiety R.

The labile moiety R′ can provide a passivated surface, which can be activated upon exposure to radiation. In operation 501, the patterning structure is exposed to a patterned radiation exposure to provide an exposed film having radiation exposed area(s) 512a and radiation unexposed area(s) 512b in the imaging layer 512, as well as radiation exposed area(s) 513a and radiation unexposed area(s) 513b in the absorbing layer 513. Due to radiation exposure, the labile moieties R and R′ are removed or cleaved, thus providing metal reactive centers, i.e., Sn in the imaging layer 513 and Te in the absorbing layer 514, that can react to form a metal-metal (M-M) bond (here, a Sn—Te bond). In the imaging layer, radiation-induced cleavage of the Sn—R bond in the organotin oxide layer also induces consolidation to provide a more condensed metal oxide (tin oxide) network in the radiation exposed area(s).

In operation 502, the unexposed area(s) of the imaging layer are etched or dissolved, thereby releasing a structure having the exposed portion 512a of the imaging layer and providing a pattern. Such etching can include dry etching, e.g., using halide chemistry described herein. In operation 503, the unexposed area(s) of the absorbing layer are removed, thereby providing a patterning structure having the exposed portion 513a of the absorbing layer. Such removing can include dry etching, e.g., using halide chemistry described herein, or plasma etching (e.g., with CH₄- or F-based plasma, including NF₃, CF₄, etc.).

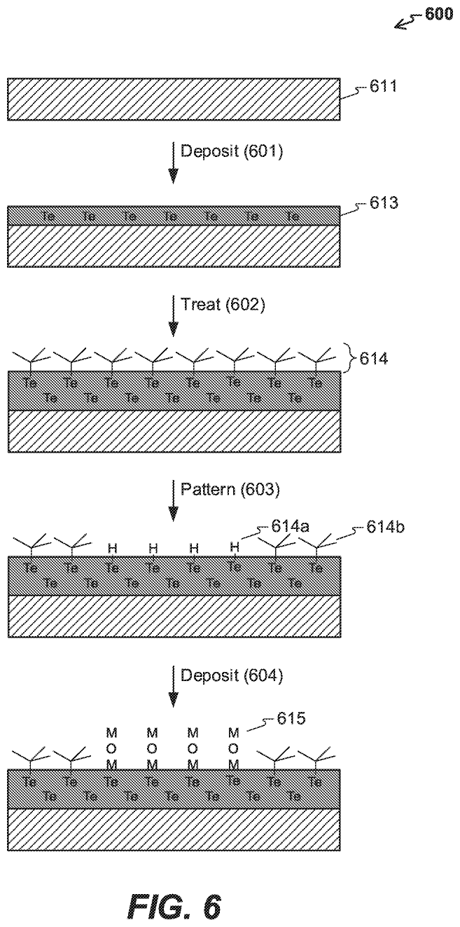

FIG. 6 provides another use for an absorbing layer including Te and a labile moiety, e.g., t-butyl. The non-limiting method 600 includes providing a substrate 611 (e.g., an ashable hardmask carbon underlayer). In operation 601, a thin absorbing layer 613 is deposited, in which absorbing layer includes or consists of Te. A non-limiting thickness of the absorbing layer is about 3 to 5 nm. In operation 602, the surface of the absorbing layer is treated with an organometallic precursor having a high-absorbing element (e.g., Te) and a labile moiety (e.g., t-butyl). Non-limiting precursors including Te and t-butyl (t-Bu) can be (t-Bu)TeH or (t-Bu)₂Te.

In operation 603, the surface 614 of the absorbing layer 613 is patterned with a patterning radiation (e.g., EUV radiation) to provide an exposed area 614a and an unexposed area 614b. The labile moiety is released by EUV-induced cleavage. For instance, when the labile moiety is 1-butyl, isobutylene is released after cleavage of that moiety from the absorbing layer.

The radiation-exposed areas can provide enhanced deposition of a material, thereby providing selective deposition of the material on the patterned surface. In one instance, the exposed areas include an acidic group, such as a M-H bond or an M-OH bond, which can initiate selective growth or deposition of a metal oxide material. As can be seen, in operation 604, a metal (M)-oxygen (O) containing material 615 can be selectively deposited on the exposed area 614a. Such materials can be deposited by using a metal oxide (MOx) precursor and an oxygen-containing precursor (e.g., water vapor or a counter-reactant described herein), which can be delivered alternately and repeatedly.

### Substrate Preparation

An incoming wafer can be prepared with a substrate surface of a desired material, with the uppermost material being the layer into which the resist pattern is transferred. While the material selection may vary depending on integration, it is generally desired to select a material which can be etched with high selectivity to (i.e., much faster than) the EUV resist or imaging layer. Suitable substrate materials can include various carbon-based films (e.g., ashable hardmask (AHM), silicon-based films (e.g., SiOx, SiCx, SiOxCy, SiOxNy, SiOxCyNz), a-Si:H, poly-Si, or SiN), or any other (generally sacrificial) film applied to facilitate the patterning process). In cases where there are device features present on the substrate to be patterned which create significant topography, another important function of the underlayer can be to overcoat and planarize the existing topography so that the subsequent patterning step may be performed on a flat surface with all areas of the pattern in focus. For such applications, the underlayer (or at least one of multiple underlayers) is generally applied using spin-coating techniques. When the photoresist material being employed possesses a significant inorganic component, for example it exhibits a predominately metal oxide framework, the underlayer may advantageously be a carbon-based film, applied either by spin-coating or by dry vacuum-based deposition processes. The layer may include various AHM films with carbon- and hydrogen-based compositions, and may be doped with additional elements such as tungsten, boron, nitrogen, or fluorine.

In some embodiments, a substrate comprising exposed hydroxyl groups comprises a surface layer or film comprising hydroxyl-terminated SnOₓ. For example, the substrate may comprise amorphous carbon having a surface of hydroxyl-terminated SnOₓ. Without limiting the mechanism, function or utility of present technology, it is believed that the hydroxyl-terminated SnO, layer may offer benefits such as improved adhesion of materials deposited on the surface of the substrate and enhanced absorption of EUV (or other radiation) during patterning. Sensitivity to EUV or other irradiation and resolution may be dependent on the properties of the SnO, layer, such as thickness, density and short-range charge transfer characteristics. In various embodiments, the SnO, layer has a thickness of from 0.1 nm to 20 nm, or from 0.2 nm to 10 nm, or from 0.5 nm to 5 nm.

In some embodiments, the hydroxyl-terminated SnO, layer is deposited on the surface of the substrate by vapor deposition. In such methods, the deposition comprises reacting Sn—Xₙ with an oxygen-containing counter-reactant, wherein X is a ligand such as dialkylamino, (e.g., dimethylamino, methylethylamino, and diethylamino), alcohol (e.g., t-butoxy, and isopropoxy), halogen (e.g., F, Cl, Br, and I), or other organic substituent (e.g., acetylacetone, N2,N3-di-tertbutyl-butane-2,3-diamino). For example, Sn—Xₙ may be SnCl₄, SnI₄, or Sn(NR₂)₄ wherein R is methyl or ethyl, or Sn(t-BuO)₄. In some embodiments, multiple types of ligands are present. The oxygen-containing counter-reactant may be selected from the group consisting of water, hydrogen peroxide, formic acid, alcohols, oxygen, ozone, and combinations thereof.

Suitable vapor deposition processes include chemical vapor deposition (CVD), atomic layer deposition (ALD), plasma-enhanced chemical vapor deposition (PECVD), or plasma-enhanced atomic layer deposition (PEALD). In some embodiments, the deposition is ALD, in a cyclical process of depositing the Sn—Xₙ and depositing the oxygen-containing counter-reactant. In some embodiments, the deposition is CVD, by simultaneously flowing the Sn—Xₙ and the oxygen-containing counter-reactant. Materials and processes among those useful herein for depositing SnO, layers are described in Nazarov et al., Atomic Layer Deposition of Tin Dioxide Nanofilms: A Review, 40 Rev. Adv. Mater. Sci. 262 (2015). A SnO, substrate may be deposited by a CVD or ALD process, as described herein.

A surface activation operation may be used to activate the surface for future operations. For example, for a SiOx surface, a water or oxygen/hydrogen plasma may be used to create hydroxyl groups on the surface. For a carbon- or hydrocarbon-based surface, a water, hydrogen/oxygen or CO₂ plasma or ozone treatment may be used to create carboxylic acids/or hydroxyl groups. Such approaches can prove critical for improving the adhesion of resist features to the substrate, which might otherwise delaminate or lift off in the solvent used for development.

Adhesion may also be enhanced by inducing roughness in the substrate surface to increase the surface area available for interaction, as well as directly improve mechanical adhesion. For example, first a sputtering process using Ar or other non-reactive ion bombardment can be used to produce rough surfaces. Then, the surface can be terminated with a desired surface functionality as described above (e.g., hydroxyl and/or carboxylic acid groups). On carbon, a combination approach can be employed wherein a chemically reactive oxygen-containing plasma such as CO₂, O₂, H₂O (or mixtures of H₂ and O₂) can be used to etch away a thin layer of film with local non-uniformity and simultaneously terminate with —OH, —OOH, or —COOH groups. This may be done with or without bias. In conjunction with the surface modification strategies mentioned above, this approach could serve the dual purpose of surface roughening and chemical activation of the substrate surface, either for direct adhesion to an inorganic metal-oxide based resist or as an intermediate surface modification for further functionalization.

### Deposition of a EUV Enhancement Layer

### Implementation 1: Deposition of Material for Increased EUV Photon Absorption

Once the substrate is prepared, for example via surface modification as described above, the wafer can be brought into a processing chamber for deposition of a material to enhance EUV sensitivity. This will allow elements exhibiting very high EUV absorptivity to be incorporated onto the surface. Following the deposition of an EUV absorption-enhancing layer, an EUV-sensitive imaging layer such as a dry-deposited organometallic layer, a spin-coated organometallic layer, or a chemically amplified resist can be deposited on the wafer. Upon exposure, some of the EUV photons that pass through the EUV-sensitive imaging layer may be absorbed by the high EUV absorbing enhancement layer, generating secondary electrons. The secondary electrons may interact with the EUV-sensitive imaging layer, promoting reactions in the EUV films. In this way, such as conceptually depicted in FIG. 1A-1B, there is an enhanced sensitivity and usage of the EUV photons for the film stack. The surface modification, deposition of the EUV absorbing layer, and deposition of the EUV resist may occur in the same chamber or separate chambers.

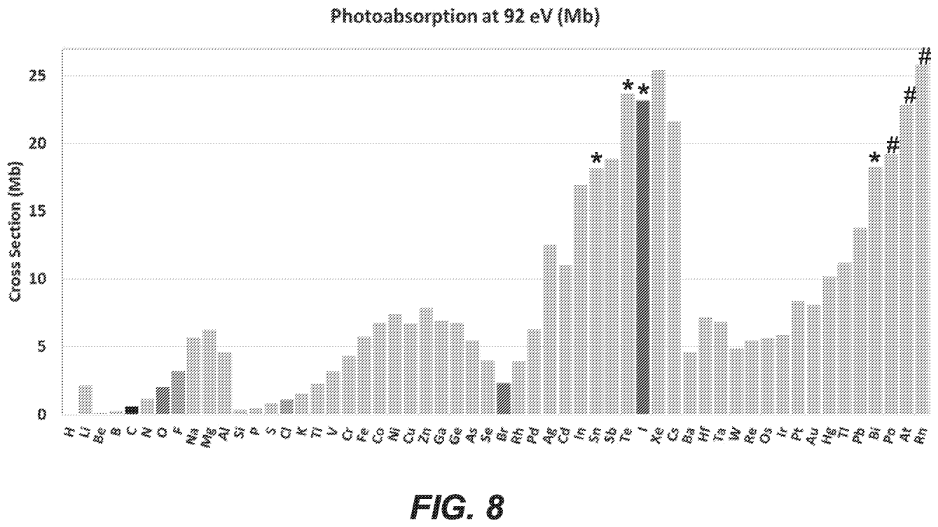

The advantage of the deposition of an enhancement layer may be observed with any element with higher EUV cross-section than the substrate. Most typically employed carbon-based underlayers have relatively low EUV cross-sections. Hence, a wide variety of elements may be appropriate for surface modification. Some particularly suitable elements are those exhibiting the high EUV absorption cross-section and which can be effectively be removed using dry etch processes, including In, Sn, Sb, Te, I, Pb, and Bi (see FIG. 8). Alloys and oxides and other compounds of these elements may also be utilized.

The thickness of the EUV enhancing layer will vary depending on integration scheme. A resulting substrate surface modified layer can be very thin, ranging from 0.3 nm to 5 nm, since secondary electrons generated deeper than 5 nm are less likely to penetrate up through the film and into the resist layer. However, any EUV absorbing underlayer that can be etched with high etch selectivity to the photoresist film can also be applied much thicker, and, in some cases, this can prove advantageous if etch chemistries exist to allow underlayer device layers to be selectively removed using the underlayer film as an etch mask.

Significant enhanced EUV absorption has also been achieved in many organic based formulations through substitution C—H bonds by C—F bonds, for example. While this disclosure is not limited by any particular theory of operation, apart from increasing EUV absorption, it is understood that C—F bond-containing compounds may generate secondary electrons upon EUV exposure, that in turn may liberate F anions, providing another potential mechanism for EUV induced changes in solubility or dry etch rate.

One method to achieve a surface modification is through the use of a reactive species containing an EUV-absorbing element. In some iterations, a vapor of the reactive species may be passed over the wafer. The wafer may be heated to provide thermal energy for the reaction to proceed. In some iterations, the heating can be between 50-250° C. In some cases, pulses of the reactant may be used, separated by pump and/or purging steps. In some cases, a counter-reactant may be pulsed between the reactant pulses resulting in ALD or ALD-like growth. In other cases, both the reactant and the counter-reactant may be flowed at the same time. Examples of elements useful for surface modification include I, F, Sn, Bi, Sb, Te, and oxides or alloys of these compounds.

Some examples of surface modification according to this technique include evaporation/sublimation of either pure elements or any sufficiently volatile compound of them. Coatings may also be applied by various sputtering or physical vapor deposition techniques.

Atomic layer deposition (ALD) techniques may also be advantageously used to controllably apply such thin films. In this way, thin, highly EUV absorbing layers of tin-, antimony-, or bismuth telluride may be deposited using alternating flows of various volatile metal alkoxide based precursors together with bis(trimethylsilyl)tellurium. An example of this is illustrated for the deposition of thin films of SnTe₂ in FIG. 4. A particular advantage of such a process is the ability to fine tune the interface to maximize adhesion to an inorganic metal oxide-based resist overlayer.

Another method that may be applied to achieve surface modification according to this disclosure is through plasma techniques. A plasma may be struck such that the reactive species within the plasma reacts with the surface to deposit highly EUV-absorbing elements. The plasma may be a remote plasma or a direct plasma.

Some examples of these plasma techniques include a plasma-deposited ashable carbon hardmask (AHM) film modified by exposure to a plasma generated in a flow of iodine vapor in an inert carrier gas. I₂ plasma can be used to create reactive I₂ or atomic I species that can break surface C—C bonds and insert themselves to create C—I functionality at the surface. Such a plasma strategy can be applicable both to diamond-like carbon film, which contains mostly C—C single bonds, as well as materials containing double bonds between carbon atoms. Alternatively, a thin iodine-rich layer can be grafted onto the surface by exposure to a plasma discharge generated in a flow of di-iodomethane/He or other iodinated hydrocarbon over the wafer surface.

Alternatively, a thermal, chemical reaction, or plasma-induced decomposition of a volatile organometallic precursor can be employed to generate films with a predominately elemental composition. For example, a thin tellurium-rich film may be deposited by the thermal decomposition of bis(t-butyl)tellurium on an AHM carbon film heated to 250° C. Alternatively, an RF plasma can be ignited in a flow of bis(t-butyl)tellurium and H₂ or He causing a tellurium-rich layer to deposit onto the surface of an AHM film. Similarly, such a layer can be deposited by a chemical vapor deposition reaction between bis(trimethylsilyl)tellurium and water vapor. In yet another example, a thin Sn-rich film may be formed by generating a plasma in a mixture containing a tin precursor such as tetrakis(dimethylamino)tin or tetra(isopropyl)tin, resulting in a Sn-containing species bonded to the surface through the loss of one or more of the dimethylamino or isopropyl ligands.

Implementation 2: Deposition of Material for Enhanced EUV Photon Absorption with Responsive Surface Adhesion

In a second implementation, a material can be deposited that will modify the surface to both enhance the EUV photo absorption and provide photo-responsive, tailorable surface adhesion to an EUV-sensitive imaging layer. Examples of this approach are depicted in FIG. 2 and FIG. 5. The modification process can leave a surface terminated with EUV-labile groups such as alkyl groups (e.g., i-butyl, n-butyl, sec-butyl, i-propyl, etc.) or fluorine substituted alkyl groups, such as —CF₃, —CF₂CF₃, for example. Following the EUV-absorbing layer application, the EUV-sensitive imaging layer such as a dry-deposited organometallic layer, a spin-coated organometallic layer, or a chemically amplified resist can be deposited on the wafer. The depositions may occur in the same chamber or in separate chambers, although having the chambers integrated may be advantageous on surfaces that are air reactive upon removal from vacuum.

According to this implementation, the substrate can be modified such that it will absorb additional EUV photons and create secondary electrons. These secondary electrons can then go into the EUV-sensitive imaging layer to cause further exposure in the film, thus increasing the efficiency of harvesting EUV photons. In addition, this layer can allow for tuning of the adhesion of EUV-sensitive imaging layer to the modified surface such that exposed regions have improved adhesion over unexposed regions. This effect is particularly pertinent to enhancing the performance of negative tone acting resists, where it is the exposed areas which become insoluble and remain behind after development.

An example of this implementation for a dry-deposited organometallic EUV resist follows: alkyl groups present on the surface in EUV irradiated areas can undergo a beta-hydrogen elimination such that the alkyl groups are removed, leaving M-H groups on the interface. These groups may be converted to M-OH groups upon exposure to oxygen and moisture. During the exposure or subsequent post exposure bake steps, some of these groups may react with hydroxyl groups either already present in the film or generated by EUV induced reactions in the resist film, creating strong bonds between the exposed resist film and the substrate. A post exposure bake may further enhance the adhesion and increase the number of cross-linking points. This adhesion difference can assist in selectively removing unexposed regions as desired in a negative tone resist. Spin-coated organic or metal-organic resists may also benefit by similar mechanisms.

The underlayer composition may vary. Candidate EUV absorbers include In, Sn, Sb, Te, Pb, Bi, and their alloys or compounds including with other elements not listed. The EUV-labile groups may also vary, but include alkyl groups CₙH₂ₙ₊₁, preferably wherein n≥3, and include fluorine substituted alkyl groups. The underlayer may be deposited by either a wet or dry process. Some exemplary methods for making these layers include the following:

ALD or CVD oxide with alkyl group termination: A thin metal oxide or metal may be deposited by ALD or CVD. Examples include SnOx, BiOx, and Te. Following deposition, the film may be capped with an alkyl substituted precursor of the form MRₓL_{y} where M is a metal preferably with high EUV absorption, R is an alkyl or fluoroalkyl group, L is a ligand that reacts with the surface of the thin metal oxide or metal, x is an integer equal to or greater than 1 and y is an integer equal to or greater than 1. A counter-reactant may be used to better remove the ligands and multiple cycles may be repeated to ensure complete saturation of the substrate surface. The surface is then ready for the EUV-sensitive imaging layer to be deposited. One possible method is to produce a thin film of SnOx. Possible chemistries include growth of SnO₂ by cycling tetrakis(dimethylamino)tin and a counter-reactant such as water or O₂ plasma. After the growth, a capping agent could be used. For example, isopropyltris(dimethylamino)tin vapor may be flown over the surface.

Plasma-assisted processes with in situ capping, such as an alkyl-terminated Sn interface modification: One approach involves the deposition of a thin metallic Sn or Sn alloy based film on the surface of the substrate underlayer. The vapor of an alkyl organometallic Tin precursor can be flown into the chamber. The alkyl tin precursor may have the form of SnR₂ or SnR₄, depending on the Sn oxidation state. The alkyl group can be CₙH₂ₙ₊₁, where n is generally greater than or equal to 2. Examples include tetraisopropyltin and tetra(t-butyl)tin. Precursor vapors can be entrained in a suitable carrier gas (for example H₂, He, Ar, or N₂) and flown into the chamber, and an RF plasma ignited between the wafer and showerhead. The result is the deposition of a film with a basic composition resembling elemental Sn. The power of the plasma may be adjusted throughout the deposition, and possibly ramped down at the end. The plasma power is then stopped, but the alkyl tin precursor is still flown. The result can be a tin underlayer capped with alkyl groups. A resist such as a metalorganic resist can then be deposited on top of the modified layer and brought into an EUV scanner for exposure. Upon EUV exposure, the alkyl groups of the modified interface can undergo a beta-hydrogen elimination, resulting in the formation of Sn—H bonds at the interface. At this stage, or during the post exposure bake, the Sn—H bonds may react with the resist to form Sn—O—Sn bridges across the interface, effectively increasing the adhesion of the film in the exposed region.

Alkyl-terminated Te interface modification: Similar to the process described for alkyl-terminated Sn interface modification, an organotellurium precursor can be employed to deposit a thin predominately Te composition film providing high EUV absorptivity. The organo-Te precursor may have the form of RTeH or R₂Te, where R is an alkyl group or a ligand molecule. The alkyl group may be CₙH₂ₙ₊₁, where n is greater than or equal to 3. Examples include t-butyl tellurium hydride, di(t-butyl) tellurium, di(isopropyl)tellurium, or bis(trimethylsilyl)tellurium. Typical diluent gases may include H₂, He, Ar, or N₂. Igniting an RF plasma results in the deposition of a predominately Te film. The power of the plasma may be adjusted throughout the deposition, may be ramped down at the end and extinguished while still flowing the organotellurium precursor, resulting in a Te underlayer capped with alkyl groups. An EUV resist, such as a spun-on or dry-deposited metalorganic resist as described above, can then be deposited on top of the modified layer and brought into an EUV scanner for exposure. Upon EUV exposure, the Te at the bottom of the film (e.g., deposited on the surface of an AHM carbon underlayer) will strongly absorb EUV photons not captured in the resist material, thereby maximizing the generation of secondary electrons likely to induce alkyl group cleavage and the formation of Te—Sn bonds at the interface. Alkyl groups present at the modified interface can undergo a beta-hydrogen elimination, resulting in the formation of reactive Te—H bonds at the interface. Upon bake Te—H may react with Sn in the resist film on top and form stable Sn—Te bonds. An example of this approach is depicted in FIG. 5.

CF, and OH, O, COO surface modification: In this example, enhanced EUV absorption can be achieved through the incorporation of F at the interface, while also including OH, O, or COO groups to adjust adhesion. The absorption can be enhanced in the EUV-exposed region by the presence of F from fluorocarbon (or NF₃, SF₆, or other F source) plasma treatment of organic (carbon based) underlayers. To create a thin CFₓ terminated surface, an RF plasma can be generated in one or more fluorinated hydrocarbon precursor (examples include CH₂F₂, C₄F₆, CHF₃, CH₃F, CF₄, or C₄F₈), optionally in combination with gases such as O₂, H₂, and/or CO₂ to promote the formation of polar moieties to facilitate adhesion of EUV-exposed metal oxide based resist materials to the substrate surface. A plasma is struck and conditions are selected such that a CFₓ layer is deposited on the wafer under conditions also shown to be effective at forming surface functionality expected to enhance adhesion with exposed metalorganic films. The resist—for example a dry-deposited metalorganic film—is then applied over the modified substrate surface and subjected to EUV-patterning. Upon EUV exposure, free F ions can be generated, and exhibit the tendency to form insoluble Fluoride complexes more resistant to dissolution in photoresist developers.

### Implementation 3: Deposition of High EUV Absorption for Surface Imaging

In a third implementation, a material can be deposited that will act to both enhance the EUV photo absorption and serve as a surface that is itself EUV-active and capable of further processing through surface imaging techniques, examples of which are described in our prior application No. 62/767,198, incorporated herein by reference for its disclosure of surface imaging techniques. Examples of this approach are depicted in FIG. 3 and FIG. 6. A wafer can be brought into a processing chamber for deposition of a material to enhance EUV-sensitivity at the substrate surface. The surface modification process can leave a wafer substrate surface terminated with EUV-labile groups such as alkyl groups (e.g., i-butyl, n-butyl, sec-butyl, i-propyl, etc.) or fluorine-substituted alkyl groups, such as —CF₃, —CF₂CF₃, for example. The wafer can then be moved to an EUV scanner and exposed. After exposure, the wafer can be removed from the scanner, optionally baked, optionally exposed to a controlled amount of oxygen or moisture, and then processed using a surface imaging technique, such as one of the surface imaging techniques described herein. It may advantageous to integrate the surface modification tool and EUV scanner; the EUV scanner and surface imaging tool; or the surface modification tool, EUV scanner and surface imaging tool such that there is a controlled environment between the different steps, preferably with minimal or carefully controlled exposure to moisture and/or oxygen.

Surface imaging may take many forms. These include a selective ALD or CVD process, selective deposition by an ELD process, or spinning a sol-gel on top of the surface. A common mechanism relies on the differences in the surface upon exposure. In the exposed regions, the EUV-labile groups may be removed, and the surface switched from an M-R to an M-H (typically becoming an —OH) surface. The differences in the reactivity and surface energy of the M-H or M-OH surfaces relative to the initial M-R functionality can enable subsequent processing, and the presence of the high EUV-absorbing underlayer can enhance harvesting of EUV photons.

The composition of the high EUV-absorbing underlayer can vary. Candidate constituent EUV-absorbing elements include In, Sn, Sb, Te, Pb, Bi, and alloys or compounds thereof, including with other elements, as well as oxides, nitrides, carbides, or any mixtures thereof. The EUV-labile groups may also vary, including alkyl groups CₙH₂ₙ₊₁, preferably wherein n≥3, and fluorine substituted alkyl groups, such as —CF₃, —CF₂CF₃, for example. The underlayer may be deposited by either a wet or dry process. Some exemplary methods for making these layers include the following:

Thermal ALD processes for surface imaging: The substrate can be modified with an ALD coating, such as a coating of SnO₂, Te, BiOx, SnTe, etc. resulting in an alkyl-terminated film being deposited on the surface. This may be done through alkyl-substituted ALD precursors, such as is described in greater detail in our prior application No. 62/767,198, incorporated herein by reference for its disclosure of surface imaging techniques.

Alkyl-terminated Te imaging layer: Similar to the process described for alkyl-terminated Sn interface modification, an organo-Te vapor may be flown into a chamber. The organo-Te precursor may have the form of RTeH or R₂Te, where R is an alkyl group or a ligand molecule. The alkyl group may be of the form CₙH₂ₙ₊₁, where n is greater than or equal to 3. Examples include t-butyl tellurium hydride, di(t-butyl) tellurium, di(isopropyl)tellurium, or bis(trimethylsilyl) tellurium with precursor supplied to the chamber in a mixture with carrier gases typically including at least one of H₂, He, Ar, or N₂ and a plasma struck resulting in the deposition of a thin Te film. The power of the plasma may be adjusted throughout the deposition, and possibly ramped down at the end. The plasma power may be stopped with the organo-Te precursor is still being flown, resulting in a Te thin layer capped with alkyl groups. Upon EUV exposure, high-absorbing Te layer can generate a lot of secondary electrons, which can induce beta-hydrogen elimination of these alkyl groups, resulting in the formation of Te—H bonds at the interface. Optionally, these bonds may be converted to Te—OH bonds through the introduction of moisture. The wafer may then be processed through a surface imaging technique. An example of this approach is depicted in FIG. 6.

High EUV underlayer+CFₓ surface modification: in this example, a CFₓ polymer film is deposited on top of a high EUV absorbing film. The absorbing film may be a variety of materials, including the Sn and Te layers described above. To deposit a fluorocarbon based film, gases with fluorine, carbon, and optionally hydrogen may be flown into the chamber. Example gases include, but are not limited to, CH₂F₂, C₄F₆, CHF₃, CH₃F, CF₄ and C₄F₈. In some cases, inert gases such as N₂, Ar, or He, and optionally hydrogen may also be added, and a plasma struck with conditions selected such that a CFₓ layer is deposited on the wafer. The CF, layer chemistry and deposition conditions can be tuned such that it is very inert to the certain vapor phase chemistries. Upon EUV exposure, reactive sites may be created on the surface through abstraction of F or CFₓ groups as a result of EUV generated secondary electrons. The wafer may then be brought into an ALD chamber where surface imaging can be performed. The ALD precursors may not exhibit reactivity with the unmodified fluorocarbon modified interface, but may nucleate on the exposed regions. An etch hardmask may be thus be formed through this method, and transferred into the underlying layers, for example as described in our prior application No. 62/767,198, incorporated herein by reference for its disclosure of surface imaging techniques.

### Some Non-Limiting Applications and Advantages

Techniques described in this disclosure enable tuning substrate chemistry through the incorporation of highly absorbing EUV materials and/or control of surface adhesion. Among the many potential uses and advantages include the following:
Potential to reduce EUV dose requirement in multiple types of photoresists by incorporation of more highly absorbing EUV materials at the interface near a resist to inject additional secondary electrons into the resist, allowing for more efficient harvest of EUV photons;
EUV-responsive adhesion to allow for easier removal of unexposed regions (less scumming) while promoting adhesion in the exposed regions; and
Potential for enabling novel “photoresist free” surface imaging strategies based on the selective ALD growth of a selective hard etch mask. This offers the potential for patterning at the lowest possible EUV exposure dose.

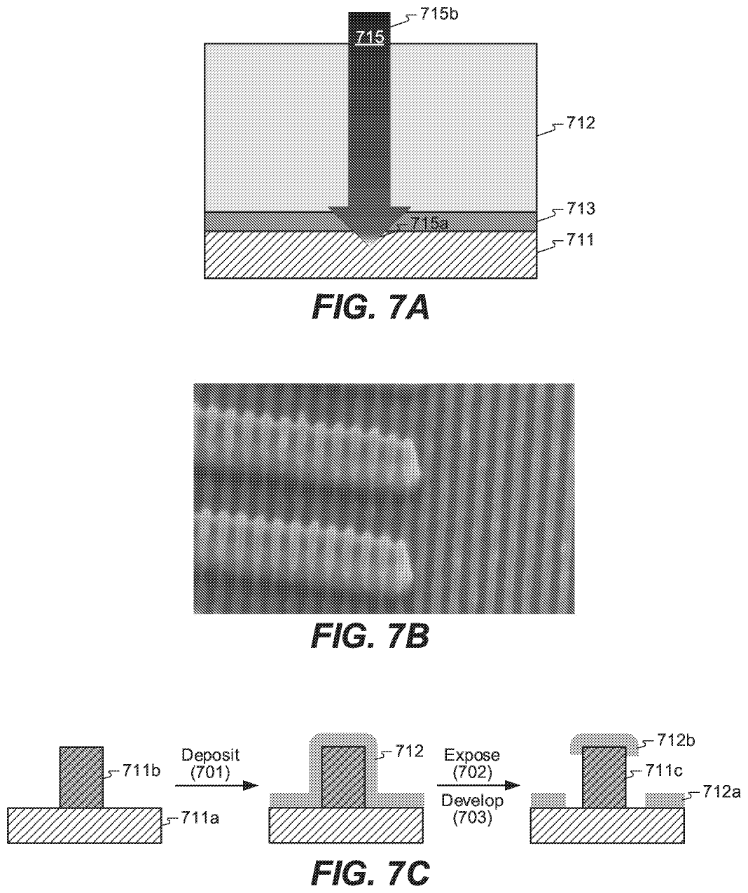

Yet other potential advantages include those associated with dry vacuum deposition, as compared to spin-coating. In one instance, use of dry deposition completely decouples surface preparation from coating quality and uniformity, which can allow for deposition of thinner films without defects or requirements for adhesion layers or surface pretreatments. Furthermore, constraints regarding solution stability can be minimized or eliminated, which can permit exploration of more reactive and homogeneous compositions offering potential for dose and LWR reduction. There can also be complete elimination of solubility constraint, which can permit extension to insoluble compositions targeted specifically towards dry development. In addition, such dry deposition approached can be more readily integrated with promising strategies for underlayer interface modification to enhance EUV absorption and reactivity. As seen in FIG. 7A, the patterning structure can include a tin, iodine, or tellurium-doped AHM underlayer 713 above a substrate 711 and below an imaging layer 712. Such a structure can have enhanced EUV absorption 715 at both interfaces 715a, 715b.

Potential applications include use with an expanding range of substrates and devices, including the possibility of deposition and patterning directly over device topography (see, non-limiting substrate in FIG. 7B). One application includes potential self-alignment via selective adhesion/attachment to underlying (planarized) device features.

Another non-limiting potential includes selective removal of underexposed sidewall (reverse of self-aligned double patterning (SADP)). In particular, the method includes underexposure and selective removal of a material (e.g., a film, an absorbing layer, and/or an imaging layer) deposited on a vertical sidewall of device features. The resulting distribution of the remaining exposed film material is thus opposite of that achieved in a standard SADP workflow, in which anisotropic plasma etch is applied to remove material on top and bottom horizontal surfaces while leaving behind that on the vertical sidewall. FIG. 7C provides a non-limiting method of such an application, which includes providing a substrate including a planar structure 711a and a feature 711b. The method can further include an operation 701 of depositing a film 712 on the substrate, an operation 702 of exposing the film to a blanket exposure of radiation, and operation 703 of developing the exposed film (e.g., by wet or dry negative tone development). After development, the resultant structure can include a horizontal overhang portion 712b disposed on a top surface of the feature 711b and a horizontal planar portion 712a disposed on a top surface of the planar structure 711a. Underexposure of the film can provide such an overhang portion 712b, while minimizing exposure to the film disposed on the vertical sidewall 711c. In non-limiting embodiments, the film can include a photoresponsive adhesive layer to enhance adhesion of the film to the feature surface. Such exposed vertical sidewalls can be used to provide lateral connections (e.g., lateral electrical connections) within the architecture or to other devices or lines.

### Precursors

The layers herein (e.g., a radiation-absorbing layer and/or an imaging layer) may include an element (e.g., a metal atom or a non-metal atom) having a high photoabsorption cross-section, such as equal to or greater than 1×10⁷ cm²/mol. Such elements can be provided by depositing one or more precursor(s) to provide the absorbing layer and/or the imaging layer.

The absorbing and imaging layers, either alone or together, can be considered a film. In some embodiments, the film is a radiation-sensitive film (e.g., an EUV-sensitive film). This film, in turn, can serve as an EUV resist, as further described herein. In particular embodiments, the layer or film can include one or more ligands (e.g., EUV labile ligands) that can be removed, cleaved, or cross-linked by radiation (e.g., EUV or DUV radiation).

The precursor can provide a patternable film that is sensitive to radiation (or a patterning radiation-sensitive film or a photopatternable film). Such radiation can include EUV radiation, DUV radiation, or UV radiation that is provided by irradiating through a patterned mask, thereby being a patterned radiation. The film itself can be altered by being exposed to such radiation, such that the film is radiation-sensitive or photosensitive. In particular embodiments, the precursor is an organometallic compound, which includes at least one metal center. In other embodiments, the film obtained from the precursor is characterized by a Beer's absorption coefficient α of more than about 6 μm⁻¹ (e.g., more than about 7 μm⁻¹, 8 μm⁻¹, 9 μm⁻¹, 10 μm⁻¹, 20 μm⁻¹, 30 μm⁻¹, or more) at the wavelength of the patterned radiation being exposed to the film (e.g., from UV, DUV, or EUV exposure).

The precursor can have any useful number and type of ligand(s). In some embodiments, the ligand can be characterized by its ability to react in the presence of a counter-reactant or in the presence of patterned radiation. For instance, the precursor can include a ligand that reacts with a counter-reactant, which can introduce linkages between metal centers (e.g., an —O— linkage). In another instance, the precursor can include a ligand that eliminates in the presence of patterned radiation. Such an EUV labile ligand can include branched or linear alkyl groups having a beta-hydrogen, as well as any described herein for R in formula (I) or (II).

The precursor can be any useful metal-containing precursor, such as an organometallic agent, a metal halide, or a capping agent (e.g., as described herein). In a non-limiting instance, the precursor includes a structure having formula (I):

MₐR_{b} (I),

wherein:
M is a metal or an atom having a high EUV absorption cross-section;
each R is, independently, H, halo, optionally substituted alkyl, optionally substituted cycloalkyl, optionally substituted cycloalkenyl, optionally substituted alkenyl, optionally substituted alkynyl, optionally substituted alkoxy, optionally substituted alkanoyloxy, optionally substituted aryl, optionally substituted amino, optionally substituted bis(trialkylsilyl)amino, optionally substituted trialkylsilyl, oxo, an anionic ligand, a neutral ligand, or a multidentate ligand;
a≥1; and b≥1.

In another non-limiting instance, the precursor includes a structure having formula (II):

MₐR_{b}L_{c} (II),

wherein:
M is a metal or an atom having a high EUV absorption cross-section;
each R is, independently, halo, optionally substituted alkyl, optionally substituted aryl, optionally substituted amino, optionally substituted alkoxy, or L;
each L is, independently, a ligand, an anionic ligand, a neutral ligand, a multidentate ligand, ion, or other moiety that is reactive with a counter-reactant, in which R and L with M, taken together, can optionally form a heterocyclyl group or in which R and L, taken together, can optionally form a heterocyclyl group;
a≥1; b≥1; and c≥1.

In some embodiments, each ligand within the precursor can be one that is reactive with a counter-reactant. In one instance, the precursor includes a structure having formula (II), in which each R is, independently, L. In another instance, the precursor includes a structure having formula (IIa):

MₐL_{c} (IIa),

wherein:
M is a metal or an atom having a high EUV absorption cross-section;
each L is, independently, a ligand, ion, or other moiety that is reactive with a counter-reactant, in which two L, taken together, can optionally form a heterocyclyl group;
a≥1; and c≥1.
   In particular embodiments of formula (IIa), a is 1. In further embodiments, c is 2, 3, or 4.

For any formula herein, M can be a metal or a metalloid or an atom with a high patterning radiation absorption cross-section (e.g., an EUV absorption cross-section that is equal to or greater than 1×10⁷ cm²/mol). In some embodiments, M is tin (Sn), bismuth (Bi), tellurium (Te), cesium (Cs), antimony (Sb), indium (In), molybdenum (Mo), hafnium (Hf), iodine (I), zirconium (Zr), iron (Fe), cobalt (Co), nickel (Ni), copper (Cu), zinc (Zn), silver (Ag), platinum (Pt), and lead (Pb). In further embodiments, M is Sn, a is 1, and c is 4 in formula (I), (II), or (IIa). In other embodiments, M is Sn, a is 1, and c is 2 in formula (I), (II), or (IIa). In particular embodiments, M is Sn(II) (e.g., in formula (I), (II), or (IIa)), thereby providing a precursor that is a Sn(II)-based compound. In other embodiments, M is Sn(IV) (e.g., in formula (I), (II), or (IIa)), thereby providing a precursor that is a Sn(IV)-based compound. In particular embodiments, the precursor includes iodine (e.g., as in periodate).

For any formula herein, each R is, independently, H, halo, optionally substituted alkyl, optionally substituted cycloalkyl, optionally substituted cycloalkenyl, optionally substituted alkenyl, optionally substituted alkynyl, optionally substituted alkoxy (e.g., —OR¹, in which R¹ can be optionally substituted alkyl), optionally substituted alkanoyloxy, optionally substituted aryl, optionally substituted amino, optionally substituted bis(trialkylsilyl)amino, optionally substituted trialkylsilyl, oxo, an anionic ligand (e.g., oxido, chlorido, hydrido, acetate, iminodiacetate, propanoate, butanoate, benzoate, etc.), a neutral ligand, or a multidentate ligand.

In some embodiments, the optionally substituted amino is —NR¹R², in which each R¹ and R² is, independently, H or alkyl; or in which R¹ and R², taken together with the nitrogen atom to which each are attached, form a heterocyclyl group, as defined herein. In other embodiments, the optionally substituted bis(trialkylsilyl)amino is —N(SiR¹R²R³)₂, in which each R¹, R², and R³ is, independently, optionally substituted alkyl. In yet other embodiments, the optionally substituted trialkylsilyl is —SiR¹R²R³, in which each R¹, R², and R³ is, independently, optionally substituted alkyl.

In other embodiments, the formula includes a first R (or first L) that is —NR¹R² and a second R (or second L) that is —NR¹R², in which each R¹ and R² is, independently, H or optionally substituted alkyl; or in which R¹ from a first R (or first L) and R¹ from a second R (or second L), taken together with the nitrogen atom and the metal atom to which each are attached, form a heterocyclyl group, as defined herein. In yet other embodiments, the formula includes a first R that is —OR¹ and a second R that is —OR¹, in which each R¹ is, independently, H or optionally substituted alkyl, or in which R¹ from a first R and R¹ from a second R, taken together with the oxygen atom and the metal atom to which each are attached, form a heterocyclyl group, as defined herein.

In some embodiments, at least one of R or L (e.g., in formula (I), (II), or (IIa)) is optionally substituted alkyl. Non-limiting alkyl groups include, e.g., CₙH₂ₙ₊₁, where n is 1, 2, 3, or greater, such as methyl, ethyl, n-propyl, isopropyl, n-butyl, isobutyl, s-butyl, or i-butyl. In various embodiments, R or L has at least one beta-hydrogen or beta-fluorine. In other embodiments, at least one of R or L is a halo-substituted alkyl (e.g., a fluoro-substituted alkyl).

In some embodiments, each R or L or at least one R or L (e.g., in formula (I), (II), or (IIa)) is halo. In particular, the precursor can be a metal halide. Non-limiting metal halides include SnBr₄, SnCl₄, SnI₄, and SbCl₃.

In some embodiments, each R or L or at least one R or L (e.g., in formula (I), (II), or (IIa)) can include a nitrogen atom. In particular embodiments, one or more R or L can be optionally substituted amino, an optionally substituted monoalkylamino (e.g., —NR¹H, in which R¹ is optionally substituted alkyl), an optionally substituted dialkylamino (e.g., —NR¹R², in which each R¹ and R² is, independently, optionally substituted alkyl), or optionally substituted bis(trialkylsilyl)amino. Non-limiting R and L substituents can include, e.g., —NMe₂, —NHMe, —NEt₂, —NHEt, —NMeEt, —N(t-Bu)—[CHCH₃]₂—N(t-Bu)-(tbba), —N(SiMe₃)₂, and —N(SiEt₃)₂.

In some embodiments, each R or L or at least one R or L (e.g., in formula (I), (II), or (IIa)) can include a silicon atom. In particular embodiments, one or more R or L can be optionally substituted trialkylsilyl or optionally substituted bis(trialkylsilyl)amino. Non-limiting R or L substituents can include, e.g., —SiMe₃, —SiEt₃, —N(SiMe₃)₂, and —N(SiEt₃)₂.

In some embodiments, each R or L or at least one R or L (e.g., in formula (I), (II), or (IIa)) can include an oxygen atom. In particular embodiments, one or more R or L can be optionally substituted alkoxy or optionally substituted alkanoyloxy. Non-limiting R or L substituents include, e.g., methoxy, ethoxy, isopropoxy (i-PrO), t-butoxy (t-BuO), acetate (—OC(O)—CH₃), and —O═C(CH₃)—CH═C(CH₃)—O— (acac).

Any formulas herein can include one or more neutral ligands. Non-limiting neutral ligands include an optionally substituted amine (e.g., NR₃ or R₂N-Ak-NR₂, in which each R can be, independently, H, optionally substituted alkyl, optionally substituted hydrocarbyl, or optionally substituted aryl, and Ak is optionally substituted alkylene), an optionally substituted phosphine (e.g., PR₃ or R₂P-Ak-PR₂, in which each R can be, independently, H, optionally substituted alkyl, optionally substituted hydrocarbyl, or optionally substituted aryl, and Ak is optionally substituted alkylene), an optionally substituted ether (e.g., OR₂, in which each R can be, independently, H, optionally substituted alkyl, optionally substituted hydrocarbyl, or optionally substituted aryl), an optionally substituted alkyl, an optionally substituted alkene, an optionally substituted alkyne, an optionally substituted benzene, oxo, or carbon monoxide.

Any formulas herein can include one or more multidentate (e.g., bidentate) ligands. Non-limiting multidentate ligand include a diketonate (e.g., acetylacetonate (acac) or —OC(R¹)-Ak-(R¹)CO— or —OC(R¹)—C(R²)—(R¹)CO—), a bidentate chelating dinitrogen (e.g., —N(R¹)-Ak-N(R¹)— or —N(R³)—CR⁴—CR²═N(R¹)—), an aromatic (e.g., —Ar—), an amidinate (e.g., —N(R¹)—C(R²)—N(R¹)—), an aminoalkoxide (e.g., —N(R¹)-Ak-O— or —N(R¹)₂-Ak-O—), a diazadienyl (e.g., —N(R¹)—C(R²)—C(R²)—N(R¹)—), a cyclopentadienyl, a pyrazolate, an optionally substituted heterocyclyl, an optionally substituted alkylene, or an optionally substituted heteroalkylene. In particular embodiments, each R¹ is, independently, H, optionally substituted alkyl, optionally substituted haloalkyl, or optionally substituted aryl; each R² is, independently, H or optionally substituted alkyl; R³ and R⁴, taken together, forms an optionally substituted heterocyclyl; Ak is optionally substituted alkylene; and Ar is optionally substituted arylene.

In particular embodiments, the precursor includes tin. In some embodiments, the tin precursor includes SnR or SnR₂ or SnR₄ or R₃SnSnR₃, wherein each R is, independently, H, halo, optionally substituted C₁₋₁₂ alkyl, optionally substituted C₁₋₁₂ alkoxy, optionally substituted amino (e.g., —NR¹R²), optionally substituted C₂₋₁₂ alkenyl, optionally substituted C₂₋₁₂ alkynyl, optionally substituted C₃₋₈ cycloalkyl, optionally substituted aryl, cyclopentadienyl, optionally substituted bis(trialkylsilyl)amino (e.g., —N(SiR¹R²R³)₂), optionally substituted alkanoyloxy (e.g., acetate), a diketonate (e.g., —OC(R¹)-Ak-(R²)CO—), or a bidentate chelating dinitrogen (e.g.,

—N(R¹)-Ak-N(R¹)—). In particular embodiments, each R¹, R², and R³ is, independently, H or C₁₋₁₂ alkyl (e.g., methyl, ethyl, isopropyl, t-butyl, or neopentyl); and Ak is optionally substituted C₁₋₆ alkylene. In particular embodiments, each R is, independently, halo, optionally substituted C₁₋₁₂ alkoxy, optionally substituted amino, optionally substituted aryl, cyclopentadienyl, or a diketonate. Non-limiting tin precursors include SnF₂, SnH₄, SnBr₄, SnCl₄, SnI₄, tetramethyl tin (SnMe₄), tetraethyl tin (SnEt₄), trimethyl tin chloride (SnMe₃Cl), dimethyl tin dichloride (SnMe₂Cl₂), methyl tin trichloride (SnMeCl₃), tetraallyltin, tetravinyl tin, hexaphenyl ditin (IV) (Ph₃Sn—SnPh₃, in which Ph is phenyl), dibutyldiphenyltin (SnBu₂Ph₂), trimethyl(phenyl) tin (SnMe₃Ph), trimethyl(phenylethynyl) tin, tricyclohexyl tin hydride, tributyl tin hydride (SnBu₃H), dibutyltin diacetate (SnBu₂(CH₃COO)₂), tin(II) acetylacetonate (Sn(acac)₂), SnBu₃(OEt), SnBu₂(OMe)₂, SnBu₃(OMe), Sn(t-BuO)₄, Sn(n-Bu)(t-BuO)₃, tetrakis(dimethylamino)tin (Sn(NMe₂)₄), tetrakis(ethylmethylamino)tin (Sn(NMeEt)₄), tetrakis(diethylamino)tin(IV) (Sn(NEt₂)₄), (dimethylamino)trimethyl tin(IV) (Sn(Me)₃(NMe₂), Sn(i-Pr)(NMe₂)₃, Sn(n-Bu)(NMe₂)₃, Sn(s-Bu)(NMe₂)₃, Sn(i-Bu)(NMe₂)₃, Sn(t-Bu)(NMe₂)₃, Sn(t-Bu)₂(NMe₂)₂, Sn(t-Bu)(NEt₂)₃, Sn(tbba), Sn(II) (1,3-bis(1,1-dimethylethyl)-4,5-dimethyl-(4R,5R)-1,3,2-diazastannolidin-2-ylidene), or bis[bis(trimethylsilyl)amino] tin (Sn[N(SiMe₃)₂]₂).

In other embodiments, the precursor includes bismuth, such as in BiR₃, wherein each R is, independently, halo, optionally substituted C₁₋₁₂ alkyl, mono-C₁₋₁₂ alkylamino (e.g., —NR¹H), di-C₁₋₁₂ alkylamino (e.g., —NR¹R²), optionally substituted aryl, optionally substituted bis(trialkylsilyl)amino (e.g., —N(SiR¹R²R³)₂), or a diketonate (e.g., —OC(R⁴)-Ak-(R⁵)CO—). In particular embodiments, each R¹, R², and R³ is, independently, C₁₋₁₂ alkyl (e.g., methyl, ethyl, isopropyl, t-butyl, or neopentyl); and each R⁴ and R⁵ is, independently, H or optionally substituted C₁₋₁₂ alkyl (e.g., methyl, ethyl, isopropyl, t-butyl, or neopentyl). Non-limiting bismuth precursors include BiCl₃, BiMe₃, BiPh₃, Bi(NMe₂)₃, Bi[N(SiMe₃)₂]₃, and Bi(thd)₃, in which thd is 2,2,6,6-tetramethyl-3,5-heptanedionate.

In other embodiments, the precursor includes tellurium, such as TeR₂ or TeR₄, wherein each R is, independently, halo, optionally substituted C₁₋₁₂ alkyl (e.g., methyl, ethyl, isopropyl, t-butyl, and neopentyl), optionally substituted C₁₋₁₂ alkoxy, optionally substituted aryl, hydroxyl, oxo, or optionally substituted trialkylsilyl. Non-limiting tellurium precursors include dimethyl tellurium (TeMe₂), diethyl tellurium (TeEt₂), di(n-butyl) tellurium (Te(n-Bu)₂), di(isopropyl) tellurium (Te(i-Pr)₂), di(t-butyl) tellurium (Te(t-Bu)₂), t-butyl tellurium hydride (Te(t-Bu)(H)), Te(OEt)₄, bis(trimethylsilyl)tellurium (Te(SiMe₃)₂), and bis(triethylsilyl) tellurium (Te(SiEt₃)₂).

The precursor can include antimony, such as in SbR₃, wherein each R is, independently, halo, optionally substituted C₁₋₁₂ alkyl (e.g., methyl, ethyl, isopropyl, t-butyl, and neopentyl), optionally substituted C₁₋₁₂ alkoxy, or optionally substituted amino (e.g., —NR¹R², in which each R¹ and R² is, independently, H or optionally substituted C₁₋₁₂ alkyl). Non-limiting antimony precursors include SbCl₃, Sb(OEt)₃, Sb(On-Bu)₃, and Sb(NMe₂)₃.

Other precursors include indium precursors, such as in InR₃, wherein each R is, independently, halo, optionally substituted C₁₋₁₂ alkyl (e.g., methyl, ethyl, isopropyl, t-butyl, and neopentyl), or a diketonate (e.g., —OC(R⁴)-Ak-(R¹)CO—, in which each R⁴ and R⁵ is, independently, H or C₁₋₁₂ alkyl). Non-limiting indium precursors include InCp, in which Cp is cyclopentadienyl, InCl₃, InMe₃, In(acac)₃, In(CF₃COCHCOCH₃)₃, and In(thd)₃.

The precursor can include iodine, such as RI, wherein R is iodo (I) or optionally substituted C₁₋₁₂ alkyl, or periodate. Non-limiting iodine precursors include iodine gas (I₂), diiodomethane (CH₂I₂), and periodate.

Yet other precursors and non-limiting substituents are described herein. For instance, precursors can be any having a structure of formulas (I), (II), and (IIa), as described above; or formulas (III), (IV), (V), (VI), (VII), or (VIII), as described below. Any of the substituents M, R, X, or L, as described herein, can be employed in any of formulas (I), (II), (IIa), (III), (IV), (V), (VI), (VII), or (VIII).

Yet other exemplary EUV-sensitive materials, as well as processing methods and apparatuses, are described in U.S. Pat. No. 9,996,004; Int. Pat. Pub. No. WO 2020/102085; and Int. Pat. Pub. No. WO 2019/217749, each of which is incorporated herein by reference in its entirety.

As described herein, the films, layers, and methods herein can be employed with any useful precursor. In some instances, the precursor includes a metal halide having the following formula (III):

MXₙ (III),

in which M is a metal, X is halo, and n is 2 to 4, depending on the selection of M. Exemplary metals for M include Sn, Te, Bi, or Sb. Exemplary metal halides include SnBr₄, SnCl₄, SnI₄, and SbCl₃.

Another non-limiting precursor includes a structure having formula (IV):

MRₙ (IV),

in which M is a metal; each R is independently H, an optionally substituted alkyl, amino (e.g., —NR₂, in which each R is independently alkyl), optionally substituted bis(trialkylsilyl)amino (e.g., —N(SiR₃)₂, in which each R is independently alkyl), or an optionally substituted trialkylsilyl (e.g., —SiR₃, in which each R is independently alkyl); and n is 2 to 4, depending on the selection of M. Exemplary metals for M include Sn, Te, Bi, or Sb. The alkyl group may be CₙH₂ₙ₊₁, where n is 1, 2, 3, or greater. Exemplary organometallic agents include SnMe₄, SnEt₄, TeRn, RTeR, t-butyl tellurium hydride (Te(t-Bu)(H)), dimethyl tellurium (TeMe₂), di(t-butyl) tellurium (Te(t-Bu)₂), di(isopropyl)tellurium (Te(i-Pr)₂), bis(trimethylsilyl)tellurium (Te(SiMe₃)₂), bis(triethylsilyl) tellurium (Te(SiEt₃)₂), tris(bis(trimethylsilyl)amido) bismuth (Bi[N(SiMe₃)₂]₃), Sb(NMe₂)₃, and the like.

Another non-limiting precursor can include a capping agent having the following formula (V):

MLₙ (V),

in which M is a metal; each L is independently an optionally substituted alkyl, amino (e.g., —NR¹R², in which each of R¹ and R² can be H or alkyl, such as any described herein), alkoxy (e.g., —OR, in which R is alkyl, such as any described herein), halo, or other organic substituent; and n is 2 to 4, depending on the selection of M. Exemplary metals for M include Sn, Te, Bi, or Sb. Exemplary ligands include dialkylamino (e.g., dimethylamino, methylethylamino, and diethylamino), alkoxy (e.g., t-butoxy and isopropoxy), halo (e.g., F, Cl, Br, and I), or other organic substituents (e.g., acetylacetone or N²,N³-di-tertbutyl-butane-2,3-diamino). Non-limiting capping agents include SnCl₄; SnI₄; Sn(NR₂)₄, wherein each of R is independently methyl or ethyl; or Sn(t-BuO)₄. In some embodiments, multiple types of ligands are present.

A precursor can include a hydrocarbyl-substituted capping agent having the following formula (VI):

RₙMXₘ (VI),

wherein M is a metal, R is a C₂₋₁₀ alkyl or substituted alkyl having a beta-hydrogen, and X is a suitable leaving group upon reaction with a hydroxyl group of the exposed hydroxyl groups. In various embodiments, n=1 to 3, and m=4−n, 3−n, or 2−n, so long as m>0 (or m≥1). For example, R may be t-butyl, t-pentyl, t-hexyl, cyclohexyl, isopropyl, isobutyl, sec-butyl, n-butyl, n-pentyl, n-hexyl, or derivatives thereof having a heteroatom substituent in the beta position. Suitable heteroatoms include halogen (F, Cl, Br, or I), or oxygen (—OH or —OR). X may be dialkylamino (e.g., dimethylamino, methylethylamino, or diethylamino), alkoxy (e.g., t-butoxy, isopropoxy), halo (e.g., F, Cl, Br, or I), or another organic ligand. Examples of hydrocarbyl-substituted capping agents include t-butyltris(dimethylamino)tin (Sn(t-Bu)(NMe₂)₃), n-butyltris(dimethylamino)tin (Sn(n-Bu)(NMe₂)₃), t-butyltris(diethylamino)tin (Sn(t-Bu)(NEt₂)₃), di(t-butyl)di(dimethylamino)tin (Sn(t-Bu)₂(NMe₂)₂), sec-butyltris(dimethylamino)tin (Sn(s-Bu)(NMe₂)₃), n-pentyltris(dimethylamino)tin (Sn(n-pentyl)(NMe₂)₃), i-butyltris(dimethylamino) tin (Sn(i-Bu)(NMe₂)₃), i-propyltris(dimethylamino)tin (Sn(i-Pr)(NMe₂)₃), t-butyltris(t-butoxy)tin (Sn(t-Bu)(t-BuO)₃), n-butyl(tris(t-butoxy)tin (Sn(n-Bu)(t-BuO)₃), or isopropyltris(t-butoxy)tin (Sn(i-Pr)(t-BuO)₃).

In various embodiments, a precursor includes at least one alkyl group on each metal atom that can survive the vapor-phase reaction, while other ligands or ions coordinated to the metal atom can be replaced by the counter-reactants. Accordingly, another non-limiting precursor includes an organometallic agent having the formula (VII):

MₐR_{b}L_{c} (VII),

in which M is a metal; R is an optionally substituted alkyl; L is a ligand, ion, or other moiety which is reactive with the counter-reactant; a≥1; b≥1; and c≥1. In particular embodiments, a=1, and b+c=4. In some embodiments, M is Sn, Te, Bi, or Sb. In particular embodiments, each L is independently amino (e.g., —NR¹R², in which each of R¹ and R² can be H or alkyl, such as any described herein), alkoxy (e.g., —OR, in which R is alkyl, such as any described herein), or halo (e.g., F, Cl, Br, or I). Exemplary agents include SnMe₃Cl, SnMe₂Cl₂, SnMeCl₃, SnMe(NMe₂)₃, SnMe₂(NMe₂)₂, SnMe₃(NMe₂), and the like.

In other embodiments, the non-limiting precursor includes an organometallic agent having the formula (VIII):

MₐL_{c} (VIII),

in which M is a metal; L is a ligand, ion, or other moiety which is reactive with the counter-reactant; a≥1; and c≥1. In particular embodiments, c=n−1, and n is 2, 3, or 4. In some embodiments, M is Sn, Te, Bi, or Sb. Counter-reactants preferably have the ability to replace the reactive moieties ligands or ions (e.g., L in formulas herein) so as to link at least two metal atoms via chemical bonding.

In any embodiment herein, R can be an optionally substituted alkyl (e.g., C₁₋₁₀ alkyl). In one embodiment, alkyl is substituted with one or more halo (e.g., halo-substituted C₁₋₁₀ alkyl, including one, two, three, four, or more halo, such as F, Cl, Br, or I). Exemplary R substituents include CₙH₂ₙ₊₁, preferably wherein n≥3; and CₙFₓH₍₂ₙ₊₁₋ₓ₎, wherein 2n+1≤x≤1. In various embodiments, R has at least one beta-hydrogen or beta-fluorine. For example, R may be selected from the group consisting of i-propyl, n-propyl, t-butyl, i-butyl, n-butyl, sec-butyl, ii-pentyl, i-pentyl, I-pentyl, sec-pentyl, and mixtures thereof.

In any embodiment herein, L may be any moiety readily displaced by a counter-reactant to generate an M-OH moiety, such as a moiety selected from the group consisting of an amino (e.g., —NR¹R², in which each of R¹ and R² can be H or alkyl, such as any described herein), alkoxy (e.g., —OR, in which R is alkyl, such as any described herein), carboxylates, halo (e.g., F, Cl, Br, or I), and mixtures thereof.

Counter-reactants preferably have the ability to replace the reactive moieties, ligands, or ions (e.g., L in formulas herein) so as to link at least two metal atoms via chemical bonding. Exemplary counter-reactants include oxygen-containing counter-reactants, such as oxygen (O₂), ozone (O₃), water, peroxides (e.g., hydrogen peroxide), oxygen plasma, water plasma, alcohols, dihydroxy alcohols, polyhydroxy alcohols, fluorinated dihydroxy alcohol, fluorinated polyhydroxy alcohols, fluorinated glycols, formic acid, and other sources of hydroxyl moieties, as well as combinations thereof. In various embodiments, a counter-reactant reacts with the precursor by forming oxygen bridges between neighboring metal atoms. Other potential counter-reactants include hydrogen sulfide and hydrogen disulfide, which can crosslink metal atoms via sulfur bridges and bis(trimethylsilyl)tellurium, which can crosslink metal atoms via tellurium bridges. In addition, hydrogen iodide may be utilized to incorporate iodine into the film.

Yet other non-limiting counter-reactants include a chalcogenide precursor having the formula ZR₂, wherein: Z is sulfur, selenium, or tellurium; and each R is, independently, H, optionally substituted alkyl (e.g., methyl, ethyl, n-propyl, isopropyl, n-butyl, i-butyl, etc.), optionally substituted alkenyl, optionally substituted aryl, optionally substituted amino, optionally substituted alkoxy, or optionally substituted trialkylsilyl.

Exemplary organometallic agents include SnMeCl₃, (N²,N³-di-t-butyl-butane-2,3-diamido) tin(II) (Sn(tbba)), bis(bis(trimethylsilyl)amido) tin(II), tetrakis(dimethylamino) tin(IV) (Sn(NMe₂)₄), t-butyl tris(dimethylamino) tin (Sn(t-butyl)(NMe₂)₃), i-butyl tris(dimethylamino) tin (Sn(i-Bu)(NMe₂)₃), n-butyl tris(dimethylamino) tin (Sn(n-Bu)(NMe₂)₃), sec-butyl tris(dimethylamino) tin (Sn(s-Bu)(NMe₂)₃), i-propyl(tris)dimethylamino tin (Sn(i-Pr)(NMe₂)₃), n-propyl tris(diethylamino) tin (Sn(n-Pr)(NEt₂)₃), and analogous alkyl(tris)(t-butoxy) tin compounds, such as 1-butyl tris(t-butoxy) tin (Sn(t-Bu)(t-BuO)₃). In some embodiments, the organometallic agents are partially fluorinated.

### Lithographic Processes

EUV lithography makes use of EUV resists, which may be polymer-based chemically amplified resists produced by liquid-based spin-on techniques or metal oxide-based resists produced by dry vapor-deposited techniques. Such EUV resists can include any EUV-sensitive film or material described herein. Lithographic methods can include patterning the resist, e.g., by exposure of the EUV resist with EUV radiation to form a photo pattern, followed by developing the pattern by removing a portion of the resist according to the photo pattern to form a mask.

It should also be understood that while the present disclosure relates to lithographic patterning techniques and materials exemplified by EUV lithography, it is also applicable to other next generation lithographic techniques. In addition to EUV, which includes the standard 13.5 nm EUV wavelength currently in use and development, the radiation sources most relevant to such lithography are DUV (deep-UV), which generally refers to use of 248 nm or 193 nm excimer laser sources, X-ray, which formally includes EUV at the lower energy range of the X-ray range, as well as e-beam, which can cover a wide energy range. Such methods include those where a substrate (e.g., optionally having exposed hydroxyl groups) is contacted with a precursor (e.g., any described herein) to form a metal oxide (e.g., a layer including a network of metal oxide bonds, which may include other non-metal and non-oxygen groups) film as the imaging/PR layer on the surface of the substrate. The specific methods may depend on the particular materials and applications used in the semiconductor substrate and ultimate semiconducting device. Thus, the methods described in this application are merely exemplary of the methods and materials that may be used in present technology. In some embodiments, lithography includes use of a radiation source having a wavelength that is between 10 nm and 400 nm.

Directly photopatternable EUV resists may be composed of or contain metals and/or metal oxides. The metals/metal oxides are highly promising in that they can enhance the EUV photon absorption and generate secondary electrons and/or show increased etch selectivity to an underlying film stack and device layers. To date, these resists have been developed using a wet (solvent) approach, which requires the wafer to move to the track, where it is exposed to developing solvent, dried and baked. Wet development does not only limit productivity but can also lead to line collapse due to surface tension effects during the evaporation of solvent between fine features.

Dry development techniques have been proposed to overcome these issues by eliminating substrate delamination and interface failures. Dry development has its own challenges, including etch selectivity between unexposed and EUV exposed resist material which can lead to a higher dose to size requirement for effective resist exposure when compared to wet development. Suboptimal selectivity can also cause PR corner rounding due to longer exposures under etching gas, which may increase line CD variation in the following transfer etch step. Additional processes employed during lithography are described in detail below.

### Deposition Processes, Including Dry Deposition

As discussed above, the present disclosure provides methods for making absorbing layers and imaging layers on semiconductor substrates, which may be patterned using EUV or other next generation lithographic techniques. Methods include those where polymerized organometallic materials are produced in a vapor and deposited on a substrate. In some embodiments, dry deposition can employ any useful precursor (e.g., metal halides, capping agents, or organometallic agents described herein). In other embodiments, a spin-on formulation may be used. Deposition processes can include applying a EUV-sensitive material as a resist film or an EUV-sensitive film.

Such EUV-sensitive films comprise materials which, upon exposure to EUV, undergo changes, such as the loss of bulky pendant ligands bonded to metal atoms in low density M-OH rich materials, allowing their crosslinking to denser M-O-M bonded metal oxide materials. In other embodiments, EUV exposure results in further cross-linking between ligands bonded to metal atoms, thereby providing denser M-L-M bonded organometallic materials, in which L is a ligand. In yet other embodiments, EUV exposure results in loss of ligands to provide M-OH materials that can be removed by positive tone developers.

Through EUV patterning, areas of the film are created that have altered physical or chemical properties relative to unexposed areas. These properties may be exploited in subsequent processing, such as to dissolve either unexposed or exposed areas or to selectively deposit materials on either the exposed or unexposed areas. In some embodiments, the unexposed film has a hydrophobic surface, and the exposed film has a hydrophilic surface (it being recognized that the hydrophilic properties of exposed and unexposed areas are relative to one another) under the conditions at which such subsequent processing is performed. For example, the removal of material may be performed by leveraging differences in chemical composition, density, and cross-linking of the film. Removal may be by wet processing or dry processing, as further described herein.

The thickness of the EUV-patternable film formed on the surface of the substrate may vary according to the surface characteristics, materials used, and processing conditions. In various embodiments, the film thickness may range from about 0.5 nm to about 100 nm. Preferably, the film has a sufficient thickness to absorb most of the EUV light under the conditions of EUV patterning. For example, the overall absorption of the resist film may be 30% or less (e.g., 10% or less, or 5% or less), so that the resist material at the bottom of the resist film is sufficiently exposed. In some embodiments, the film thickness is from 10 nm to 20 nm. Without limiting the mechanism, function, or utility of the present disclosure, it is believed that, unlike wet, spin-coating processes of the art, the processes of the present disclosure have fewer restrictions on the surface adhesion properties of the substrate, and therefore can be applied to a wide variety of substrates. Moreover, as discussed above, the deposited films may closely conform to surface features, providing advantages in forming masks over substrates, such as substrates having underlying features, without “filling in” or otherwise planarizing such features.

The film (e.g., absorbing layer and/or imaging layer) may be composed of a metal oxide layer deposited in any useful manner. Such a metal oxide layer can be deposited or applied by using any EUV-sensitive material described herein, such as a precursor (e.g., metal-containing precursor, a metal halide, a capping agent, or an organometallic agent) in combination with a counter-reactant. In exemplary processes, a polymerized organometallic material is formed in vapor phase or in situ on the surface of the substrate in order to provide the metal oxide layer. The metal oxide layer may be employed as a film, an adhesion layer, or a capping layer.

Optionally, the metal oxide layer can include a hydroxyl-terminated metal oxide layer, which can be deposited by employing a capping agent (e.g., any described herein) with an oxygen-containing counter-reactant. Such a hydroxyl-terminated metal oxide layer can be employed, e.g., as an adhesion layer between two other layers, such as between the substrate and the film and/or between the photoresist layer and the underlayer.

Exemplary deposition techniques (e.g., for a film) include any described herein, such as ALD (e.g., thermal ALD and plasma-enhanced ALD), spin-coat deposition, PVD including PVD co-sputtering, CVD (e.g., PE-CVD or LP-CVD), sputter deposition, e-beam deposition including e-beam co-evaporation, etc., or a combination thereof, such as ALD with a CVD component, such as a discontinuous, ALD-like process in which precursors and counter-reactants are separated in either time or space.

Further description of precursors and methods for their deposition as EUV photoresist films applicable to this disclosure may be found in International Appl. No. PCT/US19/31618, published as International Pub. No. WO2019/217749, filed May 9, 2019, and titled METHODS FOR MAKING EUV PATTERNABLE HARD MASKS. The thin films may include optional materials in addition to a precursor and a counter-reactant to modify the chemical or physical properties of the film, such as to modify the sensitivity of the film to EUV or enhancing etch resistance. Such optional materials may be introduced, such as by doping during vapor phase formation prior to deposition on the substrate, after deposition of the film, or both. In some embodiments, a gentle remote H₂ plasma may be introduced so as to replace some Sn-L bonds with Sn—H, for example, which can increase reactivity of the resist under EUV.

In general, methods can include mixing a vapor stream of a precursor (e.g., a metal-containing precursor, such as an organometallic agent) with an optional vapor stream of a counter-reactant so as to form a polymerized organometallic material, and depositing the organometallic material onto the surface of the semiconductor substrate. In some embodiments, mixing the precursor and optional counter-reactant can form a polymerized organometallic material. As will be understood by one of ordinary skill in the art, the mixing and depositing aspects of the process may be concurrent, in a substantially continuous process.

In an exemplary continuous CVD process, two or more gas streams, in separate inlet paths, of sources of precursor and optional counter-reactant are introduced to the deposition chamber of a CVD apparatus, where they mix and react in the gas phase, to form agglomerated polymeric materials (e.g., via metal-oxygen-metal bond formation) or a film on the substrate. Gas streams may be introduced, for example, using separate injection inlets or a dual-plenum showerhead. The apparatus is configured so that the streams of precursor and optional counter-reactant are mixed in the chamber, allowing the precursor and optional counter-reactant to react to form a polymerized organometallic material or a film (e.g., a metal oxide coating or agglomerated polymeric materials, such as via metal-oxygen-metal bond formation).

For depositing metal oxide, the CVD process is generally conducted at reduced pressures, such as from 0.1 Torr to 10 Torr. In some embodiments, the process is conducted at pressures from 1 Torr to 2 Torr. The temperature of the substrate is preferably below the temperature of the reactant streams. For example, the substrate temperature may be from 0° C. to 250° C., or from ambient temperature (e.g., 23° C.) to 150° C.

For depositing agglomerated polymeric materials, the CVD process is generally conducted at reduced pressures, such as from 10 mTorr to 10 Torr. In some embodiments, the process is conducted at from 0.5 to 2 Torr. The temperature of the substrate is preferably at or below the temperature of the reactant streams. For example, the substrate temperature may be from 0° C. to 250° C., or from ambient temperature (e.g., 23° C.) to 150° C. In various processes, deposition of the polymerized organometallic material on the substrate occurs at rates inversely proportional to surface temperature. Without limiting the mechanism, function or utility of present technology, it is believed that the product from such vapor-phase reaction becomes heavier in molecular weight as metal atoms are crosslinked by counter-reactants, and is then condensed or otherwise deposited onto the substrate. In various embodiments, the steric hindrance of the bulky alkyl groups further prevents the formation of densely packed network and produces low density films having increased porosity.

A potential advantage of using dry deposition methods is ease of tuning the composition of the film as it grows. In a CVD process, this may be accomplished by changing the relative flows of a first precursor and a second precursor during deposition. Deposition may occur between 30° C. and 200° C. at pressures between 0.01 Torr to 100 Torr, but more generally between about 0.1 Torr and 10 Torr.

A film (e.g., a metal oxide coating or agglomerated polymeric materials, such as via metal-oxygen-metal bond formation) may also be deposited by an ALD process. For example, the precursor(s) and optional counter-reactant are introduced at separate times, representing an ALD cycle. The precursors react on the surface, forming up to a monolayer of material at a time for each cycle. This may allow for excellent control over the uniformity of film thickness across the surface. The ALD process is generally conducted at reduced pressures, such as from 0.1 Torr to 10 Torr. In some embodiments, the process is conducted from 1 Torr to 2 Torr. The substrate temperature may be from 0° C. to 250° C., or from ambient temperature (e.g., 23° C.) to 150° C. The process may be a thermal process or, preferably, a plasma-assisted deposition.

Any of the deposition methods herein can be modified to allow for use of two or more different precursors. In one embodiment, the precursors can include the same metal but different ligands. In another embodiment, the precursors can include different metal groups. In one non-limiting instance, alternating flows of various volatile precursors can provide a mixed metal-containing layer, such as use of a metal alkoxide precursor having a first metal (e.g., Sn) with a silyl-based precursor having a different second metal (e.g., Te).

Processes herein can be used to achieve a surface modification. In some iterations, a vapor of the precursor may be passed over the wafer. The wafer may be heated to provide thermal energy for the reaction to proceed. In some iterations, the heating can be between about 50° C. to about 250° C. In some cases, pulses of the precursor may be used, separated by pump and/or purging steps. For instance, a first precursor may be pulsed between pulses of a second precursor pulses resulting in ALD or ALD-like growth. In other cases, both precursors may be flowed at the same time. Examples of elements useful for surface modification include I, F, Sn, Bi, Sb, Te, and oxides or alloys of these compounds.

The processes herein can be used to deposit a thin metal oxide or metal by ALD or CVD. Examples include tin oxide (SnOx), bismuth oxide (BiOx), and Te. Following deposition, the film may be capped with an alkyl substituted precursor of the form MₐR_{b}L_{c}, as described elsewhere herein. A counter-reactant may be used to better remove the ligands, and multiple cycles may be repeated to ensure complete saturation of the substrate surface. The surface can then ready for the EUV-sensitive film to be deposited. One possible method is to produce a thin film of SnOx. Possible chemistries include growth of SnO₂ by cycling tetrakis(dimethylamino)tin and a counter-reactant such as water or O₂ plasma. After the growth, a capping agent could be used. For example, isopropyltris(dimethylamino)tin vapor may be flown over the surface.

Deposition processes can be employed on any useful surface. As referred to herein, the “surface” is a surface onto which a film of the present technology is to be deposited or that is to be exposed to EUV during processing. Such a surface can be present on a substrate (e.g., upon which a film is to be deposited), on a film (e.g., upon which a capping layer can be deposited), or on an underlayer.

Any useful substrate can be employed, including any material construct suitable for lithographic processing, particularly for the production of integrated circuits and other semiconducting devices. In some embodiments, substrates are silicon wafers. Substrates may be silicon wafers upon which features have been created (“underlying topographical features”), having an irregular surface topography.

Such underlying topographical features may include regions in which material has been removed (e.g., by etching) or regions in which materials have been added (e.g., by deposition) during processing prior to conducting a method of this technology. Such prior processing may include methods of this technology or other processing methods in an iterative process by which two or more layers of features are formed on the substrate. Without limiting the mechanism, function, or utility of the present technology, it is believed that, in some embodiments, methods of the present technology offer advantages relative to methods among those known in the art in which photolithographic films are deposited on the surface of substrates using spin casting methods. Such advantages may derive from the conformance of the films of the present technology to underlying features without “filling in” or otherwise planarizing such features, and the ability to deposit films on a wide variety of material surfaces.

In some embodiments, the substrate is a hardmask, which is used in lithographic etching of an underlying semiconductor material. The hardmask may comprise any of a variety of materials, including amorphous carbon (a-C), tin oxide (e.g., SnO.), silicon oxide (e.g., SiO₂), silicon oxynitride (e.g., SiOₓN_{y}), silicon oxycarbide (e.g., SiOₓC), silicon nitride (e.g., Si₃N₄), titanium oxide (e.g., TiO₂), titanium nitride (e.g., TiN), tungsten (e.g., W), doped carbon (e.g., W-doped C), tungsten oxide (e.g., WO.), hafnium oxide (e.g., HfO₂), zirconium oxide (e.g., ZrO₂), and aluminum oxide (e.g., Al₂O₃). For example, the substrate may preferably comprise SnOx, such as SnO₂. In various embodiments, the layer may be from 1 nm to 100 nm thick, or from 2 nm to 10 nm thick.

In some non-limiting embodiments, a substrate comprises an underlayer. An underlayer may be deposited on a hardmask or other layer and is generally underneath an imaging layer (or film), as described herein. An underlayer may be used to improve the sensitivity of a PR, increase EUV absorptivity, and/or increase the patterning performance of the PR. In cases where there are device features present on the substrate to be patterned which create significant topography, another important function of the underlayer can be to overcoat and planarize the existing topography so that the subsequent patterning step may be performed on a flat surface with all areas of the pattern in focus. For such applications, the underlayer (or at least one of multiple underlayers) may be applied using spin-coating techniques. When the PR material being employed possesses a significant inorganic component, for example it exhibits a predominately metal oxide framework, the underlayer may advantageously be a carbon-based film, applied either by spin-coating or by dry vacuum-based deposition processes. The layer may include various ashable hardmask (AHM) films with carbon- and hydrogen-based compositions and may be doped with additional elements, such as tungsten, boron, nitrogen, or fluorine.

In various embodiments, the surface (e.g., of the substrate and/or the film) comprises exposed hydroxyl groups on its surface. In general, the surface may be any surface that comprises, or has been treated to produce, an exposed hydroxyl surface. Such hydroxyl groups may be formed on the surface by surface treatment of a substrate using oxygen plasma, water plasma, or ozone. In other embodiments, the surface of the film can be treated to provide exposed hydroxyl groups, upon which a capping layer can be applied. In various embodiments, the hydroxyl-terminated metal oxide layer has a thickness of from 0.1 nm to 20 nm, or from 0.2 nm to 10 nm, or from 0.5 nm to 5 nm.

### EUV Exposure Processes

EUV exposure of the film can provide EUV exposed areas having activated reactive centers including a metal atom (M), which are produced by EUV-mediated cleavage events. Such reactive centers can include dangling metal bonds, M-H groups, cleaved M-ligand groups, dimerized M-M bonds, or M-O-M bridges.

EUV exposure can have a wavelength in the range of about 10 nm to about 20 nm in a vacuum ambient, such as a wavelength of from 10 nm to 15 nm, e.g., 13.5 nm. In particular, patterning can provide EUV exposed areas and EUV unexposed areas to form a pattern.

The present technology can include patterning using EUV, as well as DUV or e-beam. In such patterning, the radiation is focused on one or more regions of the imaging layer. The exposure is typically performed such that imaging layer film comprises one or more regions that are not exposed to the radiation. The resulting imaging layer may comprise a plurality of exposed and unexposed regions, creating a pattern consistent with the creation of transistor or other features of a semiconductor device, formed by addition or removal of material from the substrate in subsequent processing of the substrate. EUV, DUV and e-beam radiation methods and equipment among useful herein include methods and equipment known in the art.

In some EUV lithography techniques, an organic hardmask (e.g., an ashable hardmask of PECVD amorphous hydrogenated carbon) is patterned using a conventional photoresist process. During photoresist exposure, EUV radiation is absorbed in the resist and in the substrate below, producing highly energetic photoelectrons (e.g., about 100 eV) and in turn a cascade of low-energy secondary electrons (e.g., about 10 eV) that diffuse laterally by several nanometers. These electrons increase the extent of chemical reactions in the resist which increases its EUV dose sensitivity. However, a secondary electron pattern that is random in nature is superimposed on the optical image. This unwanted secondary electron exposure results in loss of resolution, observable line edge roughness (LER) and linewidth variation in the patterned resist. These defects are replicated in the material to be patterned during subsequent pattern transfer etching.

A vacuum-integrated metal hardmask process and related vacuum-integrated hardware that combines film formation (deposition/condensation) and optical lithography with the result of greatly improved EUV lithography (EUVL) performance—e.g. reduced line edge roughness—is disclosed herein.

In various embodiments described herein, a deposition (e.g., condensation) process (e.g., ALD or MOCVD carried out in a PECVD tool, such as the Lam Vector®) can be used to form a thin film of a metal-containing film, such a photosensitive metal salt or metal-containing organic compound (organometallic compound), with a strong absorption in the EUV (e.g., at wavelengths on the order of 10 nm to 20 nm), for example at the wavelength of the EUVL light source (e.g., 13.5 nm=91.8 eV). This film photo-decomposes upon EUV exposure and forms a metal mask that is the pattern transfer layer during subsequent etching (e.g., in a conductor etch tool, such as the Lam 2300® Kiyo®).

Following deposition, the EUV-patternable thin film is patterned by exposure to a beam of EUV light, typically under relatively high vacuum. For EUV exposure, the metal-containing film can then be deposited in a chamber integrated with a lithography platform (e.g., a wafer stepper such as the TWINSCAN NXE: 3300B® platform supplied by ASML of Veldhoven, NL) and transferred under vacuum so as not to react before exposure. Integration with the lithography tool is facilitated by the fact that EUVL also requires a greatly reduced pressure given the strong optical absorption of the incident photons by ambient gases such as H₂O, O₂, etc. In other embodiments, the photosensitive metal film deposition and EUV exposure may be conducted in the same chamber.

### Development Processes, Including Dry Development

EUV exposed or unexposed areas can be removed by any useful development process. In one embodiment, the EUV exposed area can have activated reactive centers, such as dangling metal bonds, M-H groups, or dimerized M-M bonds. In particular embodiments, M-H groups can be selectively removed by employing one or more dry development processes (e.g., halide chemistry). In other embodiments, M-M bonds can be selectively removed by employing a wet development process, e.g., use of hot ethanol and water to provide soluble M(OH), groups. In yet other embodiments, EUV exposed areas are removed by use of wet development (e.g., by using a positive tone developer). In some embodiments, EUV unexposed areas are removed by use of dry development.

Dry development processes can include use of halides, such as HCl— or HBr-based processes. While this disclosure is not limited to any particular theory or mechanism of operation, the approach is understood to leverage the chemical reactivity of the dry-deposited EUV photoresist films with the clean chemistry (e.g., HCl, HBr, and BCl₃) to form volatile products using vapors or plasma. The dry-deposited EUV photoresist films can be removed with etch rates of up to 1 nm/s. The quick removal of dry-deposited EUV photoresist films by these chemistries is applicable to chamber cleaning, backside clean, bevel clean, and PR developing. Although the films can be removed using vapors at various temperatures (e.g., HCl or HBr at a temperature greater than −10° C., or BCl₃ at a temperature greater than 80° C., for example), a plasma can also be used to further accelerate or enhance the reactivity.

Plasma processes include transformer coupled plasma (TCP), inductively coupled plasma (ICP) or capacitively coupled plasma (CCP), employing equipment and techniques among those known in the art. For example, a process may be conducted at a pressure of >0.5 mTorr (e.g., such as from 1 mTorr to 100 mTorr), at a power level of <1000 W (e.g., <500 W). Temperatures may be from 30° C. to 300° C. (e.g., 30° C. to 120° C.), at flow rate of 100 to 1000 standard cubic centimeters per minute (sccm), e.g., about 500 sccm, for from 1 to 3000 seconds (e.g., 10 seconds to 600 seconds).

Where the halide reactant flows are of hydrogen gas and halide gas, a remote plasma/UV radiation is used to generate radicals from the H₂ and Cl₂ and/or Br₂, and the hydrogen and halide radicals are flowed to the reaction chamber to contact the patterned EUV photoresist on the substrate layer of the wafer. Suitable plasma power may range from 100 W to 500 W, with no bias. It should be understood that while these conditions are suitable for some processing reactors, e.g., a Kiyo etch tool available from Lam Research Corporation, Fremont, Calif., a wider range of process conditions may be used according to the capabilities of the processing reactor.

In thermal development processes, the substrate is exposed to dry development chemistry (e.g., a Lewis Acid) in a vacuum chamber (e.g., oven). Suitable chambers can include a vacuum line, a dry development hydrogen halide chemistry gas (e.g., HBr, HCl) line, and heaters for temperature control. In some embodiments, the chamber interior can be coated with corrosion resistant films, such as organic polymers or inorganic coatings. One such coating is polytetrafluoroethylene ((PTFE), e.g., Teflon™). Such materials can be used in thermal processes of this disclosure without risk of removal by plasma exposure.

The process conditions for the dry development may be reactant flow of 100 sccm to 500 sccm (e.g., 500 sccm HBr or HCl), temperature of −10° C. to 120° C. (e.g., −10° C.), pressure of 1 mTorr to 500 mTorr (e.g., 300 mTorr) with no plasma and for a time of about 10 sec to 1 min, dependent on the photoresist film and their composition and properties.

In various embodiments, methods of the present disclosure combine all dry steps of film deposition, formation by vapor deposition, (EUV) lithographic photopatterning, and dry development. In such processes, a substrate may directly go to a dry development/etch chamber following photopatterning in an EUV scanner. Such processes may avoid material and productivity costs associated with a wet development. A dry process can also provide more tunability and give further CD control and/or scum removal.

In various embodiments, the EUV photoresist, containing some amount of metal, metal oxide and organic components, can be dry developed by a thermal, plasma (e.g., including possibly photoactivated plasma, such as lamp-heated or UV lamp heated), or a mixture of thermal and plasma methods while flowing a dry development gas including a compound of formula R Z_{y}, where R═B, Al, Si, C, S, SO with x>0 and Z═Cl, H, Br, F, CH₄ and y>0. The dry development can result in a positive tone, in which the RₓZ_{y} species selectively removes the exposed material, leaving behind the unexposed counterpart as a mask. In some embodiments, the exposed portions of organotin oxide-based photoresist films are removed by dry development in accordance with this disclosure. Positive tone dry development may be achieved by the selective dry development (removal) of EUV exposed regions exposed to flows comprising hydrogen halides or hydrogen and halides, including HCl and/or HBr without striking a plasma, or flows of H₂ and Cl₂ and/or Br₂ with a remote plasma or UV radiation generated from plasma to generate radicals.

Wet development methods can also be employed. In particular embodiments, such wet developments methods are used to remove EUV exposed regions to provide a positive tone photoresist or a negative tone resist. Exemplary, non-limiting wet development can include use of an alkaline developer (e.g., an aqueous alkaline developer), such as those including ammonium, e.g., ammonium hydroxide (NH₄OH); ammonium-based ionic liquids, e.g., tetramethylammonium hydroxide (TMAH), tetraethylammonium hydroxide (TEAH), tetrapropylammonium hydroxide (TPAH), tetrabutylammonium hydroxide (TBAH), or other quaternary alkylammonium hydroxides; an organoamine, such as mono-, di-, and tri-organoamines (e.g., dimethylamine, diethylamine, ethylenediamine, triethylenetetramine); or an alkanolamine, such as monoethanolamine, diethanolamine, triethanolamine, or diethyleneglycolamine. In other embodiments, the alkaline developer can include nitrogen-containing bases, e.g., compounds having the formula R^{N1}NH₂, R^{N1}R^{N2}NH, R^{N1}R^{N2}R^{N3}N, or R^{N1}R^{N2}R^{N3}R^{N4}N⁺X^{N1-}, where each of R^{N1}, R^{N2}, R^{N3}, and R^{N4} is, independently, an organo substituent (e.g., optionally substituted alkyl or any described herein), or two or more organo substituents that can be joined together, and X^{N1-} may comprise OH⁻, F⁻, Cl⁻, Br⁻, I⁻, or other art-known quaternary ammonium cationic species. These bases may also comprise heterocyclyl nitrogen compounds known in the art, some of which are described herein.

Other development methodologies can include use of an acidic developer (e.g., an aqueous acidic developer or an acid developer in an organic solvent) that includes a halide (e.g., HCl or HBr), an organic acid (e.g., formic acid, acetic acid, or citric acid), or an organofluorine compound (e.g., trifluoroacetic acid); or use of an organic developer, such as a ketone (e.g., 2-heptanone, cyclohexanone, or acetone), an ester (e.g., γ-butyrolactone or ethyl 3-ethoxypropionate (EEP)), an alcohol (e.g., isopropyl alcohol (IPA)), or an ether, such as a glycol ether (e.g., propylene glycol methyl ether (PGME) or propylene glycol methyl ether acetate (PGMEA)), as well as combinations thereof.

In particular embodiments, the positive tone developer is an aqueous alkaline developer (e.g., including NH₄OH, TMAH, TEAH, TPAH, or TBAH). In other embodiments, the negative tone developer is an aqueous acidic developer, an acidic developer in an organic solvent, or an organic developer (e.g., HCl, HBr, formic acid, trifluoroacetic acid, 2-heptanone, IPA, PGME, PGMEA, or combinations thereof).

### Post-Application Processes

The methods herein can include any useful post-application processes, as described below.

For the backside and bevel clean process, the vapor and/or the plasma can be limited to a specific region of the wafer to ensure that only the backside and the bevel are removed, without any film degradation on the frontside of the wafer. The dry-deposited EUV photoresist films being removed are generally composed of Sn, O and C, but the same clean approaches can be extended to films of other metal oxide resists and materials. In addition, this approach can also be used for film strip and PR rework.

Suitable process conditions for a dry bevel edge and backside clean may be a reactant flow of 100 sccm to 500 sccm (e.g., 500 sccm HCl, HBr, or H₂ and Cl₂ or Br₂, BCl₃ or H₂), temperature of −10° C. to 120° C. (e.g., 20° C.), pressure of 20 mTorr to 500 mTorr (e.g., 300 mTorr), plasma power of 0 to 500 W at high frequency (e.g., 13.56 MHz), and for a time of about 10 sec to 20 sec, dependent on the photoresist film and composition and properties. It should be understood that while these conditions are suitable for some processing reactors, e.g., a Kiyo etch tool available from Lam Research Corporation, Fremont, Calif., a wider range of process conditions may be used according to the capabilities of the processing reactor.

Photolithography processes typically involve one or more bake steps, to facilitate the chemical reactions required to produce chemical contrast between exposed and unexposed areas of the photoresist. For high volume manufacturing (HVM), such bake steps are typically performed on tracks where the wafers are baked on a hot-plate at a pre-set temperature under ambient air or in some cases N₂ flow. More careful control of the bake ambient as well as introduction of additional reactive gas component in the ambient during these bake steps can help further reduce the dose requirement and/or improve pattern fidelity.

According to various aspects of this disclosure, one or more post treatments to metal and/or metal oxide-based photoresists after deposition (e.g., post-application bake (PAB)) and/or exposure (e.g., post-exposure bake (PEB)) and/or development (e.g., post-development bake (PDB)) are capable of increasing material property differences between exposed and unexposed photoresist and therefore decreasing dose to size (DtS), improving PR profile, and improving line edge and width roughness (LER/LWR) after subsequent dry development. Such processing can involve a thermal process with the control of temperature, gas ambient, and moisture, resulting in improved dry development performance in processing to follow. In some instances, a remote plasma might be used.

In the case of post-application processing (e.g., PAB), a thermal process with control of temperature, gas ambient (e.g., air, H₂O, CO₂, CO, O₂, O₃, CH₄, CH₃OH, N₂, H₂, NH₃, N₂O, NO, Ar, He, or their mixtures) or under vacuum, and moisture can be used after deposition and before exposure to change the composition of unexposed metal and/or metal oxide photoresist. The change can increase the EUV sensitivity of the material and thus lower dose to size and edge roughness can be achieved after exposure and dry development.

In the case of post-exposure processing (e.g., PEB), a thermal process with the control of temperature, gas atmosphere (e.g., air, H₂O, CO₂, CO, O₂, O₃, CH₄, CH₃OH, N₂, H₂, NH₃, N₂O, NO, Ar, He, or their mixtures) or under vacuum, and moisture can be used to change the composition of both unexposed and exposed photoresist. The change can increase the composition/material properties difference between the unexposed and exposed photoresist and the etch rate difference of dry development etch gas between the unexposed and exposed photoresist. A higher etch selectivity can thereby be achieved. Due to the improved selectivity, a squarer PR profile can be obtained with improved surface roughness, and/or less photoresist residual/scum. In particular embodiments, PEB can be performed in air and in the optional presence of moisture and CO₂.

In the case of post-development processing (e.g., post development bake or PDB), a thermal process with the control of temperature, gas atmosphere (e.g., air, H₂O, CO₂, CO, O₂, O₃, CH₄, CH₃OH, N₂, H₂, NH₃, N₂O, NO, Ar, He, or their mixtures) or under vacuum (e.g., with UV), and moisture can be used to change the composition of the unexposed photoresist. In particular embodiments, the condition also includes use of plasma (e.g., including O₂, O₃, Ar, He, or their mixtures). The change can increase the hardness of material, which can be beneficial if the film will be used as a resist mask when etching the underlying substrate.

In these cases, in alternative implementations, the thermal process could be replaced by a remote plasma process to increase reactive species to lower the energy barrier for the reaction and increase productivity. Remote plasma can generate more reactive radicals and therefore lower the reaction temperature/time for the treatment, leading to increased productivity.

Accordingly, one or multiple processes may be applied to modify the photoresist itself to increase dry development selectivity. This thermal or radical modification can increase the contrast between unexposed and exposed material and thus increase the selectivity of the subsequent dry development step. The resulting difference between the material properties of unexposed and exposed material can be tuned by adjusting process conditions including temperature, gas flow, moisture, pressure, and/or RF power. The large process latitude enabled by dry development, which is not limited by material solubility in a wet developer solvent, allows more aggressive conditions to be applied further enhancing the material contrast that can be achieved. The resulting high material contrast feeds back a wider process window for dry development and thus enables increased productivity, lower cost, and better defectivity performance.

A substantial limitation of wet-developed resist films is limited temperature bakes. Since wet development relies on material solubility, heating to or beyond 220° C., for example, can greatly increase the degree of cross-linking in both exposed and unexposed regions of a metal-containing PR film such that both become insoluble in the wet development solvents, so that the film can no longer by reliably wet developed. For dry-developed resist films, in which the etch rate difference (i.e., selectivity) between the exposed and unexposed regions of the PR is relied upon for removal of just the exposed or unexposed portion of the resist, the treatment temperature in a PAB, PEB, or PDB can be varied across a much broader window to tune and optimize the treatment process, for example from about 90° C. to 250° C., such as 90° C. to 190° C., for PAB, and about 170° C. to 250° C. or more, such as 190° C. to 240° C., for PEB and/or PDB. Decreasing etch rate and greater etch selectivity has been found to occur with higher treatment temperatures in the noted ranges.

In particular embodiments, the PAB, PEB, and/or PDB treatments may be conducted with gas ambient flow in the range of 100 sccm to 10000 sccm, moisture content in the amount of a few percent up to 100% (e.g., 20%-50%), at a pressure between atmospheric and vacuum, and for a duration of about 1 to 15 minutes, for example about 2 minutes.

These findings can be used to tune the treatment conditions to tailor or optimize processing for particular materials and circumstances. For example, the selectivity achieved for a given EUV dose with a 220° C. to 250° C. PEB thermal treatment in air at about 20% humidity for about 2 minutes can be made similar to that for about a 30% higher EUV dose with no such thermal treatment. So, depending on the selectivity requirements/constraints of the semiconductor processing operation, a thermal treatment such as described herein can be used to lower the EUV dose needed. Or, if higher selectivity is required and higher dose can be tolerated, much higher selectivity, up to 100 times exposed vs. unexposed, can be obtained than would be possible in a wet development context.

Yet other steps can include in situ metrology, in which physical and structural characteristics (e.g., critical dimension, film thickness, etc.) can be assessed during the photolithography process. Modules to implement in situ metrology include, e.g., scatterometry, ellipsometry, downstream mass spectroscopy, and/or plasma enhanced downstream optical emission spectroscopy modules.

### Apparatuses

The present disclosure also includes any apparatus configured to perform any methods described herein. In one embodiment, the apparatus for depositing a film includes a deposition module comprising a chamber for depositing one or more precursor(s) to provide an imaging layer and/or a radiation-absorbing layer: a patterning module comprising an EUV photolithography tool with a source of sub-30 nm wavelength radiation; and a development module comprising a chamber for developing a film including such layers.

The apparatus can further include a controller having instructions for such modules. In one embodiment, the controller includes one or more memory devices, one or more processors, and system control software coded with instructions for conducting deposition of the film. Such includes can include for, in the deposition module, depositing one or more precursor(s) to provide an imaging layer and/or a radiation-absorbing layer; in the patterning module, patterning the layer(s) with sub-30 nm resolution directly by EUV exposure, thereby forming a pattern within the film; and in the development module, developing the film. In particular embodiments, the development module provides for removal of the EUV exposed or EUV unexposed area(s), thereby providing a pattern within the film.

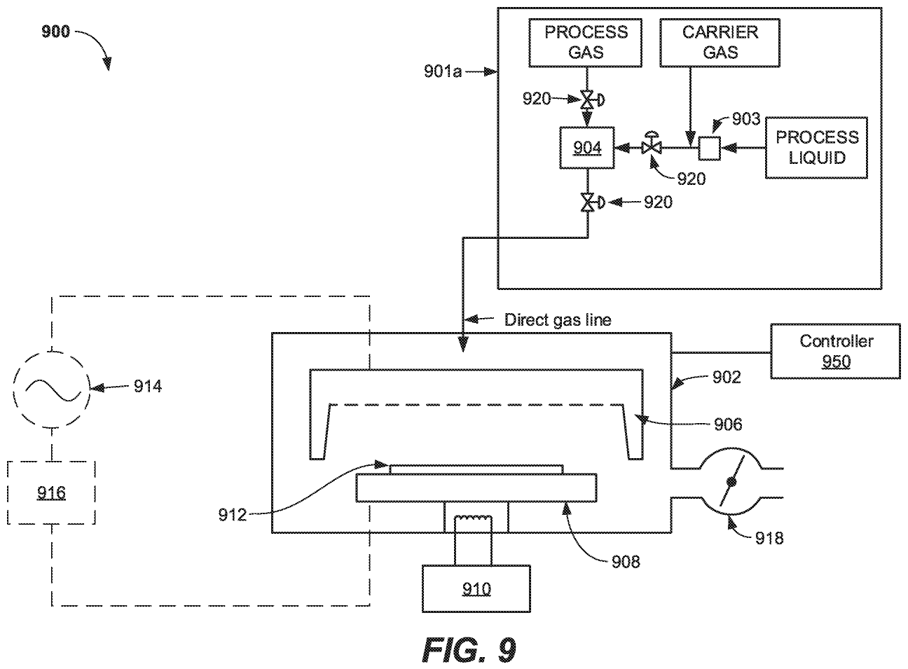

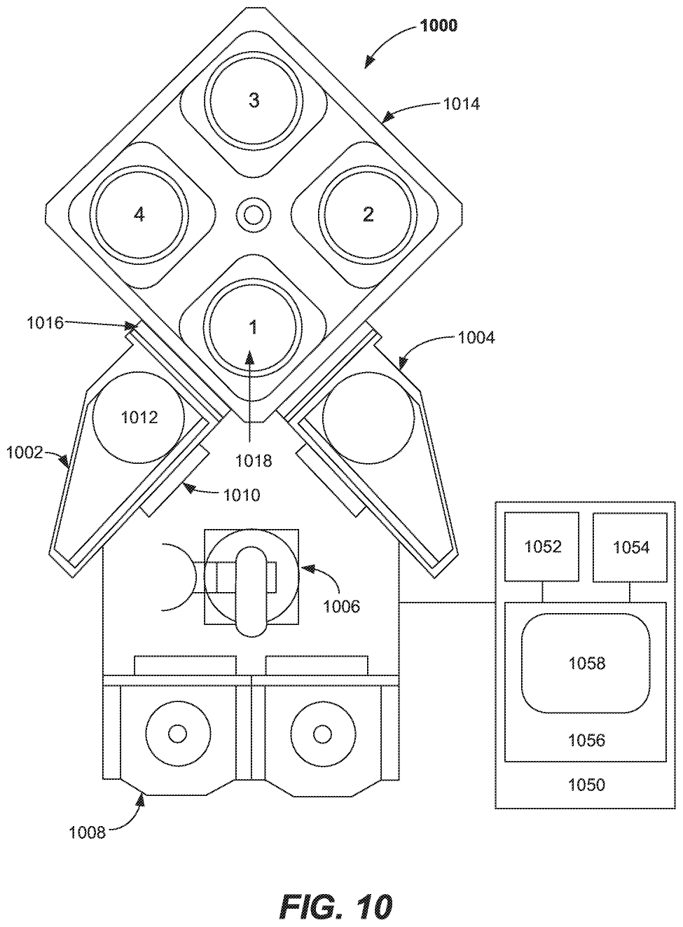

FIG. 9 depicts a schematic illustration of an embodiment of process station 900 having a process chamber body 902 for maintaining a low-pressure environment that is suitable for implementation of described dry deposition and development embodiments as described herein. A plurality of process stations 900 may be included in a common low pressure process tool environment. For example, FIG. 10 depicts an embodiment of a multi-station processing tool 1000, such as a VECTOR® processing tool available from Lam Research Corporation, Fremont, Calif. In some embodiments, one or more hardware parameters of the process station 900 including those discussed in detail below may be adjusted programmatically by one or more computer controllers 950.

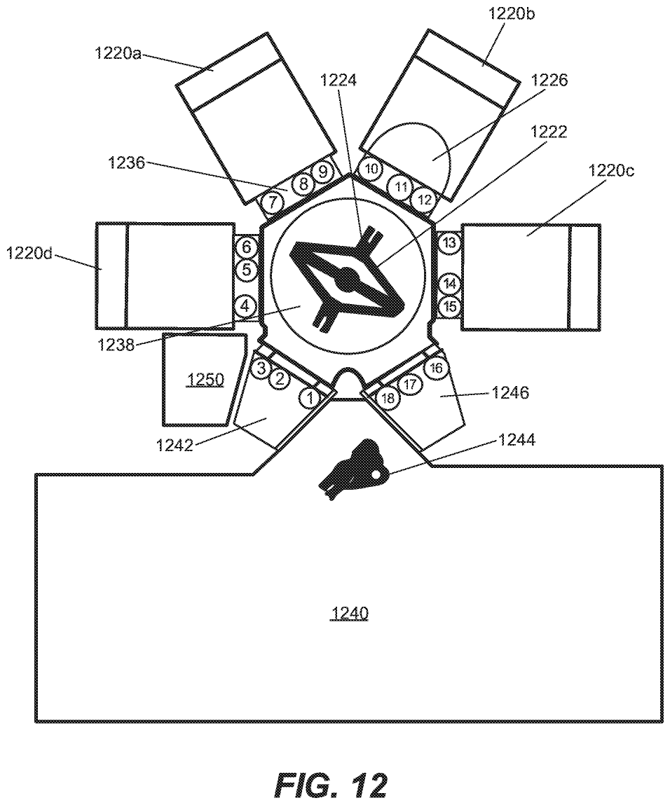

A process station may be configured as a module in a cluster tool. FIG. 12 depicts a semiconductor process cluster tool architecture with vacuum-integrated deposition and patterning modules suitable for implementation of the embodiments described herein. Such a cluster process tool architecture can include resist deposition, resist exposure (EUV scanner), resist dry development and etch modules, as described above and further below with reference to FIGS. 9-11 and 13.

In some embodiments, certain of the processing functions can be performed consecutively in the same module, for example dry development and etch. And embodiments of this disclosure are directed to methods and apparatus for receiving a wafer, including a photopatterned EUV resist thin film layer disposed on a layer or layer stack to be etched, to a dry development/etch chamber following photopatterning in an EUV scanner; dry developing photopatterned EUV resist thin film layer; and then etching the underlying layer using the patterned EUV resist as a mask, as described herein.

Returning to FIG. 9, process station 900 fluidly communicates with reactant delivery system 901a for delivering process gases to a distribution showerhead 906. Reactant delivery system 901a optionally includes a mixing vessel 904 for blending and/or conditioning process gases, for delivery to showerhead 906. One or more mixing vessel inlet valves 920 may control introduction of process gases to mixing vessel 904. Where plasma exposure is used, plasma may also be delivered to the showerhead 906 or may be generated in the process station 900. As noted above, in at least some embodiments, non-plasma thermal exposure is favored.

FIG. 9 includes an optional vaporization point 903 for vaporizing liquid reactant to be supplied to the mixing vessel 904. In some embodiments, a liquid flow controller (LFC) upstream of vaporization point 903 may be provided for controlling a mass flow of liquid for vaporization and delivery to process station 900. For example, the LFC may include a thermal mass flow meter (MFM) located downstream of the LFC. A plunger valve of the LFC may then be adjusted responsive to feedback control signals provided by a proportional-integral-derivative (PID) controller in electrical communication with the MFM.

Showerhead 906 distributes process gases toward substrate 912. In the embodiment shown in FIG. 9, the substrate 912 is located beneath showerhead 906 and is shown resting on a pedestal 908. Showerhead 906 may have any suitable shape, and may have any suitable number and arrangement of ports for distributing process gases to substrate 912.

In some embodiments, pedestal 908 maybe raised or lowered to expose substrate 912 to a volume between the substrate 912 and the showerhead 906. It will be appreciated that, in some embodiments, pedestal height may be adjusted programmatically by a suitable computer controller 950.

In some embodiments, pedestal 908 may be temperature controlled via heater 910. In some embodiments, the pedestal 908 may be heated to a temperature of greater than 0° C. and up to 300° C. or more, for example 50 to 120° C., such as about 65 to 80° C., during non-plasma thermal exposure of a photopatterned resist to hydrogen halide dry development chemistry, such as HBr, HCl, or BCl₃, as described in disclosed embodiments.

Further, in some embodiments, pressure control for process station 900 may be provided by a butterfly valve 918. As shown in the embodiment of FIG. 9, butterfly valve 918 throttles a vacuum provided by a downstream vacuum pump (not shown). However, in some embodiments, pressure control of process station 900 may also be adjusted by varying a flow rate of one or more gases introduced to the process station 900.

In some embodiments, a position of showerhead 906 may be adjusted relative to pedestal 908 to vary a volume between the substrate 912 and the showerhead 906. Further, it will be appreciated that a vertical position of pedestal 908 and/or showerhead 906 may be varied by any suitable mechanism within the scope of the present disclosure. In some embodiments, pedestal 908 may include a rotational axis for rotating an orientation of substrate 912. It will be appreciated that, in some embodiments, one or more of these example adjustments may be performed programmatically by one or more suitable computer controllers 950.

Where plasma may be used, for example in gentle plasma-based dry development embodiments and/or etch operations conducted in the same chamber, showerhead 906 and pedestal 908 electrically communicate with a radio frequency (RF) power supply 914 and matching network 916 for powering a plasma. In some embodiments, the plasma energy may be controlled by controlling one or more of a process station pressure, a gas concentration, an RF source power, an RF source frequency, and a plasma power pulse timing. For example, RF power supply 914 and matching network 916 may be operated at any suitable power to form a plasma having a desired composition of radical species. Examples of suitable powers are up to about 500 W.

In some embodiments, instructions for a controller 950 may be provided via input/output control (IOC) sequencing instructions. In one example, the instructions for setting conditions for a process phase may be included in a corresponding recipe phase of a process recipe. In some cases, process recipe phases may be sequentially arranged, so that all instructions for a process phase are executed concurrently with that process phase. In some embodiments, instructions for setting one or more reactor parameters may be included in a recipe phase. For example, a recipe phase may include instructions for setting a flow rate of a dry development chemistry reactant gas, such as HBr or HCl, and time delay instructions for the recipe phase. In some embodiments, the controller 950 may include any of the features described below with respect to system controller 1050 of FIG. 10.

As described above, one or more process stations may be included in a multi-station processing tool. FIG. 10 shows a schematic view of an embodiment of a multi-station processing tool 1000 with an inbound load lock 1002 and an outbound load lock 1004, either or both of which may include a remote plasma source. A robot 1006 at atmospheric pressure is configured to move wafers from a cassette loaded through a pod 1008 into inbound load lock 1002 via an atmospheric port 1010. A wafer is placed by the robot 1006 on a pedestal 1012 in the inbound load lock 1002, the atmospheric port 1010 is closed, and the load lock is pumped down. Where the inbound load lock 1002 includes a remote plasma source, the wafer may be exposed to a remote plasma treatment to treat the silicon nitride surface in the load lock prior to being introduced into a processing chamber 1014. Further, the wafer also may be heated in the inbound load lock 1002 as well, for example, to remove moisture and adsorbed gases. Next, a chamber transport port 1016 to processing chamber 1014 is opened, and another robot (not shown) places the wafer into the reactor on a pedestal of a first station shown in the reactor for processing. While the embodiment depicted in FIG. 10 includes load locks, it will be appreciated that, in some embodiments, direct entry of a wafer into a process station may be provided.

The depicted processing chamber 1014 includes four process stations, numbered from 1 to 4 in the embodiment shown in FIG. 10. Each station has a heated pedestal (shown at 1018 for station 1), and gas line inlets. It will be appreciated that in some embodiments, each process station may have different or multiple purposes. For example, in some embodiments, a process station may be switchable between dry development and etch process modes. Additionally or alternatively, in some embodiments, processing chamber 1014 may include one or more matched pairs of dry development and etch process stations. Also, in some embodiments, for depositing a EUV resist film with a vertically graded composition, a multi-station processing tool may be configured to deposit a series (e.g., four) sequential homogeneous stepped absorption layer, thereby increasing the density of atoms with high EUV absorptivity at the bottom of the film relative to the top of the film. While the depicted processing chamber 1014 includes four stations, it will be understood that a processing chamber according to the present disclosure may have any suitable number of stations. For example, in some embodiments, a processing chamber may have five or more stations, while in other embodiments a processing chamber may have three or fewer stations.

FIG. 10 depicts an embodiment of a wafer handling system 1090 for transferring wafers within processing chamber 1014. In some embodiments, wafer handling system 1090 may transfer wafers between various process stations and/or between a process station and a load lock. It will be appreciated that any suitable wafer handling system may be employed. Non-limiting examples include wafer carousels and wafer handling robots. FIG. 10 also depicts an embodiment of a system controller 1050 employed to control process conditions and hardware states of process tool 1000. System controller 1050 may include one or more memory devices 1056, one or more mass storage devices 1054, and one or more processors 1052. Processor 1052 may include a CPU or computer, analog, and/or digital input/output connections, stepper motor controller boards, etc.

In some embodiments, system controller 1050 controls all of the activities of process tool 1000. System controller 1050 executes system control software 1058 stored in mass storage device 1054, loaded into memory device 1056, and executed on processor 1052. Alternatively, the control logic may be hard coded in the controller 1050. Applications Specific Integrated Circuits, Programmable Logic Devices (e.g., field-programmable gate arrays, or FPGAs) and the like may be used for these purposes. In the following discussion, wherever “software” or “code” is used, functionally comparable hard coded logic may be used in its place. System control software 1058 may include instructions for controlling the timing, mixture of gases, gas flow rates, chamber and/or station pressure, chamber and/or station temperature, wafer temperature, target power levels, RF power levels, substrate pedestal, chuck and/or susceptor position, and other parameters of a particular process performed by process tool 1000. System control software 1058 may be configured in any suitable way. For example, various process tool component subroutines or control objects may be written to control operation of the process tool components used to carry out various process tool processes. System control software 1058 may be coded in any suitable computer readable programming language.

In some embodiments, system control software 1058 may include input/output control (IOC) sequencing instructions for controlling the various parameters described above. Other computer software and/or programs stored on mass storage device 1054 and/or memory device 1056 associated with system controller 1050 may be employed in some embodiments. Examples of programs or sections of programs for this purpose include a substrate positioning program, a process gas control program, a pressure control program, a heater control program, and a plasma control program.

A substrate positioning program may include program code for process tool components that are used to load the substrate onto pedestal 1018 and to control the spacing between the substrate and other parts of process tool 1000.

A process gas control program may include code for controlling hydrogen halide gas composition (e.g., HBr or HCl gas as described herein) and flow rates and optionally for flowing gas into one or more process stations prior to deposition in order to stabilize the pressure in the process station. A pressure control program may include code for controlling the pressure in the process station by regulating, for example, a throttle valve in the exhaust system of the process station, a gas flow into the process station, etc.

A heater control program may include code for controlling the current to a heating unit that is used to heat the substrate. Alternatively, the heater control program may control delivery of a heat transfer gas (such as helium) to the substrate.

A plasma control program may include code for setting RF power levels applied to the process electrodes in one or more process stations in accordance with the embodiments herein.

A pressure control program may include code for maintaining the pressure in the reaction chamber in accordance with the embodiments herein.

In some embodiments, there may be a user interface associated with system controller 1050. The user interface may include a display screen, graphical software displays of the apparatus and/or process conditions, and user input devices such as pointing devices, keyboards, touch screens, microphones, etc.

In some embodiments, parameters adjusted by system controller 1050 may relate to process conditions. Non-limiting examples include process gas composition and flow rates, temperature, pressure, plasma conditions (such as RF bias power levels), etc. These parameters may be provided to the user in the form of a recipe, which may be entered utilizing the user interface.

Signals for monitoring the process may be provided by analog and/or digital input connections of system controller 1050 from various process tool sensors. The signals for controlling the process may be output on the analog and digital output connections of process tool 1000. Non-limiting examples of process tool sensors that may be monitored include mass flow controllers, pressure sensors (such as manometers), thermocouples, etc. Appropriately programmed feedback and control algorithms may be used with data from these sensors to maintain process conditions.

System controller 1050 may provide program instructions for implementing the above-described deposition processes. The program instructions may control a variety of process parameters, such as DC power level, RF bias power level, pressure, temperature, etc. The instructions may control the parameters to operate dry development and/or etch processes according to various embodiments described herein.

The system controller 1050 will typically include one or more memory devices and one or more processors configured to execute the instructions so that the apparatus will perform a method in accordance with disclosed embodiments. Machine-readable media containing instructions for controlling process operations in accordance with disclosed embodiments may be coupled to the system controller 1050.

In some implementations, the system controller 1050 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The system controller 1050, depending on the processing conditions and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the system controller 1050 may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the system controller 1050 in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The system controller 1050, in some implementations, may be a part of or coupled to a computer that is integrated with, coupled to the system, otherwise networked to the system, or a combination thereof. For example, the system controller 1050 may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the system controller 1050 receives instructions in the form of data, which specify parameters for each of the processing steps to be performed during one or more operations. It should be understood that the parameters may be specific to the type of process to be performed and the type of tool that the system controller 1050 is configured to interface with or control. Thus, as described above, the system controller 1050 may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an ALD chamber or module, an atomic layer etch (ALE) chamber or module, an ion implantation chamber or module, a track chamber or module, an EUV lithography chamber (scanner) or module, a dry development chamber or module, and any other semiconductor processing systems that may be associated or used in the fabrication and/or manufacturing of semiconductor wafers.

As noted above, depending on the process step or steps to be performed by the tool, the system controller 1050 might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

Inductively coupled plasma (ICP) reactors which, in certain embodiments, may be suitable for etch operations suitable for implementation of some embodiments, are now described. Although ICP reactors are described herein, in some embodiments, it should be understood that capacitively coupled plasma reactors may also be used.

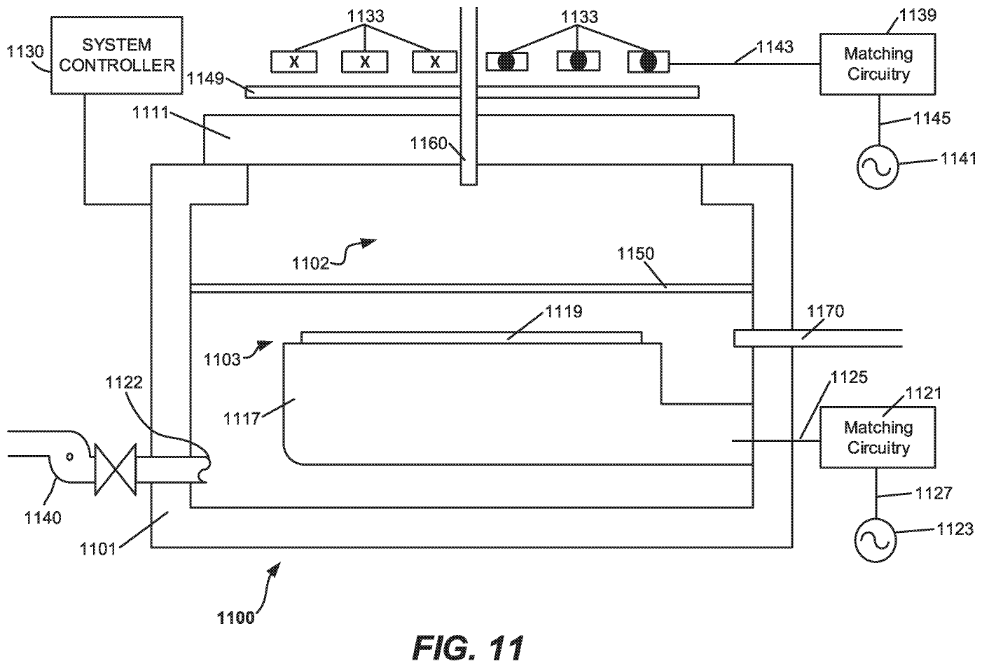

FIG. 11 schematically shows a cross-sectional view of an inductively coupled plasma apparatus 1100 appropriate for implementing certain embodiments or aspects of embodiments such as dry development and/or etch, an example of which is a Kiyo® reactor, produced by Lam Research Corp. of Fremont, Calif. In other embodiments, other tools or tool types having the functionality to conduct the dry development and/or etch processes described herein may be used for implementation.

The inductively coupled plasma apparatus 1100 includes an overall process chamber 1124 structurally defined by chamber walls 1101 and a window 1111. The chamber walls 1101 may be fabricated from stainless steel or aluminum. The window 1111 may be fabricated from quartz or other dielectric material. An optional internal plasma grid 1150 divides the overall process chamber into an upper sub-chamber 1102 and a lower sub chamber 1103. In most embodiments, plasma grid 1150 may be removed, thereby utilizing a chamber space made of sub chambers 1102 and 1103. A chuck 1117 is positioned within the lower sub-chamber 1103 near the bottom inner surface. The chuck 1117 is configured to receive and hold a semiconductor wafer 1119 upon which the etching and deposition processes are performed. The chuck 1117 can be an electrostatic chuck for supporting the wafer 1119 when present. In some embodiments, an edge ring (not shown) surrounds chuck 1117, and has an upper surface that is approximately planar with a top surface of the wafer 1119, when present over chuck 1117. The chuck 1117 also includes electrostatic electrodes for chucking and dechucking the wafer 1119. A filter and DC clamp power supply (not shown) may be provided for this purpose. Other control systems for lifting the wafer 1119 off the chuck 1117 can also be provided. The chuck 1117 can be electrically charged using an RF power supply 1123. The RF power supply 1123 is connected to matching circuitry 1121 through a connection 1127. The matching circuitry 1121 is connected to the chuck 1117 through a connection 1125. In this manner, the RF power supply 1123 is connected to the chuck 1117. In various embodiments, a bias power of the electrostatic chuck may be set at about 50V or may be set at a different bias power depending on the process performed in accordance with disclosed embodiments. For example, the bias power may be between about 20 V and about 100 V, or between about 30 V and about 150 V.

Elements for plasma generation include a coil 1133 is positioned above window 1111. In some embodiments, a coil is not used in disclosed embodiments. The coil 1133 is fabricated from an electrically conductive material and includes at least one complete turn. The example of a coil 1133 shown in FIG. 11 includes three turns. The cross sections of coil 1133 are shown with symbols, and coils having an “X” extend rotationally into the page, while coils having a “e” extend rotationally out of the page. Elements for plasma generation also include an RF power supply 1141 configured to supply RF power to the coil 1133. In general, the RF power supply 1141 is connected to matching circuitry 1139 through a connection 1145. The matching circuitry 1139 is connected to the coil 1133 through a connection 1143. In this manner, the RF power supply 1141 is connected to the coil 1133. An optional Faraday shield 1149a is positioned between the coil 1133 and the window 1111. The Faraday shield 1149a may be maintained in a spaced apart relationship relative to the coil 1133. In some embodiments, the Faraday shield 1149a is disposed immediately above the window 1111. In some embodiments, the Faraday shield 1149b is between the window 1111 and the chuck 1117. In some embodiments, the Faraday shield 1149b is not maintained in a spaced apart relationship relative to the coil 1133. For example, the Faraday shield 1149b may be directly below the window 1111 without a gap. The coil 1133, the Faraday shield 1149a, and the window 1111 are each configured to be substantially parallel to one another. The Faraday shield 1149a may prevent metal or other species from depositing on the window 1111 of the process chamber 1124.

Process gases may be flowed into the process chamber through one or more main gas flow inlets 1160 positioned in the upper sub-chamber 1102 and/or through one or more side gas flow inlets 1170. Likewise, though not explicitly shown, similar gas flow inlets may be used to supply process gases to a capacitively coupled plasma processing chamber. A vacuum pump, e.g., a one or two stage mechanical dry pump and/or turbomolecular pump 1140, may be used to draw process gases out of the process chamber 1124 and to maintain a pressure within the process chamber 1124. For example, the vacuum pump may be used to evacuate the lower sub-chamber 1103 during a purge operation of ALD. A valve-controlled conduit may be used to fluidically connect the vacuum pump to the process chamber 1124 so as to selectively control application of the vacuum environment provided by the vacuum pump. This may be done employing a closed loop-controlled flow restriction device, such as a throttle valve (not shown) or a pendulum valve (not shown), during operational plasma processing. Likewise, a vacuum pump and valve controlled fluidic connection to the capacitively coupled plasma processing chamber may also be employed.

During operation of the apparatus 1100, one or more process gases may be supplied through the gas flow inlets 1160 and/or 1170. In certain embodiments, process gas may be supplied only through the main gas flow inlet 1160, or only through the side gas flow inlet 1170. In some cases, the gas flow inlets shown in the figure may be replaced by more complex gas flow inlets, one or more showerheads, for example. The Faraday shield 1149a and/or optional grid 1150 may include internal channels and holes that allow delivery of process gases to the process chamber 1124. Either or both of Faraday shield 1149a and optional grid 1150 may serve as a showerhead for delivery of process gases. In some embodiments, a liquid vaporization and delivery system may be situated upstream of the process chamber 1124, such that once a liquid reactant or precursor is vaporized, the vaporized reactant or precursor is introduced into the process chamber 1124 via a gas flow inlet 1160 and/or 1170.

Radio frequency power is supplied from the RF power supply 1141 to the coil 1133 to cause an RF current to flow through the coil 1133. The RF current flowing through the coil 1133 generates an electromagnetic field about the coil 1133. The electromagnetic field generates an inductive current within the upper sub-chamber 1102. The physical and chemical interactions of various generated ions and radicals with the wafer 1119 etch features of and selectively deposit layers on the wafer 1119.

If the plasma grid 1150 is used such that there is both an upper sub-chamber 1102 and a lower sub-chamber 1103, the inductive current acts on the gas present in the upper sub-chamber 1102 to generate an electron-ion plasma in the upper sub-chamber 1102. The optional internal plasma grid 1150 limits the amount of hot electrons in the lower sub-chamber 1103. In some embodiments, the apparatus 1100 is designed and operated such that the plasma present in the lower sub-chamber 1103 is an ion-ion plasma.

Both the upper electron-ion plasma and the lower ion-ion plasma may contain positive and negative ions, though the ion-ion plasma will have a greater ratio of negative ions to positive ions. Volatile etching and/or deposition byproducts may be removed from the lower sub-chamber 1103 through port 1122. The chuck 1117 disclosed herein may operate at elevated temperatures ranging between about 10° C. and about 250° C. The temperature will depend on the process operation and specific recipe.

Apparatus 1100 may be coupled to facilities (not shown) when installed in a clean room or a fabrication facility. Facilities include plumbing that provide processing gases, vacuum, temperature control, and environmental particle control. These facilities are coupled to apparatus 1100, when installed in the target fabrication facility. Additionally, apparatus 1100 may be coupled to a transfer chamber that allows robotics to transfer semiconductor wafers into and out of apparatus 1100 using typical automation.

In some embodiments, a system controller 1130 (which may include one or more physical or logical controllers) controls some or all of the operations of a process chamber 1124. The system controller 1130 may include one or more memory devices and one or more processors. In some embodiments, the apparatus 1100 includes a switching system for controlling flow rates and durations when disclosed embodiments are performed. In some embodiments, the apparatus 1100 may have a switching time of up to about 500 ms, or up to about 750 ms. Switching time may depend on the flow chemistry, recipe chosen, reactor architecture, and other factors.

In some implementations, the system controller 1130 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be integrated into the system controller 1130, which may control various components or subparts of the system or systems. The system controller, depending on the processing parameters and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the system controller 1130 may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication or removal of one or more layers, materials, metals, oxides, silicon, silicon dioxide, surfaces, circuits, and/or dies of a wafer.

The system controller 1130, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the system controller 1130 receives instructions in the form of data, which specify parameters for each of the processing steps to be performed during one or more operations. It should be understood that the parameters may be specific to the type of process to be performed and the type of tool that the controller is configured to interface with or control. Thus, as described above, the system controller 1130 may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an ALD chamber or module, an ALE chamber or module, an ion implantation chamber or module, a track chamber or module, an EUV lithography chamber (scanner) or module, a dry development chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

EUVL patterning may be conducted using any suitable tool, often referred to as a scanner, for example the TWINSCAN NXE: 3300B® platform supplied by ASML of Veldhoven, NL). The EUVL patterning tool may be a standalone device from which the substrate is moved into and out of for deposition and etching as described herein. Or, as described below, the EUVL patterning tool may be a module on a larger multi-component tool. FIG. 12 depicts a semiconductor process cluster tool architecture with vacuum-integrated deposition, EUV patterning, and dry development/etch modules that interface with a vacuum transfer module, suitable for implementation of the processes described herein. While the processes may be conducted without such vacuum integrated apparatus, such apparatus may be advantageous in some implementations.

FIG. 12 depicts a semiconductor process cluster tool architecture with vacuum-integrated deposition and patterning modules that interface with a vacuum transfer module, suitable for implementation of processes described herein. The arrangement of transfer modules to “transfer” wafers among multiple storage facilities and processing modules may be referred to as a “cluster tool architecture” system. Deposition and patterning modules are vacuum-integrated, in accordance with the requirements of a particular process. Other modules, such as for etch, may also be included on the cluster.

A vacuum transport module (VTM) 1238 interfaces with four processing modules 1220a-1220d, which may be individually optimized to perform various fabrication processes. By way of example, processing modules 1220a-1220d may be implemented to perform deposition, evaporation, ELD, dry development, etch, strip, and/or other semiconductor processes. For example, module 1220a may be an ALD reactor that may be operated to perform in a non-plasma, thermal atomic layer depositions as described herein, such as Vector tool, available from Lam Research Corporation, Fremont, Calif. And module 1220b may be a PECVD tool, such as the Lam Vector®. It should be understood that the figure is not necessarily drawn to scale.

Airlocks 1242 and 1246, also known as a loadlocks or transfer modules, interface with the VTM 1238 and a patterning module 1240. For example, as noted above, a suitable patterning module may be the TWINSCAN NXE: 3300B® platform supplied by ASML of Veldhoven, NL). This tool architecture allows for work pieces, such as semiconductor substrates or wafers, to be transferred under vacuum so as not to react before exposure. Integration of the deposition modules with the lithography tool is facilitated by the fact that EUVL also requires a greatly reduced pressure given the strong optical absorption of the incident photons by ambient gases such as H₂O, O₂, etc.

As noted above, this integrated architecture is just one possible embodiment of a tool for implementation of the described processes. The processes may also be implemented with a more conventional stand-alone EUVL scanner and a deposition reactor, such as a Lam Vector tool, either stand alone or integrated in a cluster architecture with other tools, such as etch, strip etc. (e.g., Lam Kiyo or Gamma tools), as modules, for example as described with reference to FIG. 12 but without the integrated patterning module.

Airlock 1242 may be an “outgoing” loadlock, referring to the transfer of a substrate out from the VTM 1238 serving a deposition module 1220a to the patterning module 1240, and airlock 1246 may be an “ingoing” loadlock, referring to the transfer of a substrate from the patterning module 1240 back in to the VTM 1238. The ingoing loadlock 1246 may also provide an interface to the exterior of the tool for access and egress of substrates. Each process module has a facet that interfaces the module to VTM 1238. For example, deposition process module 1220a has facet 1236. Inside each facet, sensors, for example, sensors 1-18 as shown, are used to detect the passing of wafer 1226 when moved between respective stations. Patterning module 1240 and airlocks 1242 and 1246 may be similarly equipped with additional facets and sensors, not shown.

Main VTM robot 1222 transfers wafer 1226 between modules, including airlocks 1242 and 1246. In one embodiment, robot 1222 has one arm, and in another embodiment, robot 1222 has two arms, where each arm has an end effector 1224 to pick wafers such as wafer 1226 for transport. Front-end robot 1244, in is used to transfer wafers 1226 from outgoing airlock 1242 into the patterning module 1240, from the patterning module 1240 into ingoing airlock 1246. Front-end robot 1244 may also transport wafers 1226 between the ingoing loadlock and the exterior of the tool for access and egress of substrates. Because ingoing airlock module 1246 has the ability to match the environment between atmospheric and vacuum, the wafer 1226 is able to move between the two pressure environments without being damaged.

It should be noted that a EUVL tool typically operates at a higher vacuum than a deposition tool. If this is the case, it is desirable to increase the vacuum environment of the substrate during the transfer between the deposition to the EUVL tool to allow the substrate to degas prior to entry into the patterning tool. Outgoing airlock 1242 may provide this function by holding the transferred wafers at a lower pressure, no higher than the pressure in the patterning module 1240, for a period of time and exhausting any off-gassing, so that the optics of the patterning tool 1240 are not contaminated by off-gassing from the substrate. A suitable pressure for the outgoing, off-gassing airlock is no more than 1E-8 Torr.

In some embodiments, a system controller 1250 (which may include one or more physical or logical controllers) controls some or all of the operations of the cluster tool and/or its separate modules. It should be noted that the controller can be local to the cluster architecture, or can be located external to the cluster architecture in the manufacturing floor, or in a remote location and connected to the cluster architecture via a network. The system controller 1250 may include one or more memory devices and one or more processors. The processor may include a central processing unit (CPU) or computer, analog and/or digital input/output connections, stepper motor controller boards, and other like components. Instructions for implementing appropriate control operations are executed on the processor. These instructions may be stored on the memory devices associated with the controller or they may be provided over a network. In certain embodiments, the system controller executes system control software.

The system control software may include instructions for controlling the timing of application and/or magnitude of any aspect of tool or module operation. System control software may be configured in any suitable way. For example, various process tool component subroutines or control objects may be written to control operations of the process tool components necessary to carry out various process tool processes. System control software may be coded in any suitable compute readable programming language. In some embodiments, system control software includes input/output control (IOC) sequencing instructions for controlling the various parameters described above. For example, each phase of a semiconductor fabrication process may include one or more instructions for execution by the system controller. The instructions for setting process conditions for condensation, deposition, evaporation, patterning and/or etching phase may be included in a corresponding recipe phase, for example.

In various embodiments, an apparatus for forming a negative pattern mask is provided. The apparatus may include a processing chamber for patterning, deposition and etch, and a controller including instructions for forming a negative pattern mask. The instructions may include code for, in the processing chamber, patterning a feature in a chemically amplified (CAR) resist on a semiconductor substrate by EUV exposure to expose a surface of the substrate, dry developing the photopatterned resist, and etching the underlying layer or layer stack using the patterned resist as a mask.

It should be noted that the computer controlling the wafer movement can be local to the cluster architecture, or can be located external to the cluster architecture in the manufacturing floor, or in a remote location and connected to the cluster architecture via a network. A controller as described above with respect to any of FIG. 9, 10, 11, or 13 may be implemented with the tool in FIG. 12.

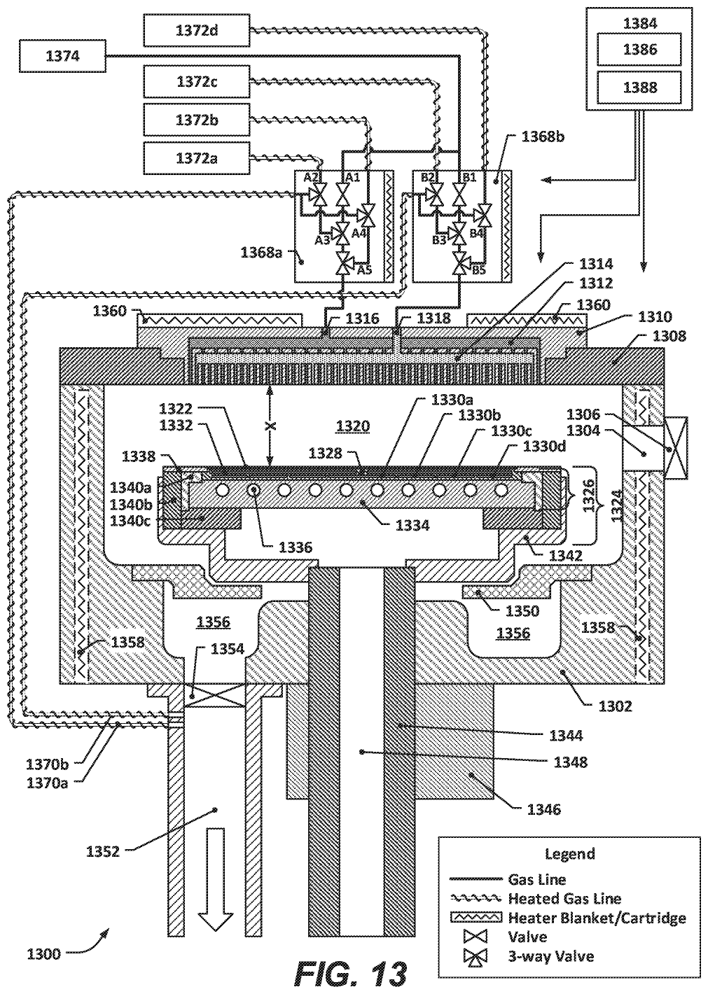

FIG. 13 shows an example of a deposition chamber (e.g., for vapor-based deposition, such as for an imaging layer and/or a radiation absorbing layer). As can be seen, an apparatus 1300 is depicted that has a processing chamber 1302 that includes a lid 1308. The processing chamber 1302 may include a wafer transfer passage 1304 through one of the walls of the processing chamber 1302 that is sized to allow a substrate 1322 to be passed therethrough and into the interior of the processing chamber 1302, where the substrate 1322 may be placed on a wafer support 1324. The wafer transfer passage 1304 may have a gate valve 1306 or similar door mechanism that may be operated to seal or unseal the wafer transfer passage, thereby allowing the environment within the processing chamber 1302 to be isolated from the environment on the other side of the gate valve 1306. For example, the processing chamber 1302 may be provided substrates 1322 via a wafer handling robot that is located in an adjoining transfer chamber. Such a transfer chamber may, for example, have multiple processing chambers 1302 arranged around its periphery, with each such processing chamber 1302 connected with the transfer chamber via a corresponding gate valve 1306.

The wafer support 1324 may, for example, include an electrostatic chuck (ESC) 1326, which may be used to provide a wafer support surface for supporting the substrate 1322. The ESC 1326 may include, for example, a base plate 1334 that is bonded to a top plate 1328 that is placed atop the base plate 1334. The top plate 1328 may, for example, be made of a ceramic material and may have embedded within it several other components. In the depicted example, the top plate 1328 has two separate electrical systems embedded within it. One such system is an electrostatic clamping electrode system, which may have one or more clamping electrodes 1332 that may be used to generate an electric charge within the substrate 1322 that causes the substrate 1322 to be drawn against the wafer support surface of the top plate 1328. In the implementation of FIG. 13, there are two clamping electrodes 1332 that provide a bi-polar electrostatic clamping system, although some implementations may use only a single clamping electrode 1332 to provide a mono-polar electrostatic clamping system.

The other system is a thermal control system that may be used to control the temperature of the substrate 1322 during processing conditions. In FIG. 13, the thermal control system is a multi-zone thermal control system featuring four annular resistance heater traces 1330a, 1330b, 1330c, and 1330d that are concentric with one another and positioned beneath the clamping electrodes 1332. The center resistance heater traces 1330a may, in some implementations, fill a generally circular area, and each resistance heater trace 1330a/b/c/d may follow a generally serpentine or otherwise meandering path within a corresponding annular region. Each resistance heater trace 1330a/b/c/d may be individually controlled to provide a variety of radial heating profiles in the top plate 1328; such a four-zone heating system may, for example, be controlled to maintain the substrate 1322 so as to have a temperature uniformity of ±0.5° C. in some cases. While the apparatus 1300 of FIG. 13 features a four-zone heating system in the ESC 1326, other implementations may use single-zone or multi-zone heating systems having more or fewer than four zones.

In some implementations, of, for example, temperature control mechanisms discussed above, heat pumps may be used instead of resistance heating traces. For example, in some implementations, the resistance heater traces may be replaced by, or augmented by, Peltier junctions or other, similar devices that may be controlled to “pump” heat from one side thereof to another. Such mechanisms may be used, for example, to draw heat from the top plate 1328 (and thus the substrate 1322) and direct it into the baseplate 1334 and the heat exchange passages 1336, thereby allowing the substrate 1322 to be cooled more rapidly and more effectively, if desired.

The ESC 1326 may also include, for example, a base plate 1334 that may be used to provide structural support to the underside of the top plate 1328 and which may also act as a heat dispersion system. For example, the base plate 1334 may include one or more heat exchange passages 1336 that are arranged in a generally distributed fashion throughout the base plate 1334, e.g., the heat exchange passages 1336 may follow a serpentine, circular switchback, or spiral pattern around the center of the base plate 1334. A heat exchange medium, e.g., water or inert fluorinated liquid, may be circulated through the heat exchange passages 1336 during use. The flow rate and temperature of the heat exchange medium may be externally controlled so as to result in a particular heating or cooling behavior in the base plate 1334.

The ESC 1326 may, for example, be supported by a wafer support housing 1342 that is connected with, and supported by, a wafer support column 1344. The wafer support column 1344 may, for example, have a routing passage 1348 other pass-throughs for routing cabling, fluid flow conduits, and other equipment to the underside of the base plate 1334 and/or the top plate 1328. For example, while not shown in FIG. 13, cabling for providing electrical power to the resistance heater traces 1330a/b/c/d may be routed through the routing passage 1348, as may cabling for providing electrical power to the clamping electrodes 1332. Other cables, e.g., cables for temperature sensors, may also be routed through the routing passage 1348 to locations in the interior of the wafer support 1324. In implementations with a temperature-controllable base plate 1334, conduits for conveying heat exchange medium to and from the base plate 1334 may also be routed through the routing passage 1348. To avoid undue clutter, such cables and conduits are not depicted in FIG. 13, but it is to be understood that they would, nonetheless, be present.

The apparatus 1300 of FIG. 13 also includes a wafer support z-actuator 1346 that may provide movable support to the wafer support column 1344. The wafer support z-actuator 1346 may be actuated to cause the wafer support column 1344, and the wafer support 1324 supported thereby, to move up or down vertically, e.g., by up to several inches, within a reaction space 1320 of the processing chamber 1302. In doing so, a gap distance X between the substrate 1322 and the underside of the showerhead 1310 may be tuned depending on various process conditions.

The wafer support 1324 may also include, in some implementations, one or more edge rings that may be used to control and/or fine-tune various process conditions. In FIG. 13, an upper edge ring 1338 is provided that lies on top of, for example, lower edge rings 1340a and 1340b, which, in turn, are supported by the wafer support housing 1342 and a third lower edge ring 1340c. The upper edge ring 1338 may, for example, be generally subjected to the same processing environment as the substrate 1322, whereas the lower edge rings 1340a/b/c may generally be shielded from the processing environment. Due to the increased exposure of the upper edge ring 1338, the upper edge ring 1338 may have a limited lifespan and may require more frequent replacement or cleaning as compared with the lower edge rings 1340a/b/c.

The apparatus 1300 may also include a system for removing process gases from the processing chamber 1302 during and after processing concludes. For example, the processing chamber 1302 may include an annular plenum 1356 that encircles the wafer support column 1344. The annular plenum 1356 may, in turn, be fluidically connected with a vacuum foreline 1352 that may be connected with a vacuum pump, e.g., such as may be located beneath a subfloor below the apparatus 1300. A regulator valve 1354 may be provided in between the vacuum foreline 1352 and the processing chamber 1302 and actuated to control the flow into the vacuum foreline 1352. In some implementations, a baffle 1350, e.g., an annular plate or other structure that may serve to make the flow into the annular plenum 1356 more evenly distributed about the circumference of the wafer support column 1344, may be provided to reduce the chances of flow non-uniformities developing in reactants flowed across the substrate 1322.

The showerhead 1310, as shown, is a dual-plenum showerhead 1310 and includes a first plenum 1312 that is provided process gas via a first inlet 1316 and a second plenum 1314 that is provided process gas via a second inlet 1318. Generally, two plenums can be employed to maintain separation between the precursor(s) and the counter-reactant(s) prior to release of the precursor and the counter-reactant. The showerhead 1310 may, in some implementations, have more than two plenums. In some instances, a single plenum is used to deliver the precursor(s) into the reaction space 1320 of the processing chamber 1302. Each plenum may have a corresponding set of gas distribution ports that fluidically connect the respective plenum with the reaction space 1320 through the faceplate of the showerhead 1310 (the faceplate being the portion of the showerhead 1310 that is interposed between the lowermost plenum and the reaction space 1320).

The first inlet 1316 and the second inlet 1318 of the showerhead 1310 may be provided processing gases via a gas supply system, which may be configured to provide one or more precursor(s) and/or counter-reactant(s), as discussed herein. The depicted apparatus 1300 is configured to provide multiple precursors and multiple counter-reactants. For example, a first valve manifold 1368a may be configured to provide precursor(s) to the first inlet 1316, while a second valve manifold 1368b may be configured to provide other precursor(s) or other counter-reactants to the second inlet 1318.

A first valve manifold 1368a may be configured to provide one or more precursor(s) to the first inlet 1316, while a second valve manifold 1368b may be configured to provide other precursor(s) or other reactant to the second inlet 1318. In this example, the first valve manifold 1368a, for example, includes multiple valves A1-A5. Valve A2 may, for example, be a three-way valve that has one port fluidically connected with a first vaporizer 1372a, another port fluidically connected with a bypass line 1370a, and a third port fluidically connected with a port on another 3-way valve A3. Similarly, valve A4 may be another three-way valve that has one port fluidically connected with a second vaporizer 1372b, another port fluidically connected with the bypass line 1370a, and a third port fluidically connected with a port on another 3-way valve A5. One of the other ports on valve A5 may be fluidically connected with the first inlet 1316 while the remaining port on valve A5 may be fluidically connected with one of the remaining ports on the valve A3. The remaining port on the valve A3 may, in turn, be fluidically connected with the valve A1 which may be fluidically interposed between the valve A3 and a purge gas source 1374, e.g., nitrogen, argon, or other suitably inert gas (with respect to precursor(s) and/or counter-reactant(s)). In some embodiments, only the first valve manifold is employed.

For the purposes of this disclosure, the term “fluidically connected” is used with respect to volumes, plenums, holes, etc., that may be connected with one another in order to form a fluidic connection, similar to how the term “electrically connected” is used with respect to components that are connected together to form an electric connection. The term “fluidically interposed,” if used, may be used to refer to a component, volume, plenum, or hole that is fluidically connected with at least two other components, volumes, plenums, or holes such that fluid flowing from one of those other components, volumes, plenums, or holes to the other or another of those components, volumes, plenums, or holes would first flow through the “fluidically interposed” component before reaching that other or another of those components, volumes, plenums, or holes. For example, if a pump is fluidically interposed between a reservoir and an outlet, fluid that flowed from the reservoir to the outlet would first flow through the pump before reaching the outlet.

The first valve manifold 1368a may, for example, be controllable to cause vapors from one or both of the vaporizers 1372a and 1372b to be flowed either to the processing chamber 1302 or through the first bypass line 1370a and into the vacuum foreline 1352. The first valve manifold 1368a may also be controllable to cause a purge gas to be flowed from the purge gas source 1374 and into the first inlet 1316.

For example, to flow vapor from the first vaporizer 1372a into the reaction space 1320, the valve A2 may be actuated to cause the vapor from the first vaporizer 1372a to first flow into the first bypass line 1370a. This flow may be maintained for a period of time sufficient to allow the flow of the vapor to reach steady state flow conditions. After sufficient time has passed (or after a flow meter, if used, indicates that the flow rate is stable), valves A2, A3, and A5 may be actuated to cause the vapor flow from the first vaporizer 1372a to be directed to the first inlet. Similar operations with valves A4 and A5 may be performed to deliver vapor from the second vaporizer 1372b to the first inlet 1316. In some instances, it may be desirable to purge one of the vapors from the first plenum 1312 by actuating the valves A1, A3, and A5 so as to cause the purge gas from the purge gas source 1374 to be flowed into the first inlet 1316. In some additional implementations, it may be desirable to simultaneously flow vapor from one of the vaporizers 1372a or 1372b in tandem with flowing gas from the purge gas into the first inlet 1316. Such implementations may be used to dilute the concentration of the reactant(s) contained in such vapor(s).

It will be appreciated that the second valve manifold 1368b may be controlled in a similar manner, e.g., by controlling valves B1-B5, to provide vapors from vaporizers 1372c and 1372d to the second inlet 1318 or to the second bypass line 1370b. It will be further appreciated that different manifold arrangements may be utilized as well, including a single unitary manifold that includes valves for controlling flow of the precursor(s), counter-reactant(s), or other reactants to the first inlet 1316 and the second inlet 1318.

As mentioned earlier, some apparatuses 1300 may feature a lesser number of vapor sources, e.g., only two vaporizers 1372, in which case the valve manifold(s) 1368 may be modified to have a lesser number of valves, e.g., only valves A1-A3.

As discussed above, apparatuses such as apparatus 1300, which may be used to provide for dry deposition of films, may be configured to maintain particular temperature profiles within the processing chamber 1302. In particular, such apparatuses 1300 may be configured to maintain the substrate 1322 at a lower temperature, e.g., at least 25° C. to 50° C. lower, than most of the equipment of the apparatus 1302 that comes into direct contact with the precursor(s) and/or counter-reactant(s). Additionally, the temperature of the equipment of the apparatus 1300 that comes into direct contact with the precursor(s) and/or counter-reactant(s) may be kept to an elevated level that is sufficiently high that condensation of the vaporized reactants on the surfaces of such equipment is discouraged. At the same time, the substrate 1322 temperature may be controlled to a level that promotes condensation, or at least deposition, of the reactants on the substrate 1322.

To provide for such temperature control, various heating systems may be included in the apparatus 1300. For example, the processing chamber 1302 may have receptacles for receiving cartridge heaters 1358, e.g., for a processing chamber 1302 that has a generally cylindrical interior volume but a square or rectangular external shape, vertical holes for receiving cartridge heaters 1358 may be bored into the four corners of the chamber 1302 housing. In some implementations, the showerhead 1310 may be covered with heater blankets 1360, which may be used to apply heat across the exposed upper surface of the showerhead 1310 to keep the showerhead temperature elevated. It may also be beneficial to heat various gas lines that are used to conduct the vaporized reactants from the vaporizers 1372 to the showerhead 1310. For example, resistive heater tape may be wound around such gas lines and used to heat them to an elevated temperature. As shown in FIG. 13, all of the gas lines that potentially have precursor(s) and/or counter-reactant(s) flowing through them are shown as being heated, including the bypass lines 1370. The only exceptions are the gas lines from the valve manifolds 1368 to the first inlet 1316 and the second inlet 1318, which may be quite short and may be indirectly heated by the showerhead 1310. Of course, even these gas lines may be actively heated, if desired. In some implementations, heaters may be provided proximate to the gate valve 1306 to provide heat to the gate valve as well.

The various operational systems of the apparatus 1300 may be controlled by a controller 1384, which may include one or more processors 1386 and one or more memory devices 1388 that are operatively connected with each other and that are communicatively connected with various systems and subsystems of the apparatus 1300 so as to provide for control functionality for those systems. For example, the controller 1384 may be configured to control the valves A1-A5 and B1-B5, the various heaters 1358, 1360, the vaporizers 1372, the regulator valve 1354, the gate valve 1306, the wafer support z-actuator, and so forth.

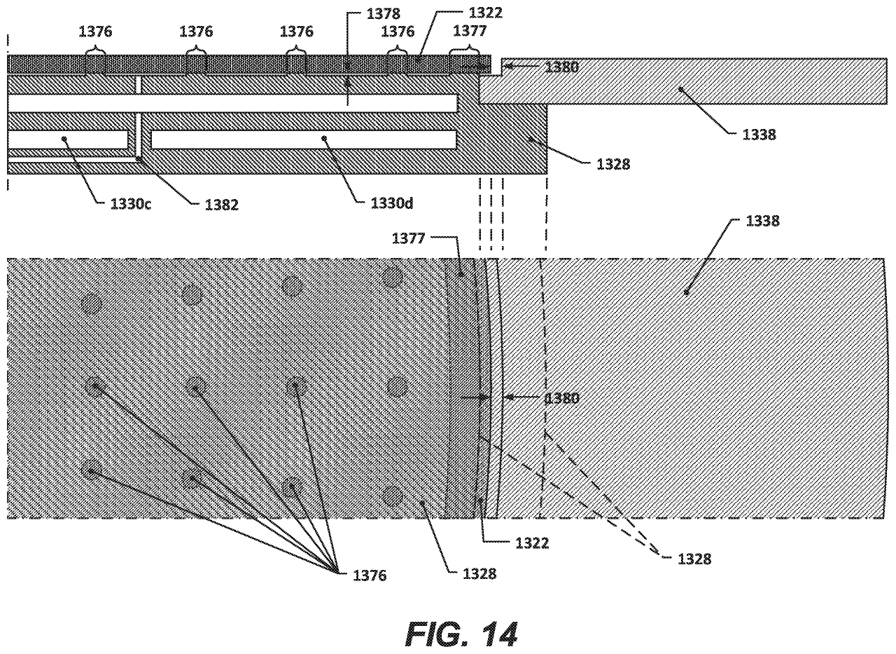

Another feature that the apparatus 1300 may include is shown in FIG. 14, which depicts close-up side cross-sectional and plan views of a portion of the substrate 1322, top plate 1328, and upper edge ring 1338 of FIG. 13. As can be seen, in some implementations, the substrate 1322 may be elevated off of most of the top plate 1328 by a plurality of small mesas 1376, which may be shallow bosses that protrude from the nominal upper surface of the top plate 1328 by a small distance so as to provide for a backside gap 1378 between the underside of the substrate 1322 and the majority of the top plate 1328. A circumferential wall feature 1377 may be provided at the periphery of the top plate 1328. The circumferential wall feature 1377 may extend around the entire perimeter of the top plate 1328 and be of nominally the same height as the mesas 1376. During processing operations, a generally inert gas, such as helium, may be flowed into the backside gap 1378 via one or more gas ports 1382. This gas may then flow radially outward before encountering the circumferential wall feature 1377, which way then restrict such radially outward flow and cause a higher-pressure region of the gas to be trapped between the substrate 1322 and the top plate 1328. The inert gas that leaks past the circumferential wall 1377 may eventually flow out through a radial gap 1380 between the outer edge of the substrate 1322 and a portion of the upper edge ring 1338. Such gas may serve to protect the underside of the substrate from undesirably being affected by the processing operations being performed by acting to prevent the gases released by the showerhead 1310 from reaching the underside of the substrate 1322. At the same time, the gas released into the backside gap 1378 region may also act to increase thermal coupling between the substrate 1322 and the top plate 1328, thereby allowing the top plate 1328 to more effectively heat or cool the substrate 1322. Due to the higher pressure provided by the circumferential wall, the gas that is within the backside gap 1378 region may also be at a higher density than gas in the remainder of the chamber, and may thus provide more effective thermal coupling between the substrate 1322 and the top plate 1328.

The controller 1384 may be configured, e.g., via execution of computer-executable instructions, to cause the apparatus 1200 to perform various operations consistent with the disclosure provided above.

Once the imaging layer and/or radiation-absorbing layer has been deposited on the substrate 1322, the substrate 1322 may, as noted above, be transferred to one or more subsequent processing chambers or tool for additional operations (e.g., any described herein). Further deposition apparatuses are described in International Patent Application No. PCT/US2020/038968, filed Jun. 22, 2020, titled “APPARATUS FOR PHOTORESIST DRY DEPOSITION,” which is herein incorporated by reference in its entirety.

### Definitions

By “acyloxy” or “alkanoyloxy,” as used interchangeably herein, is meant an acyl or alkanoyl group, as defined herein, attached to the parent molecular group through an oxy group. In particular embodiments, the alkanoyloxy is —O—C(O)-Ak, in which Ak is an alkyl group, as defined herein. In some embodiments, an unsubstituted alkanoyloxy is a C₂₋₇ alkanoyloxy group. Exemplary alkanoyloxy groups include acetoxy.

By “alkenyl” is meant an optionally substituted C₂₋₂₄ alkyl group having one or more double bonds. The alkenyl group can be cyclic (e.g., C₃₋₂₄ cycloalkenyl) or acyclic. The alkenyl group can also be substituted or unsubstituted. For example, the alkenyl group can be substituted with one or more substitution groups, as described herein for alkyl.

By “alkenylene” is meant a multivalent (e.g., bivalent) form of an alkenyl group, which is an optionally substituted C₂₋₂₄ alkyl group having one or more double bonds. The alkenylene group can be cyclic (e.g., C₃₋₂₄ cycloalkenyl) or acyclic. The alkenylene group can be substituted or unsubstituted. For example, the alkenylene group can be substituted with one or more substitution groups, as described herein for alkyl. Exemplary, non-limiting alkenylene groups include —CH═CH— or —CH═CHCH₂—.

By “alkoxy” is meant —OR, where R is an optionally substituted alkyl group, as described herein. Exemplary alkoxy groups include methoxy, ethoxy, butoxy, trihaloalkoxy, such as trifluoromethoxy, etc. The alkoxy group can be substituted or unsubstituted. For example, the alkoxy group can be substituted with one or more substitution groups, as described herein for alkyl. Exemplary unsubstituted alkoxy groups include C₁₋₃, C₁₋₆, C₁₋₁₂, C₁₋₁₆, C₁₋₁₈, C₁₋₂₀, or C₁₋₂₄ alkoxy groups.

By “alkyl” and the prefix “alk” is meant a branched or unbranched saturated hydrocarbon group of 1 to 24 carbon atoms, such as methyl (Me), ethyl (Et), in-propyl (n-Pr), isopropyl (i-Pr), cyclopropyl, n-butyl (n-Bu), isobutyl (i-Bu), s-butyl (s-Bu), t-butyl (t-Bu), cyclobutyl, n-pentyl, isopentyl, s-pentyl, neopentyl, hexyl, heptyl, octyl, nonyl, decyl, dodecyl, tetradecyl, hexadecyl, eicosyl, tetracosyl, and the like. The alkyl group can be cyclic (e.g., C₃₋₂₄ cycloalkyl) or acyclic. The alkyl group can be branched or unbranched. The alkyl group can also be substituted or unsubstituted. For example, the alkyl group can include haloalkyl, in which the alkyl group is substituted by one or more halo groups, as described herein. In another example, the alkyl group can be substituted with one, two, three or, in the case of alkyl groups of two carbons or more, four substituents independently selected from the group consisting of: (1) C₁₋₆ alkoxy (e.g., —O-Ak, wherein Ak is optionally substituted C₁₋₆ alkyl); (2) amino (e.g., —NR^{N1}R^{N2}, where each of R^{N1} and R^{N2} is, independently, H or optionally substituted alkyl, or R^{N1} and R^{N2}, taken together with the nitrogen atom to which each are attached, form a heterocyclyl group); (3) aryl; (4) arylalkoxy (e.g., —O-Lk-Ar, wherein Lk is a bivalent form of optionally substituted alkyl and Ar is optionally substituted aryl); (5) aryloyl (e.g., —C(O)—Ar, wherein Ar is optionally substituted aryl); (6) cyano (e.g., —CN); (7) carboxyaldehyde (e.g., —C(O)H); (8) carboxyl (e.g., —CO₂H); (9) C₃₋₈ cycloalkyl (e.g., a monovalent saturated or unsaturated non-aromatic cyclic C₃₋₈ hydrocarbon group); (10) halo (e.g., F, Cl, Br, or I); (11) heterocyclyl (e.g., a 5-, 6- or 7-membered ring, unless otherwise specified, containing one, two, three, or four non-carbon heteroatoms, such as nitrogen, oxygen, phosphorous, sulfur, or halo); (12) heterocyclyloxy (e.g., —O-Het, wherein Het is heterocyclyl, as described herein); (13) heterocyclyloyl (e.g., —C(O)—Het, wherein Het is heterocyclyl, as described herein); (14) hydroxyl (e.g., —OH); (15) N-protected amino; (16) nitro (e.g., —NO₂); (17) oxo (e.g., ═O); (18) —CO₂R^{A}, where R^{A} is selected from the group consisting of (a) C₁₋₆ alkyl, (b) C₄₋₁₈ aryl, and (c) (C₄₋₁₈ aryl) C₁₋₆ alkyl (e.g., -Lk-Ar, wherein Lk is a bivalent form of optionally substituted alkyl group and Ar is optionally substituted aryl); (19) —C(O)NR^{B}R^{C}, where each of R^{B} and R^{C} is, independently, selected from the group consisting of (a) hydrogen, (b) C₁₋₆ alkyl, (c) C₄₋₁₈ aryl, and (d) (C₄₋₁₈ aryl) C₁₋₆ alkyl (e.g., -Lk-Ar, wherein Lk is a bivalent form of optionally substituted alkyl group and Ar is optionally substituted aryl); and (20) —NR^{G}R^{H}, where each of R^{G} and R^{H} is, independently, selected from the group consisting of (a) hydrogen, (b) an N-protecting group, (c) C₁₋₆ alkyl, (d) C₂₋₆ alkenyl (e.g., optionally substituted alkyl having one or more double bonds), (e) C₂₋₆ alkynyl (e.g., optionally substituted alkyl having one or more triple bonds), (f) C₄₋₁₈ aryl, (g) (C₄₋₁₈ aryl) C₁₋₆ alkyl (e.g., Lk-Ar, wherein Lk is a bivalent form of optionally substituted alkyl group and Ar is optionally substituted aryl), (h) C₃₋₄ cycloalkyl, and (i) (C₃₋₈ cycloalkyl) C₁₋₆ alkyl (e.g., -Lk-Cy, wherein Lk is a bivalent form of optionally substituted alkyl group and Cy is optionally substituted cycloalkyl, as described herein), wherein in one embodiment no two groups are bound to the nitrogen atom through a carbonyl group. The alkyl group can be a primary, secondary, or tertiary alkyl group substituted with one or more substituents (e.g., one or more halo or alkoxy). In some embodiments, the unsubstituted alkyl group is a C₁₋₃, C₁₋₆, C₁₋₁₂, C₁₋₁₆, C₁₋₁₈, C₁₋₂₀, or C₁₋₂₄ alkyl group.

By “alkylene” is meant a multivalent (e.g., bivalent) form of an alkyl group, as described herein. Exemplary alkylene groups include methylene, ethylene, propylene, butylene, etc. In some embodiments, the alkylene group is a C₁₋₃, C₁₋₆, C₁₋₁₂, C₁₋₁₆, C₁₋₁₈, C₁₋₂₀, C₁₋₂₄, C₂₋₃, C₂₋₆, C₂₋₁₂, C₂₋₁₆, C₂₋₁₈, C₂₋₂₀, or C₂₋₂₄ alkylene group. The alkylene group can be branched or unbranched. The alkylene group can also be substituted or unsubstituted. For example, the alkylene group can be substituted with one or more substitution groups, as described herein for alkyl.

By “alkynyl” is meant an optionally substituted C₂₋₂₄ alkyl group having one or more triple bonds. The alkynyl group can be cyclic or acyclic and is exemplified by ethynyl, 1-propynyl, and the like. The alkynyl group can also be substituted or unsubstituted. For example, the alkynyl group can be substituted with one or more substitution groups, as described herein for alkyl.

By “alkynylene” is meant a multivalent (e.g., bivalent) form of an alkynyl group, which is an optionally substituted C₂₋₂₄ alkyl group having one or more triple bonds. The alkynylene group can be cyclic or acyclic. The alkynylene group can be substituted or unsubstituted. For example, the alkynylene group can be substituted with one or more substitution groups, as described herein for alkyl. Exemplary, non-limiting alkynylene groups include —C≡C— or —C≡CCH₂—.

By “amino” is meant —NR^{N1}R^{N2}, where each of R^{N1} and R^{N2} is, independently, H, optionally substituted alkyl, or optionally substituted aryl, or R^{N1} and R^{N2}, taken together with the nitrogen atom to which each are attached, form a heterocyclyl group, as defined herein.

By “aryl” is meant a group that contains any carbon-based aromatic group including, but not limited to, phenyl, benzyl, anthracenyl, anthryl, benzocyclobutenyl, benzocyclooctenyl, biphenylyl, chrysenyl, dihydroindenyl, fluoranthenyl, indacenyl, indenyl, naphthyl, phenanthryl, phenoxybenzyl, picenyl, pyrenyl, terphenyl, and the like, including fused benzo-C₄₋₈ cycloalkyl radicals (e.g., as defined herein) such as, for instance, indanyl, tetrahydronaphthyl, fluorenyl, and the like. The term aryl also includes heteroaryl, which is defined as a group that contains an aromatic group that has at least one heteroatom incorporated within the ring of the aromatic group. Examples of heteroatoms include, but are not limited to, nitrogen, oxygen, sulfur, and phosphorus. Likewise, the term non-heteroaryl, which is also included in the term aryl, defines a group that contains an aromatic group that does not contain a heteroatom. The aryl group can be substituted or unsubstituted. The aryl group can be substituted with one, two, three, four, or five substituents, such as any described herein for alkyl.

By “arylene” is meant a multivalent (e.g., bivalent) form of an aryl group, as described herein. Exemplary arylene groups include phenylene, naphthylene, biphenylene, triphenylene, diphenyl ether, acenaphthenylene, anthrylene, or phenanthrylene. In some embodiments, the arylene group is a C₄₋₁₈, C₄₋₁₄, C₄₋₁₂, C₄₋₁₀, C₆₋₁₈, C₆₋₁₄, C₆₋₁₂, or C₆₋₁₀ arylene group. The arylene group can be branched or unbranched. The arylene group can also be substituted or unsubstituted. For example, the arylene group can be substituted with one or more substitution groups, as described herein for alkyl or aryl.

By “(aryl)(alkyl)ene” is meant a bivalent form including an arylene group, as described herein, attached to an alkylene or a heteroalkylene group, as described herein. In some embodiments, the (arylxalkyl)ene group is -L-Ar— or -L-Ar-L- or —Ar-L-, in which Ar is an arylene group and each L is, independently, an optionally substituted alkylene group or an optionally substituted heteroalkylene group.

By “carbonyl” is meant a —C(O)— group, which can also be represented as >C═O, or a —CO group.

By “carboxyl” is meant a —CO₂H group.

By “carboxyalkyl” is meant an alkyl group, as defined herein, substituted by one or more carboxyl groups, as defined herein.

By “carboxyaryl” is meant an aryl group, as defined herein, substituted by one or more carboxyl groups, as defined herein.

By “cyclic anhydride” is meant a 3-, 4-, 5-, 6- or 7-membered ring (e.g., a 5-, 6- or 7-membered ring), unless otherwise specified, having a —C(O)—O—C(O)— group within the ring. The term “cyclic anhydride” also includes bicyclic, tricyclic and tetracyclic groups in which any of the above rings is fused to one, two, or three rings independently selected from the group consisting of an aryl ring, a cyclohexane ring, a cyclohexene ring, a cyclopentane ring, a cyclopentene ring, and another monocyclic heterocyclic ring. Exemplary cyclic anhydride groups include a radical formed from succinic anhydride, glutaric anhydride, maleic anhydride, phthalic anhydride, isochroman-1,3-dione, oxepanedione, tetrahydrophthalic anhydride, hexahydrophthalic anhydride, pyromellitic dianhydride, naphthalic anhydride, 1,2-cyclohexanedicarboxylic anhydride, etc., by removing one or more hydrogen. Other exemplary cyclic anhydride groups include dioxotetrahydrofuranyl, dioxodihydroisobenzofuranyl, etc. The cyclic anhydride group can also be substituted or unsubstituted. For example, the cyclic anhydride group can be substituted with one or more groups including those described herein for heterocyclyl.

By “cycloalkenyl” is meant a monovalent unsaturated non-aromatic or aromatic cyclic hydrocarbon group of from three to eight carbons, unless otherwise specified, having one or more double bonds. The cycloalkenyl group can also be substituted or unsubstituted. For example, the cycloalkenyl group can be substituted with one or more groups including those described herein for alkyl.

By “cycloalkyl” is meant a monovalent saturated or unsaturated non-aromatic or aromatic cyclic hydrocarbon group of from three to eight carbons, unless otherwise specified, and is exemplified by cyclopropyl, cyclobutyl, cyclopentyl, cyclopentadienyl, cyclohexyl, cycloheptyl, bicyclo[2.2.1.]heptyl, and the like. The cycloalkyl group can also be substituted or unsubstituted. For example, the cycloalkyl group can be substituted with one or more groups including those described herein for alkyl.

By “halo” is meant F, Cl, Br, or I.

By “haloalkyl” is meant an alkyl group, as defined herein, substituted with one or more halo.

By “heteroalkyl” is meant an alkyl group, as defined herein, containing one, two, three, or four non-carbon heteroatoms (e.g., independently selected from the group consisting of nitrogen, oxygen, phosphorous, sulfur, selenium, or halo).

By “heteroalkylene” is meant a bivalent form of an alkylene group, as defined herein, containing one, two, three, or four non-carbon heteroatoms (e.g., independently selected from the group consisting of nitrogen, oxygen, phosphorous, sulfur, selenium, or halo). The heteroalkylene group can be substituted or unsubstituted. For example, the heteroalkylene group can be substituted with one or more substitution groups, as described herein for alkyl.

By “heterocyclyl” is meant a 3-, 4-, 5-, 6- or 7-membered ring (e.g., a 5-, 6- or 7-membered ring), unless otherwise specified, containing one, two, three, or four non-carbon heteroatoms (e.g., independently selected from the group consisting of nitrogen, oxygen, phosphorous, sulfur, selenium, or halo). The 3-membered ring has zero to one double bonds, the 4- and 5-membered ring has zero to two double bonds, and the 6- and 7-membered rings have zero to three double bonds. The term “heterocyclyl” also includes bicyclic, tricyclic and tetracyclic groups in which any of the above heterocyclic rings is fused to one, two, or three rings independently selected from the group consisting of an aryl ring, a cyclohexane ring, a cyclohexene ring, a cyclopentane ring, a cyclopentene ring, and another monocyclic heterocyclic ring, such as indolyl, quinolyl, isoquinolyl, tetrahydroquinolyl, benzofuryl, benzothienyl and the like. Heterocyclics include acridinyl, adenyl, alloxazinyl, azaadamantanyl, azabenzimidazolyl, azabicyclononyl, azacycloheptyl, azacyclooctyl, azacyclononyl, azahypoxanthinyl, azaindazolyl, azaindolyl, azecinyl, azepanyl, azepinyl, azetidinyl, azetyl, aziridinyl, azirinyl, azocanyl, azocinyl, azonanyl, benzimidazolyl, benzisothiazolyl, benzisoxazolyl, benzodiazepinyl, benzodiazocinyl, benzodihydrofuryl, benzodioxepinyl, benzodioxinyl, benzodioxanyl, benzodioxocinyl, benzodioxolyl, benzodithiepinyl, benzodithiinyl, benzodioxocinyl, benzofuranyl, benzophenazinyl, benzopyranonyl, benzopyranyl, benzopyrenyl, benzopyronyl, benzoquinolinyl, benzoquinolizinyl, benzothiadiazepinyl, benzothiadiazolyl, benzothiazepinyl, benzothiazocinyl, benzothiazolyl, benzothienyl, benzothiophenyl, benzothiazinonyl, benzothiazinyl, benzothiopyranyl, benzothiopyronyl, benzotriazepinyl, benzotriazinonyl, benzotriazinyl, benzotriazolyl, benzoxathiinyl, benzotrioxepinyl, benzoxadiazepinyl, benzoxathiazepinyl, benzoxathiepinyl, benzoxathiocinyl, benzoxazepinyl, benzoxazinyl, benzoxazocinyl, benzoxazolinonyl, benzoxazolinyl, benzoxazolyl, benzylsultamyl benzylsultimyl, bipyrazinyl, bipyridinyl, carbazolyl (e.g., 4H-carbazolyl), carbolinyl (e.g., β-carbolinyl), chromanonyl, chromanyl, chromenyl, cinnolinyl, coumarinyl, cytdinyl, cytosinyl, decahydroisoquinolinyl, decahydroquinolinyl, diazabicyclooctyl, diazetyl, diaziridinethionyl, diaziridinonyl, diaziridinyl, diazirinyl, dibenzisoquinolinyl, dibenzoacridinyl, dibenzocarbazolyl, dibenzofuranyl, dibenzophenazinyl, dibenzopyranonyl, dibenzopyronyl (xanthonyl), dibenzoquinoxalinyl, dibenzothiazepinyl, dibenzothiepinyl, dibenzothiophenyl, dibenzoxepinyl, dihydroazepinyl, dihydroazetyl, dihydrofuranyl, dihydrofuryl, dihydroisoquinolinyl, dihydropyranyl, dihydropyridinyl, dihydroypyridyl, dihydroquinolinyl, dihydrothienyl, dihydroindolyl, dioxanyl, dioxazinyl, dioxindolyl, dioxiranyl, dioxenyl, dioxinyl, dioxobenzofuranyl, dioxolyl, dioxotetrahydrofuranyl, dioxothiomorpholinyl, dithianyl, dithiazolyl, dithienyl, dithiinyl, furanyl, furazanyl, furoyl, furyl, guaninyl, homopiperazinyl, homopiperidinyl, hypoxanthinyl, hydantoinyl, imidazolidinyl, imidazolinyl, imidazolyl, indazolyl (e.g., 1H-indazolyl), indolenyl, indolinyl, indolizinyl, indolyl (e.g., 1H-indolyl or 3H-indolyl), isatinyl, isatyl, isobenzofuranyl, isochromanyl, isochromenyl, isoindazoyl, isoindolinyl, isoindolyl, isopyrazolonyl, isopyrazolyl, isoxazolidiniyl, isoxazolyl, isoquinolinyl, isoquinolinyl, isothiazolidinyl, isothiazolyl, morpholinyl, naphthindazolyl, naphthindolyl, naphthiridinyl, naphthopyranyl, naphthothiazolyl, naphthothioxolyl, naphthotriazolyl, naphthoxindolyl, naphthyridinyl, octahydroisoquinolinyl, oxabicycloheptyl, oxauracil, oxadiazolyl, oxazinyl, oxaziridinyl, oxazolidinyl, oxazolidonyl, oxazolinyl, oxazolonyl, oxazolyl, oxepanyl, oxetanonyl, oxetanyl, oxetyl, oxtenayl, oxindolyl, oxiranyl, oxobenzoisothiazolyl, oxochromenyl, oxoisoquinolinyl, oxoquinolinyl, oxothiolanyl, phenanthridinyl, phenanthrolinyl, phenazinyl, phenothiazinyl, phenothienyl (benzothiofuranyl), phenoxathiinyl, phenoxazinyl, phthalazinyl, phthalazonyl, phthalidyl, phthalimidinyl, piperazinyl, piperidinyl, piperidonyl (e.g., 4-piperidonyl), pteridinyl, purinyl, pyranyl, pyrazinyl, pyrazolidinyl, pyrazolinyl, pyrazolopyrimidinyl, pyrazolyl, pyridazinyl, pyridinyl, pyridopyrazinyl, pyridopyrimidinyl, pyridyl, pyrimidinyl, pyrimidyl, pyronyl, pyrrolidinyl, pyrrolidonyl (e.g., 2-pyrrolidonyl), pyrrolinyl, pyrrolizidinyl, pyrrolyl (e.g., 2H-pyrrolyl), pyrylium, quinazolinyl, quinolinyl, quinolizinyl (e.g., 4H-quinolizinyl), quinoxalinyl, quinuclidinyl, selenazinyl, selenazolyl, selenophenyl, succinimidyl, sulfolanyl, tetrahydrofuranyl, tetrahydrofuryl, tetrahydroisoquinolinyl, tetrahydroisoquinolyl, tetrahydropyridinyl, tetrahydropyridyl (piperidyl), tetrahydropyranyl, tetrahydropyronyl, tetrahydroquinolinyl, tetrahydroquinolyl, tetrahydrothienyl, tetrahydrothiophenyl, tetrazinyl, tetrazolyl, thiadiazinyl (e.g., 6H-1,2,5-thiadiazinyl or 2H,6H-1,5,2-dithiazinyl), thiadiazolyl, thianthrenyl, thianyl, thianaphthenyl, thiazepinyl, thiazinyl, thiazolidinedionyl, thiazolidinyl, thiazolyl, thienyl, thiepanyl, thiepinyl, thietanyl, thietyl, thiiranyl, thiocanyl, thiochromanonyl, thiochromanyl, thiochromenyl, thiodiazinyl, thiodiazolyl, thioindoxyl, thiomorpholinyl, thiophenyl, thiopyranyl, thiopyronyl, thiotriazolyl, thiourazolyl, thioxanyl, thioxolyl, thymidinyl, thyminyl, triazinyl, triazolyl, trithianyl, urazinyl, urazolyl, uretidinyl, uretinyl, uricyl, uridinyl, xanthenyl, xanthinyl, xanthionyl, and the like, as well as modified forms thereof (e.g., including one or more oxo and/or amino) and salts thereof. The heterocyclyl group can be substituted or unsubstituted. For example, the heterocyclyl group can be substituted with one or more substitution groups, as described herein for alkyl.

By “hydrocarbyl” is meant a univalent group formed by removing a hydrogen atom from a hydrocarbon. Non-limiting unsubstituted hydrocarbyl groups include alkyl, alkenyl, alkynyl, and aryl, as defined herein, in which these groups include only carbon and hydrogen atoms. The hydrocarbyl group can be substituted or unsubstituted. For example, the hydrocarbyl group can be substituted with one or more substitution groups, as described herein for alkyl. In other embodiments, any alkyl or aryl group herein can be replaced with a hydrocarbyl group, as defined herein.

By “hydroxyl” is meant —OH.

By “hydroxyalkyl” is meant an alkyl group, as defined herein, substituted by one to three hydroxyl groups, with the proviso that no more than one hydroxyl group may be attached to a single carbon atom of the alkyl group and is exemplified by hydroxymethyl, dihydroxypropyl, and the like.

By “hydroxyaryl” is meant an aryl group, as defined herein, substituted by one to three hydroxyl groups, with the proviso that no more than one hydroxyl group may be attached to a single carbon atom of the aryl group and is exemplified by hydroxyphenyl, dihydroxyphenyl, and the like.

By “isocyanato” is meant —NCO.

By “oxido” is meant an —O⁻ group.

By “oxo” is meant an ═O group.

By “phosphine” is meant a trivalent or tetravalent phosphorous having hydrocarbyl moieties. In some embodiments, phosphine is a —PR^{P}₃ group, where each R^{P} is, independently, H, optionally substituted alkyl, or optionally substituted aryl. The phosphine group can be substituted or unsubstituted. For example, the phosphine group can be substituted with one or more substitution groups, as described herein for alkyl.

By “selenol” is meant an —SeH group.

By “tellurol” is meant an —TeH group.

By “thioisocyanato” is meant —NCS.

By “thiol” is meant an —SH group.

As used herein, the terms “top,” “bottom,” “upper,” “lower,” “above,” and “below” are used to provide a relative relationship between structures. The use of these terms does not indicate or require that a particular structure must be located at a particular location in the apparatus.

### CONCLUSION

Process and apparatus for tuning substrate chemistry through the incorporation of highly absorbing EUV materials and/or control of surface adhesion for metal oxide photoresists, for example to form a patterning mask in the context of EUV patterning, is disclosed.

It is understood that the examples and embodiments described herein are for illustrative purposes only and that various modifications or changes in light thereof will be suggested to persons skilled in the art. Although various details have been omitted for clarity's sake, various design alternatives may be implemented. Therefore, the present examples are to be considered as illustrative and not restrictive, and the disclosure is not to be limited to the details given herein, but may be modified within the scope of the disclosure.

The following sample claims are provided for further illustration of certain embodiments of the disclosure. The disclosure is not necessarily limited to these embodiments.

1. A method of making a patterning structure, the method comprising:
providing a substrate to receive a pattern;
incorporating a radiation-absorbing layer on a surface of the substrate;
providing an imaging layer, wherein the radiation-absorbing layer underlies the imaging layer to increase radiation absorptivity and/or patterning performance of the imaging layer.

2. The method of claim 1, wherein the imaging layer comprises a radiation-sensitive imaging layer, an Extreme Ultraviolet (EUV)-sensitive film, a photoresist layer, a hardmask, or an atomic layer deposition (ALD) hardmask.

3. The method of claim 1, wherein the radiation-absorbing layer comprises iodine (I), indium (In), tin (Sn), bismuth (Bi), antimony (Sb), tellurium (Te), an oxide thereof, an alloy thereof, or a combination thereof.

4. The method of claim 1, wherein the radiation-absorbing layer comprises a first element having a high patterning radiation-absorption cross-section.

5. The method of claim 4, wherein the imaging layer comprises a second element having a high patterning radiation-absorption cross-section and a moiety that is cleavable under exposure to a patterning radiation.

6. The method of claim 1, further comprising, prior to said providing the imaging layer:
incorporating halo, alkyl, or haloalkyl moieties to a surface of the radiation-absorbing layer.

7. The method of claim 1, wherein said incorporating comprises:
depositing the radiation-absorbing layer by sputtering, physical vapor deposition (PVD), chemical vapor deposition (CVD), atomic layer deposition (ALD), plasma-based deposition, thermal-induced decomposition, or plasma-induced decomposition of one or more precursors.

8. The method of claim 7, wherein said incorporating comprises:
providing a first precursor comprising tellurium (Te) and a second precursor comprising a metal oxide to the surface of the substrate, wherein the first and second precursors are each provided to the substrate in vapor phase, thereby depositing the radiation-absorbing layer on the substrate.

9. The method of claim 8, wherein the first precursor comprises TeR₂ or TeR₄, wherein each R is, independently, halo, optionally substituted C₁₋₁₂ alkyl, optionally substituted C₁₋₁₂ alkoxy, optionally substituted aryl, hydroxyl, oxo, or optionally substituted trialkylsilyl; and wherein the second precursor comprises tin oxide, antimony oxide, or bismuth oxide.

10. The method of claim 7, wherein said incorporating comprises:
exposing the surface of the substrate to a vapor comprising an element having a high EUV-absorption cross-section and in the presence of plasma or heat, thereby depositing the radiation-absorbing layer on the substrate.

11. The method of claim 10, wherein the vapor comprises iodine (I), iodine gas (I₂), diiodomethane (CH₂I₂), tin (Sn), tellurium (Te), or bis(alkyl)tellurium (TeR₂).

12. The method of claim 1, wherein a surface of the radiation-absorbing layer further comprises a photoresponsive surface having a labile moiety that is cleavable under exposure to the patterning radiation.

13. The method of claim 12, wherein said incorporating comprises:
depositing the radiation-absorbing layer on the surface of the substrate; and
capping the radiation-absorbing layer with a capping agent comprising the labile moiety.

14. The method of claim 13, wherein the radiation-absorbing layer comprises tin oxide, tin, tin alloy, bismuth oxide, or tellurium; and wherein the capping agent comprises an alkyl substituted metal-containing precursor.

15. The method of claim 12, further comprising, after said providing the imaging layer:
exposing the radiation-absorbing layer and the imaging layer to a patterned radiation exposure, thereby providing an exposed film having a radiation exposed area and a radiation unexposed area, wherein the radiation exposed area is characterized by enhanced adhesion between the radiation-absorbing layer and the imaging layer, as compared to the radiation unexposed area; and
developing the exposed film, thereby removing the radiation unexposed area to provide the pattern.

16. The method of claim 12, further comprising, before said providing the imaging layer:
exposing the photoresponsive surface of the radiation-absorbing layer to a patterned radiation exposure, thereby providing a patterned radiation-absorbing layer having a radiation exposed area and a radiation unexposed area, wherein the radiation exposed area is characterized by enhanced nucleation for deposition of the imaging layer, as compared to the radiation unexposed area.

17. The method of claim 1, wherein the method further comprises, after said providing the imaging layer:
exposing the radiation-absorbing layer and the imaging layer to a patterned radiation exposure, thereby providing an exposed film having a radiation exposed area and a radiation unexposed area; and
developing the exposed film, thereby removing the radiation unexposed area or the radiation exposed area to provide the pattern.

18. The method of claim 1, wherein said incorporating comprises:
providing one or more precursors comprising a structure having formula (I) or (II):
MₐR_{b} (I),
wherein:
M is a metal or an atom having a high EUV absorption cross-section;
each R is, independently, H, halo, optionally substituted alkyl, optionally substituted cycloalkyl, optionally substituted cycloalkenyl, optionally substituted alkenyl, optionally substituted alkynyl, optionally substituted alkoxy, optionally substituted alkanoyloxy, optionally substituted aryl, optionally substituted amino, optionally substituted bis(trialkylsilyl)amino, optionally substituted trialkylsilyl, oxo, an anionic ligand, a neutral ligand, or a multidentate ligand;
a≥1; and b≥1; or
MₐR_{b}L_{c} (II),
wherein:
M is a metal or an atom having a high EUV absorption cross-section;
each R is, independently, halo, optionally substituted alkyl, optionally substituted aryl, optionally substituted amino, optionally substituted alkoxy, or L;
each L is, independently, a ligand, an anionic ligand, a neutral ligand, a multidentate ligand, ion, or other moiety that is reactive with a counter-reactant, in which R and L with M, taken together, can optionally form a heterocyclyl group or in which R and L, taken together, can optionally form a heterocyclyl group;
a≥1; b≥1; and c≥1.

19. The method of claim 1, wherein said incorporating comprises:
providing one or more precursors selected from the group consisting of:
InR₃, wherein each R is, independently, halo, optionally substituted C₁₋₁₂ alkyl, or diketonate;
SnR₂ or SnR₄, wherein each R is, independently, halo, optionally substituted C₁₋₁₂ alkoxy, optionally substituted amino, optionally substituted aryl, cyclopentadienyl, or a diketonate;
BiR₃, wherein each R is, independently, halo, optionally substituted C₁₋₁₂ alkyl, mono-C₁₋₁₂ alkylamino, di-C₁₋₁₂ alkylamino, optionally substituted aryl, optionally substituted bis(trialkylsilyl)amino, or a diketonate;
SbR₃, wherein each R is, independently, halo, optionally substituted C₁₋₁₂ alkyl, optionally substituted C₁₋₁₂ alkoxy, or optionally substituted amino;
TeR₂ or TeR₄, wherein each R is, independently, halo, optionally substituted C₁₋₁₂ alkyl, optionally substituted C₁₋₁₂ alkoxy, optionally substituted aryl, hydroxyl, oxo, or optionally substituted trialkylsilyl; and
RI, wherein R is iodo (I) or optionally substituted C₁₋₁₂ alkyl.

20. The method of claim 1, wherein said providing the imaging layer comprises:
providing one or more precursors comprising a structure having formula (I) or (II) in the presence of the counter-reactant, wherein the counter-reactant comprises oxygen or a chalcogenide precursor

21. A patterning structure comprising:
a substrate to receive a pattern;
an imaging layer on a surface of the substrate;
a radiation-absorbing layer under the imaging layer, wherein the radiation-absorbing layer is configured to increase the radiation absorptivity and patterning performance of the imaging layer.

22. An apparatus for processing a substrate, the apparatus comprising:
(a) one or more process chambers, each process chamber comprising a chuck or a pedestal;
one or more gas inlets into the process chambers and associated flow-control hardware; and
one or more gas outlets for removing materials from the process chamber and associated flow-control hardware;
(b) a controller having at least one processor and a memory, wherein
the at least one processor and the memory are communicatively connected with one another,
the at least one processor is at least operatively connected with the flow-control hardware, and
the memory stores computer-executable instructions for controlling the at least one processor to at least control the flow-control hardware and for causing the method of claim 1.
